(19) United States
(12) Patent Application Publication
(10) Pub. No.: US 2016/0141510 A1
(43) Pub. Date: May 19, 2016

(54) ORGANIC ELECTROLUMINESCENT DEVICE

(71) Applicant: SAMSUNG DISPLAY CO., LTD., Yongin-si (KR)

(72) Inventors: Ikuo Sasaki, Yokohama (JP); Junta Fuchiwaki, Yokohama (JP); Shuri Sato, Yokohama (JP)

(21) Appl. No.: 14/938,762

(22) Filed: Nov. 11, 2015

(30) Foreign Application Priority Data
Nov. 19, 2014 (JP) 2014-234140
Nov. 19, 2014 (JP) 2014-234141

(51) Int. Cl. H01L 51/00; C09K 11/02

(52) U.S. Cl. CPC H01L 51/0061; H01L 51/0072; H01L 51/006; H01L 51/005; C09K 11/025; H01L 51/5012

(57) ABSTRACT

An organic electroluminescent device includes an anode, an emission layer, a first hole transport layer positioned between the anode and the emission layer, and a second hole transport layer positioned between the first hole transport layer and the emission layer, wherein the first hole transport layer includes an electron accepting material, and the second hole transport layer includes a hole transport material represented by the following Formula 1:

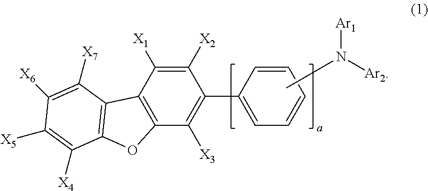

### CROSS-REFERENCE TO RELATED APPLICATIONS

This patent application claims priority to and the benefit of Japanese Patent Application Nos. 2014-234140, filed on Nov. 19, 2014, and 2014-234141, filed on Nov. 19, 2014, the entire content of each of which is hereby incorporated by reference.

### BACKGROUND

One of more aspects of embodiments of the present disclosure relate to an organic electroluminescent device.

Organic electroluminescent (EL) displays are currently being actively developed, and self-luminescent organic EL devices used in the organic EL display are also being developed.

An example of an organic EL device may have a structure including an anode, a hole transport layer positioned on the anode, an emission layer positioned on the hole transport layer, an electron transport layer positioned on the emission layer, and a cathode positioned on the electron transport layer.

In such an organic EL device, holes and electrons injected from the anode and the cathode recombine in the emission layer to generate excitons, and the excitons emit light as they transition to the ground state.

In comparable organic EL devices, hole transport materials including a carbazole group may be used in a hole transport layer. However, such organic EL devices do not exhibit satisfactory lifetimes, requiring further improvement.

### SUMMARY

One or more aspects of embodiments of the present disclosure provide a novel and improved organic EL device having increased lifetime.

One or more embodiments of the present disclosure provide an organic EL device including an anode, an emission layer, a first hole transport layer positioned between the anode and the emission layer, the first hole transport layer including an electron accepting material, and a second hole transport layer positioned between the first hole transport layer and the emission layer, the second hole transport layer including a first hole transport material represented by the following Formula 1:

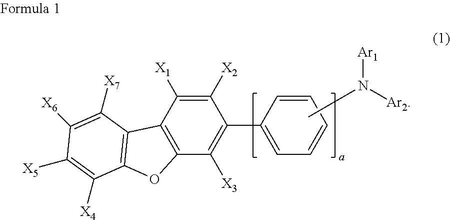

In Formula 1, Ar₁ and Ar₂ may be each independently selected from a substituted or unsubstituted aryl group having 6 to 12 carbon atoms for forming a ring, and a substituted or unsubstituted heteroaryl group having 5 to 13 carbon atoms for forming a ring; X₁ to X₇ may be each independently selected from hydrogen, deuterium, a halogen atom, an alkyl group having 1 to 15 carbon atoms, a substituted or unsubstituted aryl group having 6 to 18 carbon atoms for forming a ring, and a substituted or unsubstituted heteroaryl group having 5 to 18 carbon atoms for forming a ring, and a may be 1 or 2.

In one or more embodiments, the lifetime of the organic EL device may be improved.

In one or more embodiments, Ar₁ and Ar₂ may be each independently a substituted or unsubstituted aryl group having 6 to 12 carbon atoms for forming a ring.

In one or more embodiments, the first hole transport material may be selected from the group of compounds represented by the following Formulae 1-1 to 1-15:

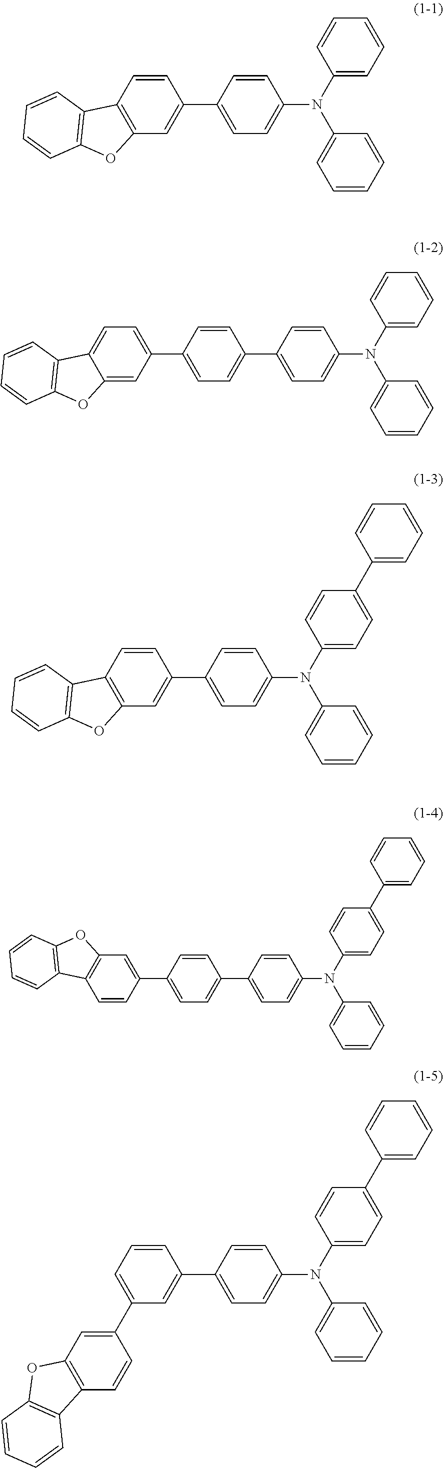 [SMILES: c1ccc(N(c2ccccc2)c2ccc(-c3ccc4c(c3)oc3ccccc34)cc2)cc1 ; c1ccc(N(c2ccccc2)c2ccc(-c3ccc(-c4ccc5c(c4)oc4ccccc45)cc3)cc2)cc1 ; c1ccc(-c2ccc(N(c3ccccc3)c3ccc(-c4ccc5c(c4)oc4ccccc45)cc3)cc2)cc1 ; c1ccc(-c2ccc(N(c3ccccc3)c3ccc(-c4ccc(-c5ccc6c(c5)oc5ccccc56)cc4)cc3)cc2)cc1 ; c1ccc(-c2ccc(N(c3ccccc3)c3ccc(-c4cccc(-c5ccc6c(c5)oc5ccccc56)c4)cc3)cc2)cc1]

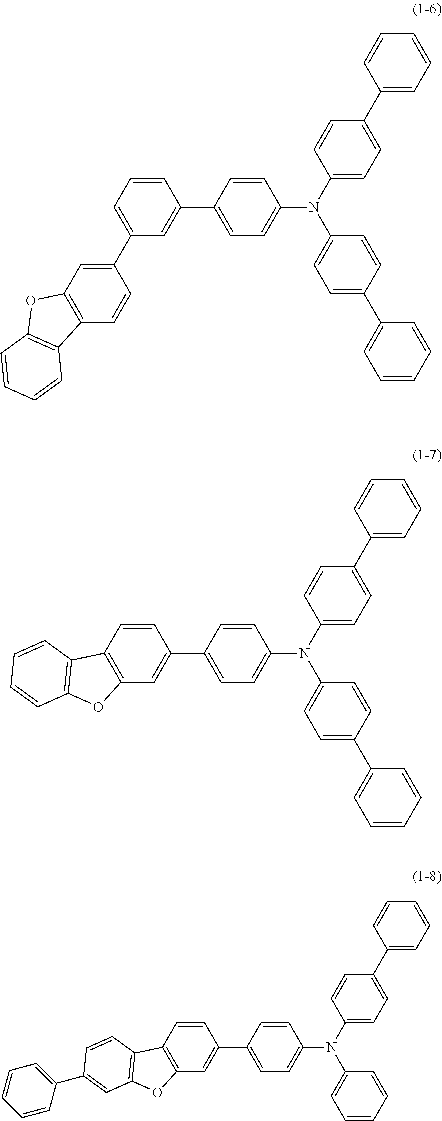 [SMILES: c1ccc(-c2ccc(N(c3ccc(-c4ccccc4)cc3)c3ccc(-c4cccc(-c5ccc6c(c5)oc5ccccc56)c4)cc3)cc2)cc1 ; c1ccc(-c2ccc(N(c3ccc(-c4ccccc4)cc3)c3ccc(-c4ccc5c(c4)oc4ccccc45)cc3)cc2)cc1 ; c1ccc(-c2ccc(N(c3ccccc3)c3ccc(-c4ccc5c(c4)oc4cc(-c6ccccc6)ccc45)cc3)cc2)cc1]

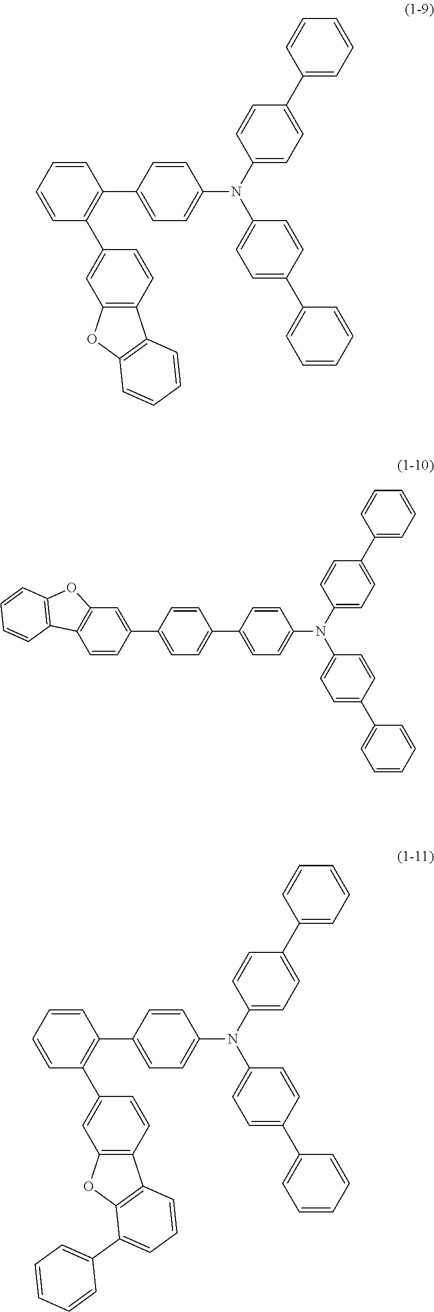 [SMILES: c1ccc(-c2ccc(N(c3ccc(-c4ccccc4)cc3)c3ccc(-c4ccccc4-c4ccc5c(c4)oc4ccccc45)cc3)cc2)cc1 ; c1ccc(-c2ccc(N(c3ccc(-c4ccccc4)cc3)c3ccc(-c4ccc(-c5ccc6c(c5)oc5ccccc56)cc4)cc3)cc2)cc1 ; c1ccc(-c2ccc(N(c3ccc(-c4ccccc4)cc3)c3ccc(-c4ccccc4-c4ccc5c(c4)oc4c(-c6ccccc6)cccc45)cc3)cc2)cc1]

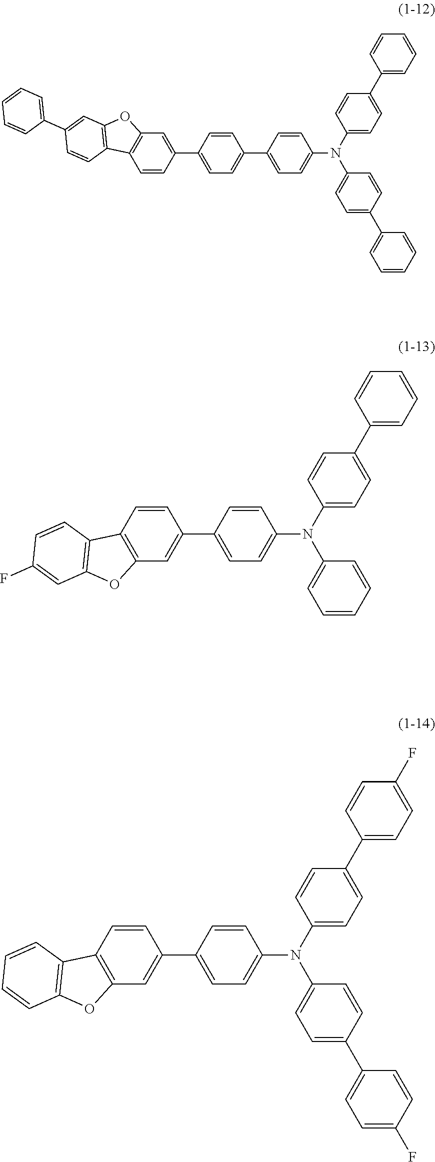 [SMILES: c1ccc(-c2ccc(N(c3ccc(-c4ccccc4)cc3)c3ccc(-c4ccc(-c5ccc6c(c5)oc5cc(-c7ccccc7)ccc56)cc4)cc3)cc2)cc1 ; Fc1ccc2c(c1)oc1cc(-c3ccc(N(c4ccccc4)c4ccc(-c5ccccc5)cc4)cc3)ccc12 ; Fc1ccc(-c2ccc(N(c3ccc(-c4ccc(F)cc4)cc3)c3ccc(-c4ccc5c(c4)oc4ccccc45)cc3)cc2)cc1]

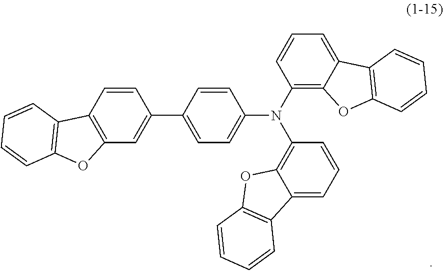 [SMILES: c1ccc2c(c1)oc1cc(-c3ccc(N(c4cccc5c4oc4ccccc45)c4cccc5c4oc4ccccc45)cc3)ccc12]

In one or more embodiments, the electron accepting material may have a Lowest Unoccupied Molecular Orbital (LUMO) level within a range of about −9.0 eV to about −4.0 eV.

In one or more embodiments, the first hole transport layer may include a second hole transport material represented by the following Formula 2:

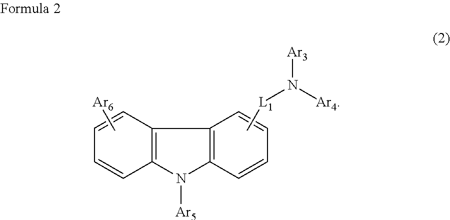

In Formula 2, Ar₃ to Ar₅ may be each independently selected from a substituted or unsubstituted aryl group and a substituted or unsubstituted heteroaryl group; Ar₆ may be selected from a substituted or unsubstituted aryl group, a substituted or unsubstituted heteroaryl group, a carbazolyl group and an alkyl group; and L₁ may be selected from a direct linkage, a substituted or unsubstituted arylene group and a substituted or unsubstituted heteroarylene group.

In one or more embodiments, the second hole transport material may be selected from the group of compounds represented by the following Formulae 2-1 to 2-16:

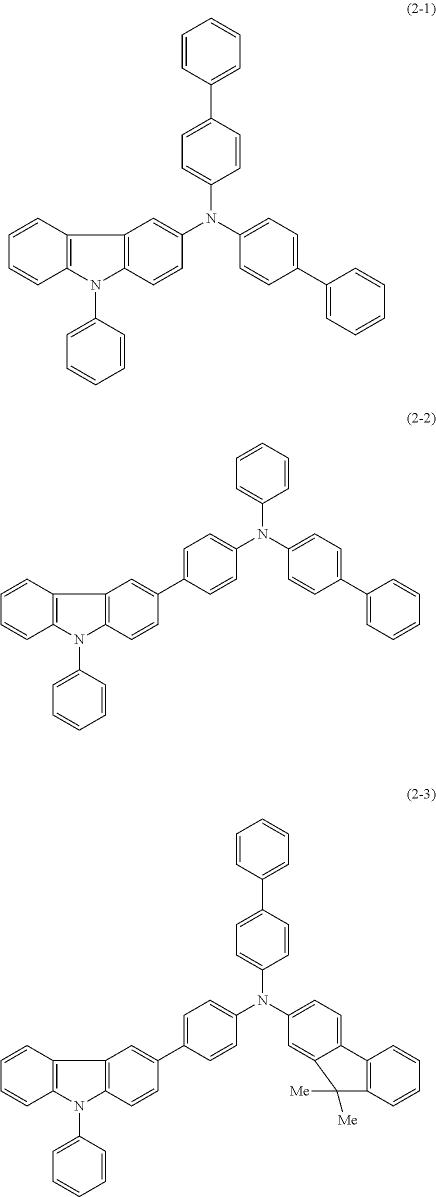 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

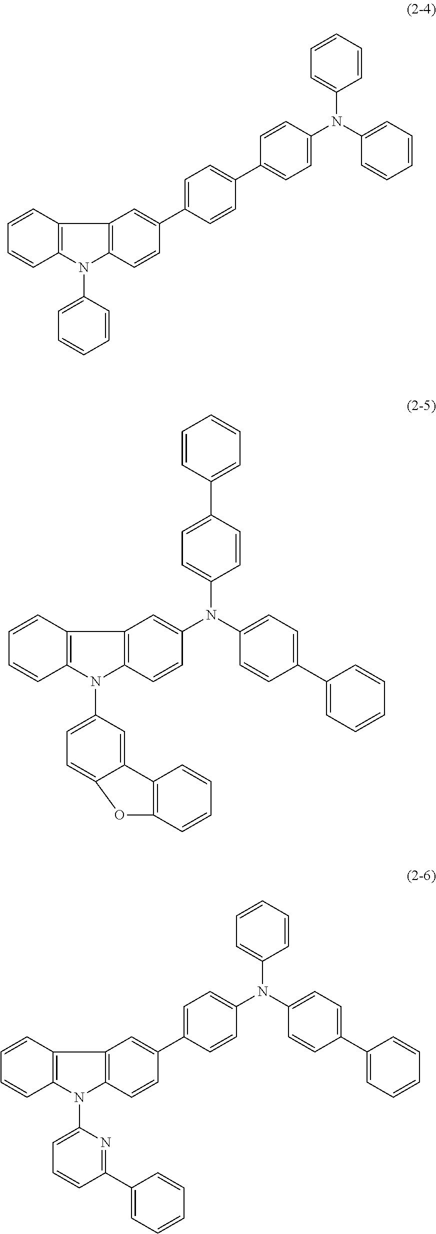 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

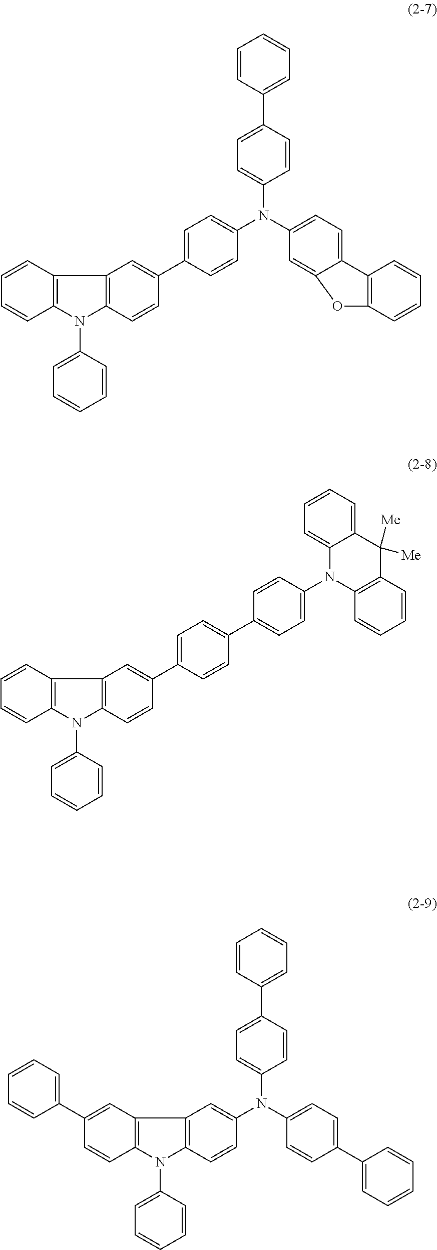 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

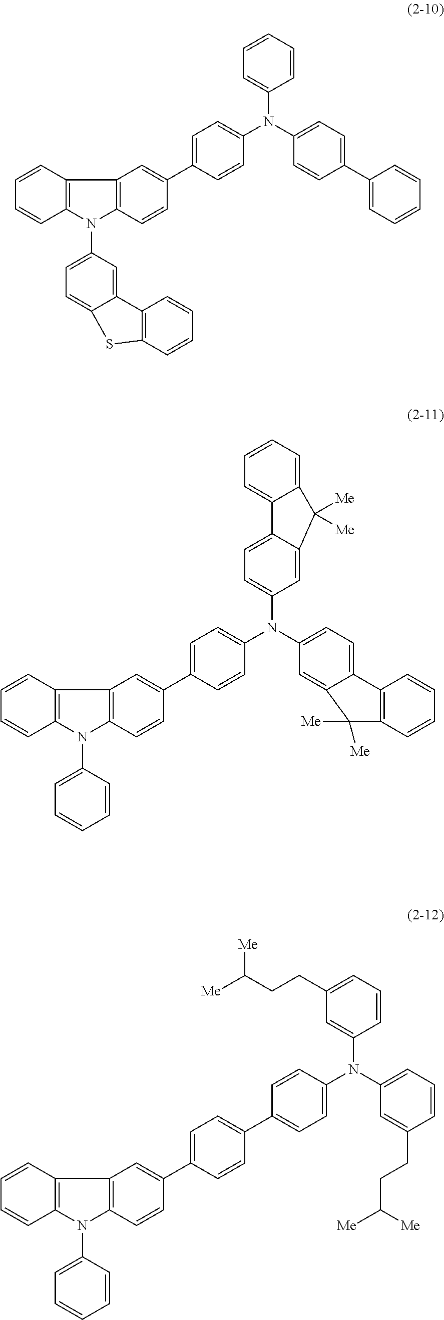 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

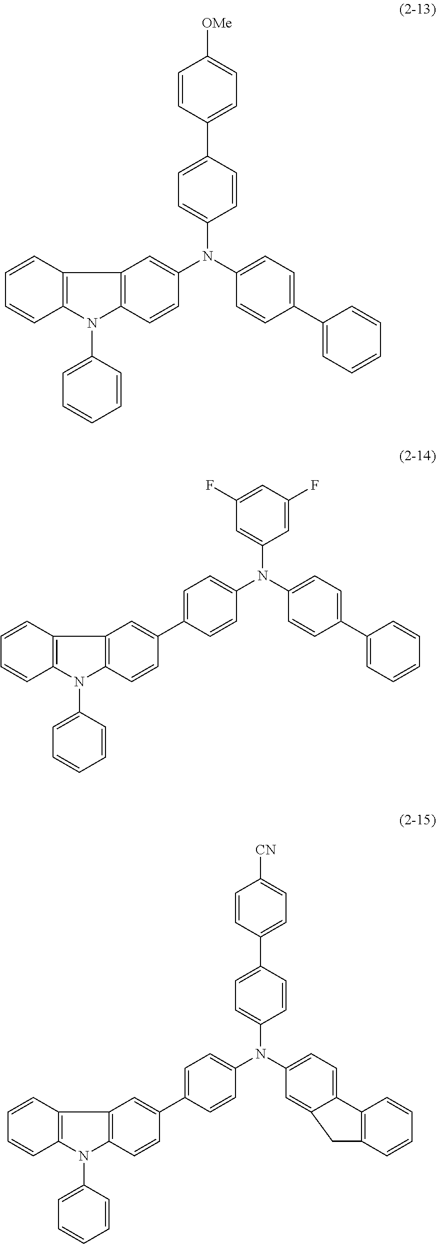 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

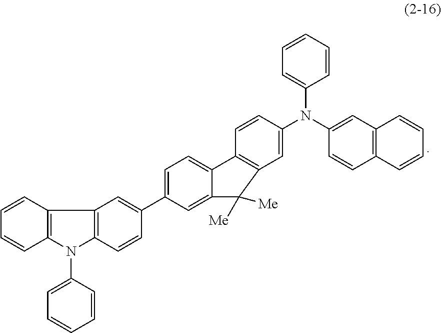 [SMILES: CC1(C)c2cc(-c3ccc4c(c3)c3ccccc3n4-c3ccccc3)ccc2-c2ccc(N(c3ccccc3)c3ccc4ccccc4c3)cc21]

In one or more embodiments, the emission layer may include a host material having a structure represented by the following Formula 3:

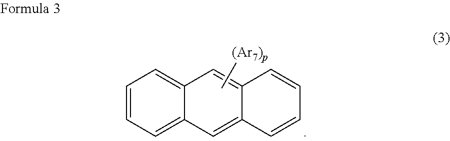

In Formula 3, each Ar₇ may be independently selected from hydrogen, deuterium, a substituted or unsubstituted alkyl group having 1 to 50 carbon atoms, a substituted or unsubstituted cycloalkyl group having 3 to 50 carbon atoms for forming a ring, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms for forming a ring, a substituted or unsubstituted arylthio group having 6 to 50 carbon atoms for forming a ring, a substituted or unsubstituted alkoxycarbonyl group having 2 to 50 carbon atoms, a substituted or unsubstituted aryl group having 6 to 50 carbon atoms for forming a ring, a substituted or unsubstituted heteroaryl group having 5 to 50 carbon atoms for forming a ring, a substituted or unsubstituted silyl group, a carboxyl group, a halogen atom, a cyano group, a nitro group and a hydroxyl group, and p may be an integer from 1 to 10.

In one or more embodiments, the second hole transport layer may be adjacent to the emission layer.

In one or more embodiments, the first hole transport layer may be adjacent to the anode.

In one or more embodiments, a third hole transport layer may be positioned between the first hole transport layer and the second hole transport layer. The third hole transport layer may further include at least one selected from the first hole transport material and the second hole transport material.

In one or more embodiments of the present disclosure, an organic EL device includes an anode, an emission layer, a first hole transport layer positioned between the anode and the emission layer, the first hole transport layer including a third hole transport material and an electron accepting material doped in the third hole transport material, and a second hole transport layer positioned between the first hole transport layer and the emission layer, the second hole transport layer including a fourth hole transport material represented by Formula 1:

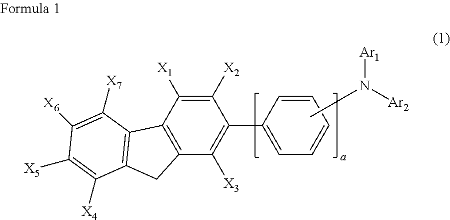

In Formula 1, Ar₁ and Ar₂ may be each independently selected from a substituted or unsubstituted aryl group having 6 to 12 carbon atoms for forming a ring, and a substituted or unsubstituted heteroaryl group having 5 to 13 carbon atoms for forming a ring; X₁ to X₇ may be each independently selected from hydrogen, deuterium, a halogen atom, an alkyl group having 1 to 15 carbon atoms, a substituted or unsubstituted aryl group having 6 to 18 carbon atoms for forming a ring, and a substituted or unsubstituted heteroaryl group having 5 to 18 carbon atoms for forming a ring, and a may be 1 or 2.

In one or more embodiments of the present disclosure, the emission efficiency and the lifetime of the organic EL device may be improved.

In one or more embodiments, Ar₁ and Ar₂ may be each independently a substituted or unsubstituted aryl group having 6 to 12 carbon atoms for forming a ring.

In one or more embodiments, the fourth hole transport material may be selected from the group of compounds represented by the following Formulae 1-1 to 1-15:

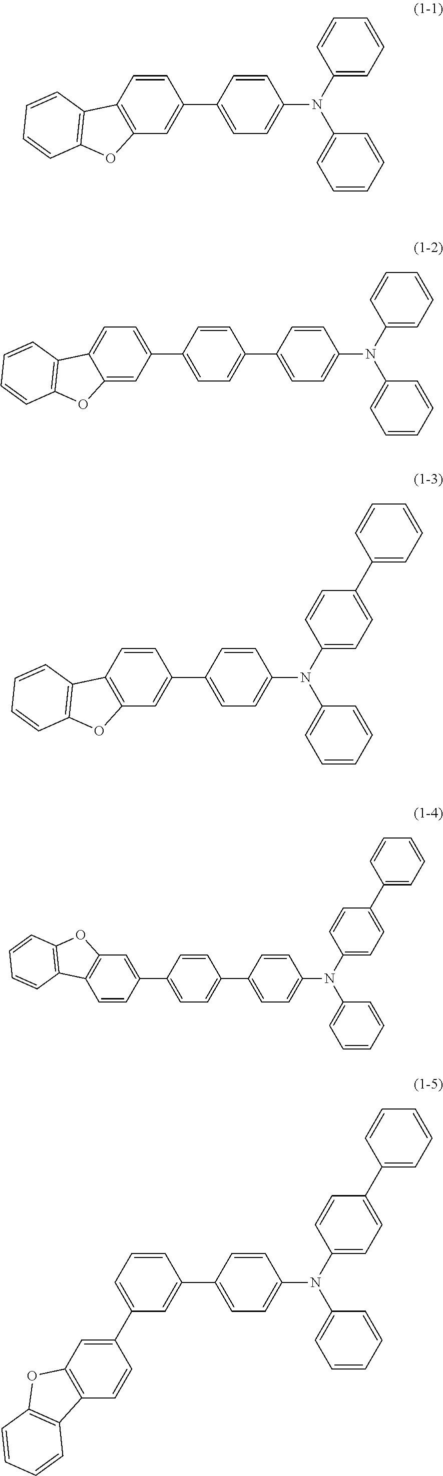 [SMILES: c1ccc(N(c2ccccc2)c2ccc(-c3ccc4c(c3)oc3ccccc34)cc2)cc1 ; c1ccc(N(c2ccccc2)c2ccc(-c3ccc(-c4ccc5c(c4)oc4ccccc45)cc3)cc2)cc1 ; c1ccc(-c2ccc(N(c3ccccc3)c3ccc(-c4ccc5c(c4)oc4ccccc45)cc3)cc2)cc1 ; c1ccc(-c2ccc(N(c3ccccc3)c3ccc(-c4ccc(-c5ccc6c(c5)oc5ccccc56)cc4)cc3)cc2)cc1 ; c1ccc(-c2ccc(N(c3ccccc3)c3ccc(-c4cccc(-c5ccc6c(c5)oc5ccccc56)c4)cc3)cc2)cc1]

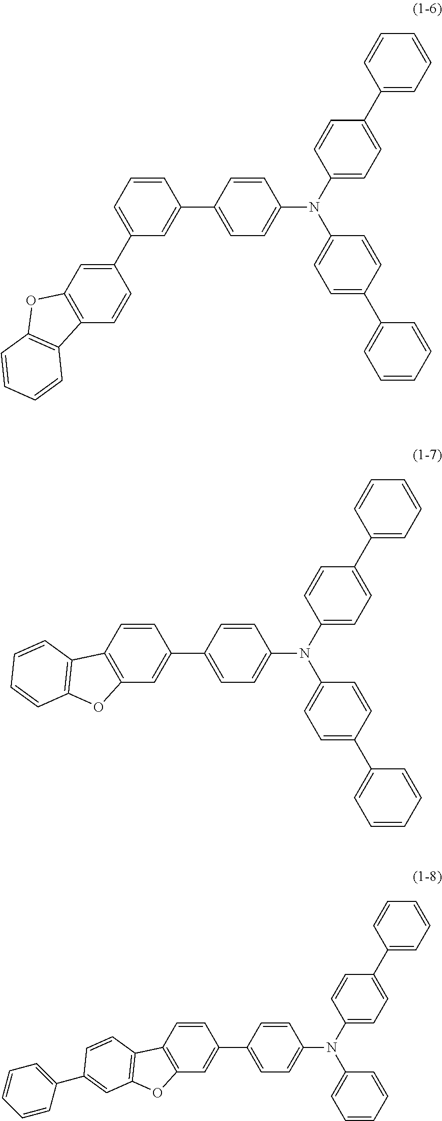 [SMILES: c1ccc(-c2ccc(N(c3ccc(-c4ccccc4)cc3)c3ccc(-c4cccc(-c5ccc6c(c5)oc5ccccc56)c4)cc3)cc2)cc1 ; c1ccc(-c2ccc(N(c3ccc(-c4ccccc4)cc3)c3ccc(-c4ccc5c(c4)oc4ccccc45)cc3)cc2)cc1 ; c1ccc(-c2ccc(N(c3ccccc3)c3ccc(-c4ccc5c(c4)oc4cc(-c6ccccc6)ccc45)cc3)cc2)cc1]

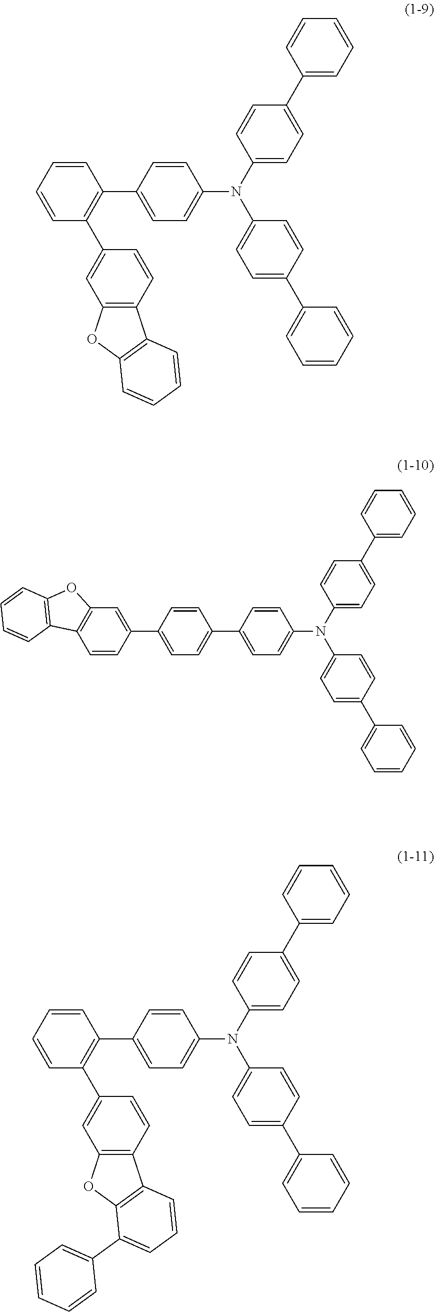 [SMILES: c1ccc(-c2ccc(N(c3ccc(-c4ccccc4)cc3)c3ccc(-c4ccccc4-c4ccc5c(c4)oc4ccccc45)cc3)cc2)cc1 ; c1ccc(-c2ccc(N(c3ccc(-c4ccccc4)cc3)c3ccc(-c4ccc(-c5ccc6c(c5)oc5ccccc56)cc4)cc3)cc2)cc1 ; c1ccc(-c2ccc(N(c3ccc(-c4ccccc4)cc3)c3ccc(-c4ccccc4-c4ccc5c(c4)oc4c(-c6ccccc6)cccc45)cc3)cc2)cc1]

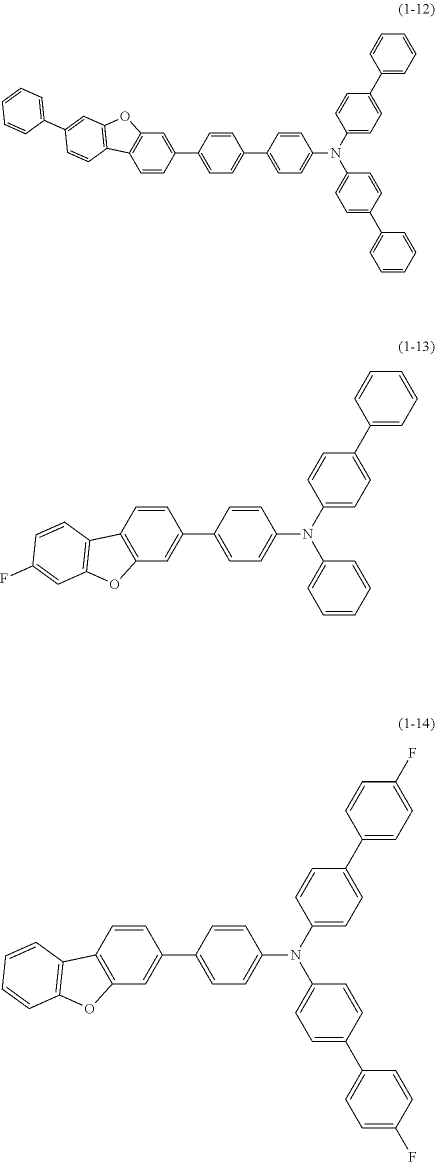 [SMILES: c1ccc(-c2ccc(N(c3ccc(-c4ccccc4)cc3)c3ccc(-c4ccc(-c5ccc6c(c5)oc5cc(-c7ccccc7)ccc56)cc4)cc3)cc2)cc1 ; Fc1ccc2c(c1)oc1cc(-c3ccc(N(c4ccccc4)c4ccc(-c5ccccc5)cc4)cc3)ccc12 ; Fc1ccc(-c2ccc(N(c3ccc(-c4ccc(F)cc4)cc3)c3ccc(-c4ccc5c(c4)oc4ccccc45)cc3)cc2)cc1]

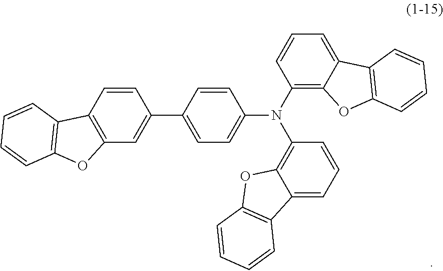 [SMILES: c1ccc2c(c1)oc1cc(-c3ccc(N(c4cccc5c4oc4ccccc45)c4cccc5c4oc4ccccc45)cc3)ccc12]

In one or more embodiments, the third hole transport material may have a structure represented by the following Formula 2:

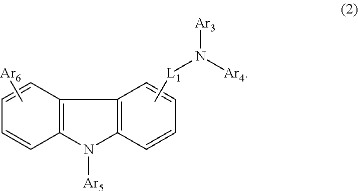

In Formula 2, Ar₃ to Ar₅ may be each independently selected from a substituted or unsubstituted aryl group and a substituted or unsubstituted heteroaryl group; Ar₆ may be selected from a substituted or unsubstituted aryl group, a substituted or unsubstituted heteroaryl group, a carbazolyl group and an alkyl group; and L₁ may be selected from a direct linkage, a substituted or unsubstituted arylene group and a substituted or unsubstituted heteroarylene group.

In one or more embodiments, the third hole transport material may be selected from the group of compounds represented by the following Formulae 2-1 to 2-16:

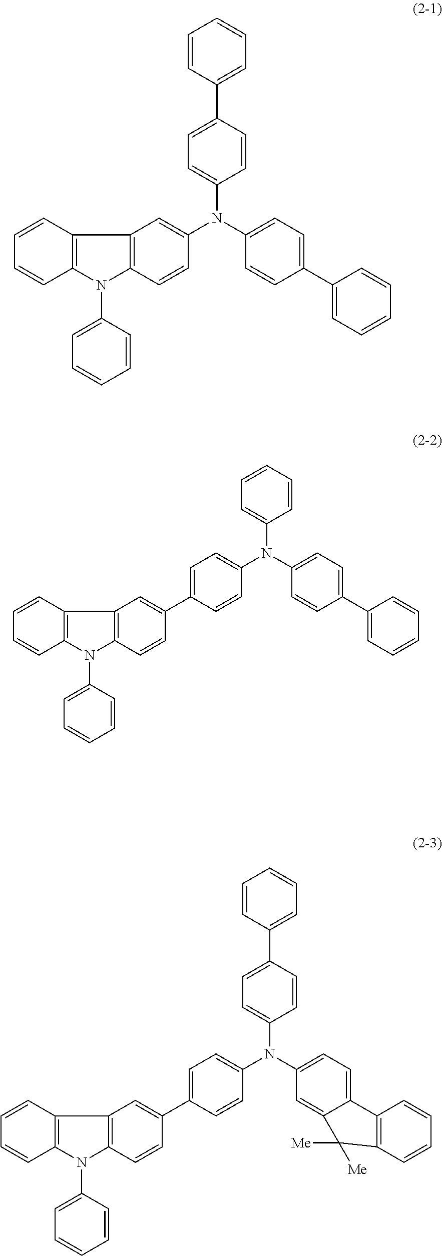 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

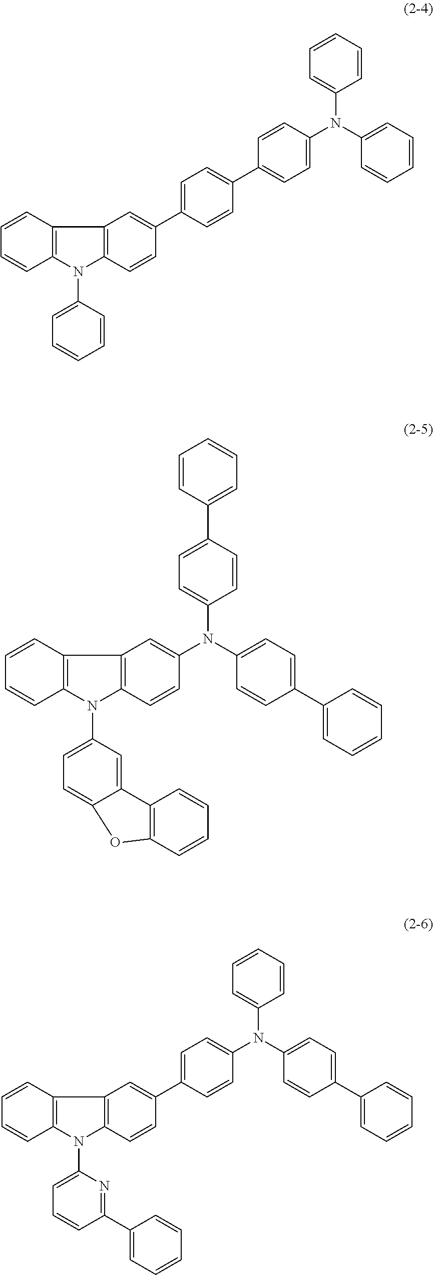 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

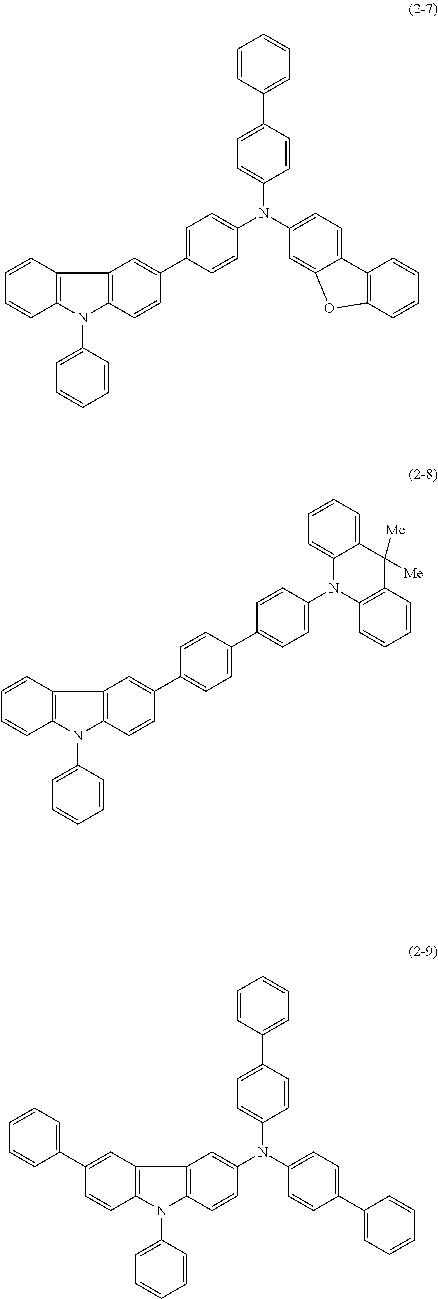 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

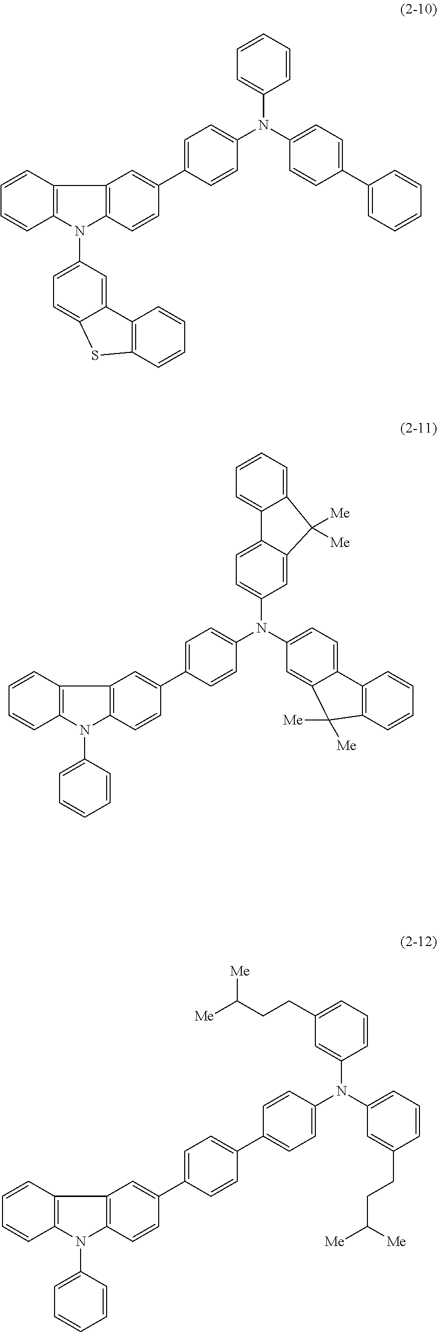 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

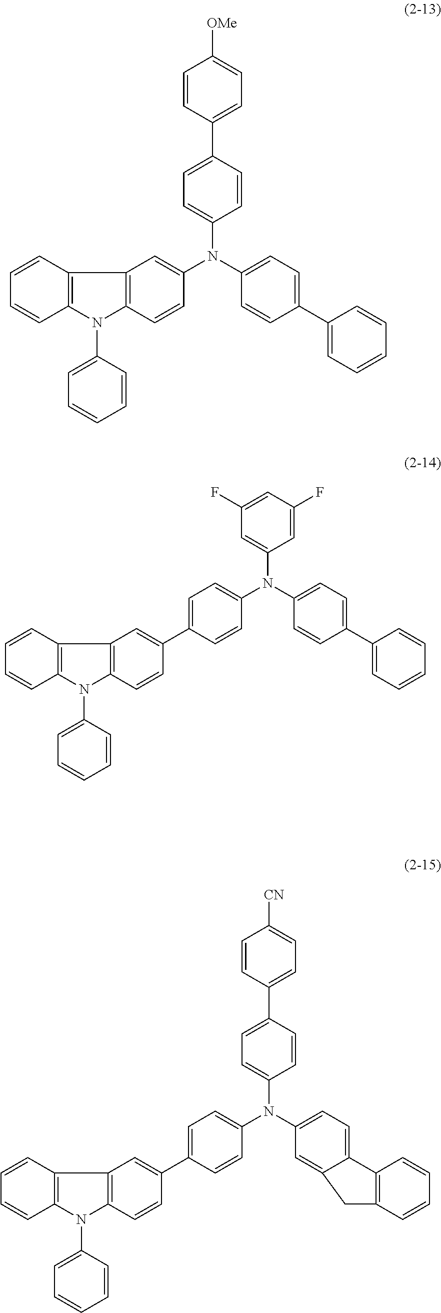 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

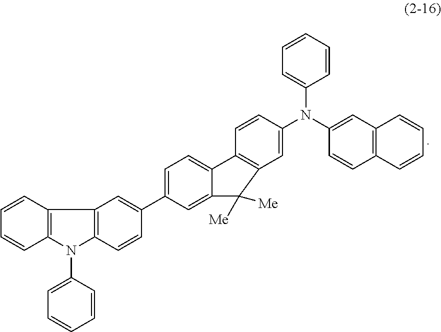 [SMILES: CC1(C)c2cc(-c3ccc4c(c3)c3ccccc3n4-c3ccccc3)ccc2-c2ccc(N(c3ccccc3)c3ccc4ccccc4c3)cc21]

In one or more embodiments, the electron accepting material may have a LUMO level within a range of about −9.0 eV to about −4.0 eV.

In one or more embodiments, the emission layer may include a host material having a structure represented by the following Formula 3:

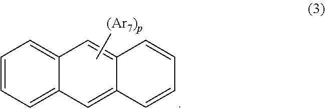

In Formula 3, each Ar₇ may be independently selected from hydrogen, deuterium, a substituted or unsubstituted alkyl group having 1 to 50 carbon atoms, a substituted or unsubstituted cycloalkyl group having 3 to 50 carbon atoms for forming a ring, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms for forming a ring, a substituted or unsubstituted arylthio group having 6 to 50 carbon atoms for forming a ring, a substituted or unsubstituted alkoxycarbonyl group having 2 to 50 carbon atoms, a substituted or unsubstituted aryl group having 6 to 50 carbon atoms for forming a ring, a substituted or unsubstituted heteroaryl group having 5 to 50 carbon atoms for forming a ring, a substituted or unsubstituted silyl group, a carboxyl group, a halogen atom, a cyano group, a nitro group and a hydroxyl group, and p may be an integer from 1 to 10.

In one or more embodiments, the second hole transport layer may be adjacent to the emission layer.

In one or more embodiments, the first hole transport layer may be adjacent to the anode.

In one or more embodiments, a third hole transport layer may be positioned between the first hole transport layer and the second hole transport layer, the third hole transport layer including at least one selected from the third hole transport material and the fourth hole transport material.

### BRIEF DESCRIPTION OF THE FIGURES

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a cross-sectional schematic view illustrating the configuration of an organic EL device according to one or more embodiments of the present disclosure; and

FIG. 2 is a cross-sectional schematic view illustrating a modification of an organic EL device according to one or more embodiments of the present disclosure.

### DETAILED DESCRIPTION

Hereinafter, one or more embodiments of the present disclosure will be described in more detail with reference to the accompanying drawings. In the description and drawings, elements having substantially the same function are designated by the same reference numerals, and repeated explanations thereof will not be provided. In addition, “a compound represented by Formula A” (A may include a numerical designation) may be also referred to as “Compound A”.

### 1-1. CONFIGURATION OF ORGANIC EL DEVICE INCLUDING FIRST HOLE TRANSPORT LAYER INCLUDING ELECTRON ACCEPTING MATERIAL ACCORDING TO EMBODIMENTS OF THE PRESENT DISCLOSURE

### 1-1-1. Overall Configuration of Organic EL Device

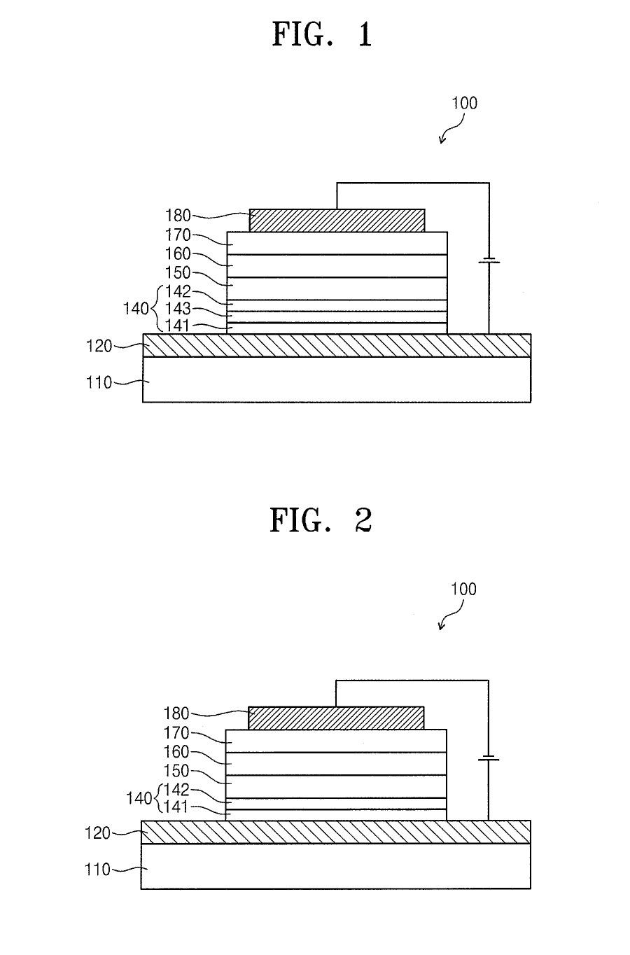

FIG. 1 is a cross-sectional schematic view illustrating the overall configuration of an organic EL device 100 according to one or more embodiments of the present disclosure. As shown in FIG. 1, an organic EL device 100 may include a substrate 110, a first electrode 120 positioned on the substrate 110, a hole transport layer 140 positioned on the first electrode 120, an emission layer 150 positioned on the hole transport layer 140, an electron transport layer 160 positioned on the emission layer 150, an electron injection layer 170 positioned on the electron transport layer 160, and a second electrode 180 positioned on the electron injection layer 170. The hole transport layer 140 may comprise a multi-layer structure including a plurality of layers 141, 142, and/or 143.

### 1-1-2. Configuration of Substrate

The substrate 110 may be any suitable substrate capable of being used in organic EL devices. For example, the substrate 110 may be a glass substrate, a semiconductor substrate, or a transparent plastic substrate.

### 1-1-3. Configuration of First Electrode

The first electrode 120 may be, for example, an anode, and may be formed on the substrate 110 using an evaporation method, a sputtering method, etc. The first electrode 120 may be formed as a transmission type electrode using, for example, a metal, an alloy, a conductive compound, etc., having a large work function. The first electrode 120 may be formed using, for example, indium tin oxide (ITO), indium zinc oxide (IZO), tin oxide (SnO₂), zinc oxide (ZnO), etc., which are conductive and transparent. In some embodiments, the anode 120 may be formed as a reflection type electrode (e.g., reflection electrode) using magnesium (Mg), aluminum (Al), etc.

### 1-1-4. Configuration of Hole Transport Layer

The hole transport layer 140 may include a hole transport material having hole transporting functionality. The hole transport layer 140 may be formed, for example, on a hole injection layer to a layer thickness (e.g., total layer thickness of a stacked structure) of about 10 nm to about 150 nm. The hole transport layer 140 of the organic EL device according to embodiments of the present disclosure may include a first hole transport layer 141, a second hole transport layer 142 and a third hole transport layer 143. The ratios of the thicknesses of the first to third hole transport layers are not specifically limited.

### (1-1-4-1. Configuration of First Hole Transport Layer)

The first hole transport layer 141 may be positioned adjacent to the first electrode 120. The first hole transport layer 141 may include an electron accepting material. The first hole transport layer 141 may include additional materials, however, the highest concentration may be that of the electron accepting material. For example, the first hole transport layer 141 may include greater than about 50 wt % of the electron accepting material on the basis of the total amount of the first hole transport layer 141, and in some embodiments, may be formed using only the electron accepting material.

The electron accepting material may include any suitable electron accepting material, and may have a LUMO level within a range of about −9.0 eV to about −4.0 eV, for example, within a range of about −6.0 eV to about −4.0 eV. The electron accepting material may be represented by the following Formulae 4-1 to 4-14:

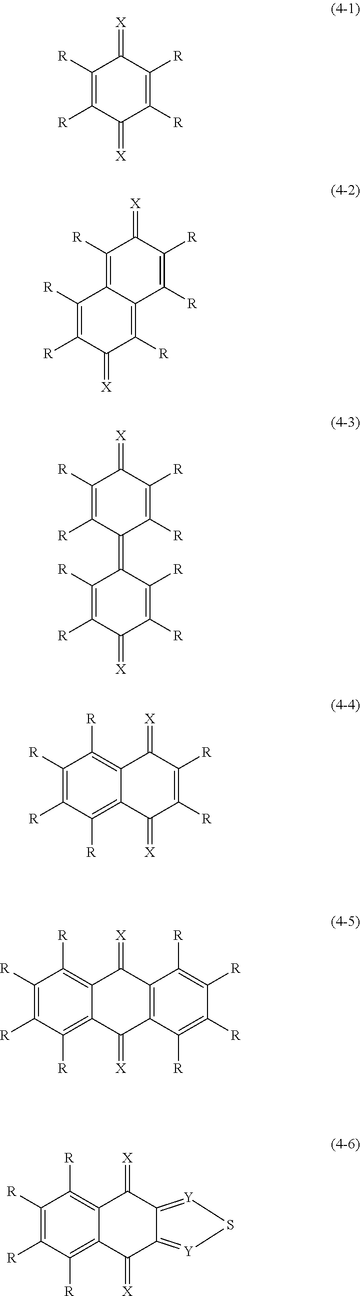

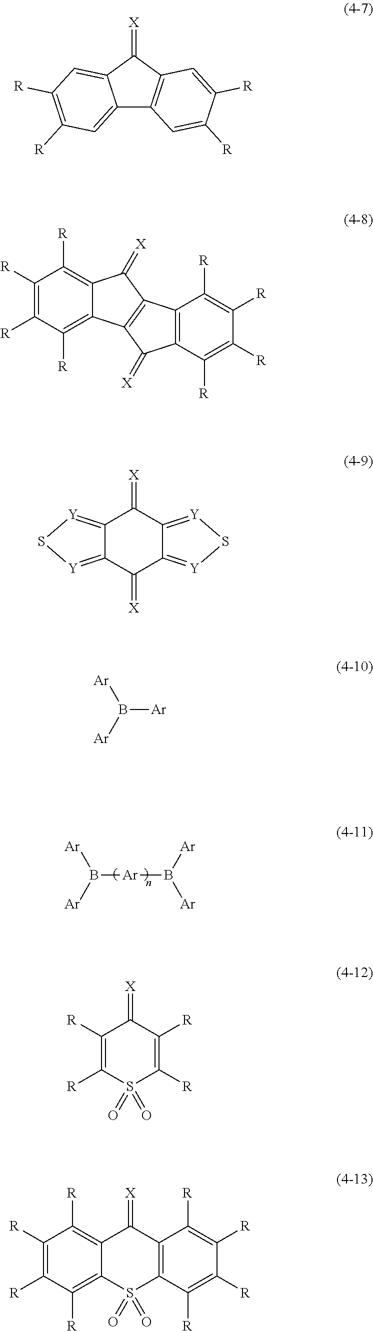

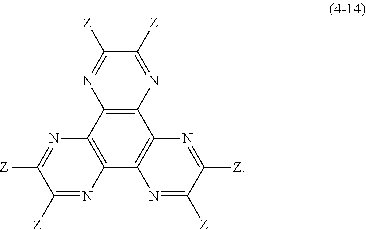

In Formulae 4-1 to 4-14, R may be selected from hydrogen, deuterium, a halogen atom, a fluoroalkyl group having 1 to 50 carbon atoms, a cyano group, an alkoxy group having 1 to 50 carbon atoms, an alkyl group having 1 to 50 carbon atoms, an aryl group having 6 to 50 carbon atoms for forming a ring, and a heteroaryl group having 5 to 50 carbon atoms for forming a ring. As used herein, the statement “atoms for forming a ring” may refer to “ring-forming atoms”. Ar may be selected from an electron-withdrawing substituted or unsubstituted aryl group having 6 to 50 carbon atoms for forming a ring and a substituted or unsubstituted heteroaryl group having 5 to 50 carbon atoms for forming a ring. Y may be selected from a carbon atom (—CH═) and a nitrogen atom (—N═). Z may be a pseudohalogen (e.g., a pseudohalogen group) or may include sulfur (S) (e.g., Z may be a sulfur-containing group). In addition, n may be an integer from 1 to 10. X may be selected from the following Formulae X₁ to X₇:

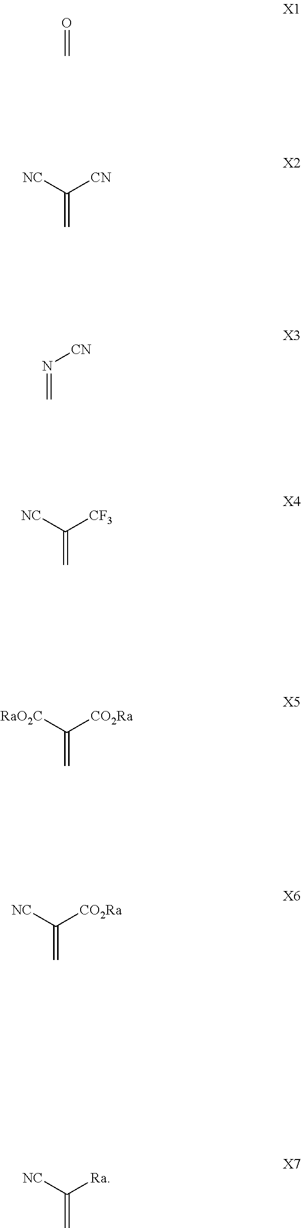

In Formulae X₁ to X₇, Ra may be selected from hydrogen, deuterium, a halogen atom, a fluoroalkyl group having 1 to 50 carbon atoms, a cyano group, an alkoxy group having 1 to 50 carbon atoms, an alkyl group having 1 to 50 carbon atoms, a substituted or unsubstituted aryl group having 6 to 50 carbon atoms for forming a ring and a substituted or unsubstituted heteroaryl group having 5 to 50 carbon atoms for forming a ring.

Non-limiting examples of the substituted or unsubstituted aryl group having 6 to 50 carbon atoms for forming a ring and the substituted or unsubstituted heteroaryl group having 5 to 50 carbon atoms for forming a ring represented, for example, by R, Ar and/or Ra may include a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenyl group, a 3-biphenyl group, a 4-biphenyl group, a p-terphenyl-4-yl group, a p-terphenyl-3-yl group, a p-terphenyl-2-yl group, an m-terphenyl-4-yl group, an m-terphenyl-3-yl group, an m-terphenyl-2-yl group, an o-tolyl group, an m-tolyl group, a p-tolyl group, a p-t-butylphenyl group, a p-(2-phenylpropyl)phenyl group, a 3-methyl-2-naphthyl group, a 4-methyl-1-naphthyl group, a 4-methyl-1-anthryl group, a 4′-methylbiphenyl group, a 4″-t-butyl-p-terphenyl-4-yl group, a fluoranthenyl group, a fluorenyl group, an 1-pyrrolyl group, a 2-pyrrolyl group, a 3-pyrrolyl group, a pyridinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, an 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a quinolyl group, a 3-quinolyl group, a 4-quinolyl group, a 5-quinolyl group, a 6-quinolyl group, a 7-quinolyl group, an 8-quinolyl group, a 1-isoquinolyl group, a 3-isoquinolyl group, a 4-isoquinolyl group, a 5-isoquinolyl group, a 6-isoquinolyl group, a 7-isoquinolyl group, an 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, an 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthroline-2-yl group, a 1,7-phenanthroline-3-yl group, a 1,7-phenanthroline-4-yl group, a 1,7-phenanthroline-5-yl group, a 1,7-phenanthroline-6-yl group, a 1,7-phenanthroline-8-yl group, a 1,7-phenanthroline-9-yl group, a 1,7-phenanthroline-10-yl group, a 1,8-phenanthroline-2-yl group, a 1,8-phenanthroline-3-yl group, a 1,8-phenanthroline-4-yl group, a 1,8-phenanthroline-5-yl group, a 1,8-phenanthroline-6-yl group, a 1,8-phenanthroline-7-yl group, a 1,8-phenanthroline-9-yl group, a 1,8-phenanthroline-10-yl group, a 1,9-phenanthroline-2-yl group, a 1,9-phenanthroline-3-yl group, a 1,9-phenanthroline-4-yl group, a 1,9-phenanthroline-5-yl group, a 1,9-phenanthroline-6-yl group, a 1,9-phenanthroline-7-yl group, a 1,9-phenanthroline-8-yl group, a 1,9-phenanthroline-10-yl group, a 1,10-phenanthroline-2-yl group, a 1,10-phenanthroline-3-yl group, a 1,10-phenanthroline-4-yl group, a 1,10-phenanthroline-5-yl group, a 2,9-phenanthroline-1-yl group, a 2,9-phenanthroline-3-yl group, a 2,9-phenanthroline-4-yl group, a 2,9-phenanthroline-5-yl group, a 2,9-phenanthroline-6-yl group, a 2,9-phenanthroline-7-yl group, a 2,9-phenanthroline-8-yl group, a 2,9-phenanthroline-10-yl group, a 2,8-phenanthroline-1-yl group, a 2,8-phenanthroline-3-yl group, a 2,8-phenanthroline-4-yl group, a 2,8-phenanthroline-5-yl group, a 2,8-phenanthroline-6-yl group, a 2,8-phenanthroline-7-yl group, a 2,8-phenanthroline-9-yl group, a 2,8-phenanthroline-10-yl group, a 2,7-phenanthroline-1-yl group, a 2,7-phenanthroline-3-yl group, a 2,7-phenanthroline-4-yl group, a 2,7-phenanthroline-5-yl group, a 2,7-phenanthroline-6-yl group, a 2,7-phenanthroline-8-yl group, a 2,7-phenanthroline-9-yl group, a 2,7-phenanthroline-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-phenoxazinyl group, a 2-phenoxazinyl group, a 3-phenoxazinyl group, a 4-phenoxazinyl group, a 10-phenoxazinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, a 2-methylpyrrole-1-yl group, a 2-methylpyrrole-3-yl group, a 2-methylpyrrole-4-yl group, a 2-methylpyrrole-5-yl group, a 3-methylpyrrole-1-yl group, a 3-methyl pyrrole-2-yl group, a 3-methyl pyrrole-4-yl group, a 3-methylpyrrole-5-yl group, a 2-t-butylpyrrole-4-yl group, a 3-(2-phenylpropyl)pyrrole-1-yl group, a 2-methyl-1-indolyl group, a 4-methyl-1-indolyl group, a 2-methyl-3-indolyl group, a 4-methyl-3-indolyl group, a 2-t-butyl-1-indolyl group, a 4-t-butyl-1-indolyl group, a 2-t-butyl-3-indolyl group, a 4-t-butyl-3-indolyl group, etc.

Non-limiting examples of the substituted or unsubstituted fluoroalkyl group having 1 to 50 carbon atoms represented, for example, by R and/or Ra may include a perfluoroalkyl group such as a trifluoromethyl group, a pentafluoroethyl group, a heptafluoropropyl group and a heptadecafluorooctane group, a monofluoromethyl group, a difluoromethyl group, a trifluoroethyl group, a tetrafluoropropyl group, an octafluoropentyl group, etc.

Non-limiting examples of the substituted or unsubstituted alkyl group having 1 to 50 carbon atoms represented, for example, by R and/or Ra may include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, a cyclopropyl group, a cyclobutyl group, a cyclopentyl group, a cyclohexyl group, a 4-methylcyclohexyl group, a 1-adamantyl group, a 2-adamantyl group, a 1-norbornyl group, a 2-norbornyl group, etc.

The substituted or unsubstituted alkoxy group having 1 to 50 carbon atoms represented, for example, by R and/or Ra may be a group represented by —OY. Non-limiting examples of Y may include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, etc.

Non-limiting examples of the halogen atom represented, for example, by R and/or Ra may include fluorine, chlorine, bromine, iodine, etc.

Non-limiting examples of the electron accepting material may include compounds represented by Formulae 4-15 and 4-16. The LUMO level of Compound 4-15 may be about −4.40 eV, and the LUMO level of Compound 4-16 may be about −5.20 eV.

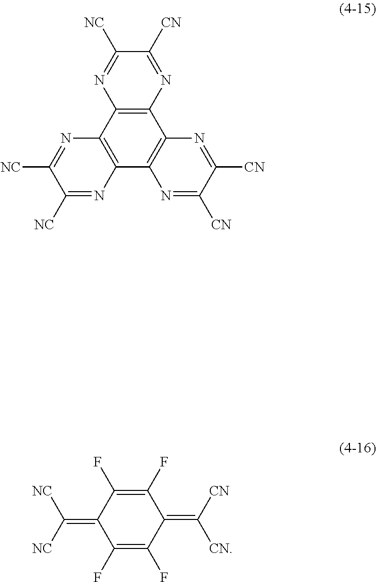 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

### (1-1-4-2. Configuration of Second Hole Transport Layer)

The second hole transport layer 142 may be positioned adjacent to the emission layer 150. The second hole transport layer 142 may include a first hole transport material. The first hole transport material may be represented by the following Formula 1:

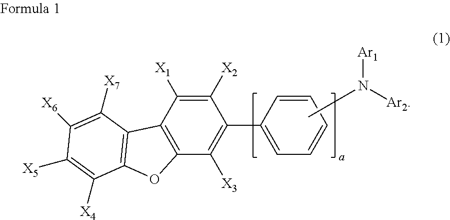

In Formula 1, Ar₁ and Ar₂ may each be independently selected from a substituted or unsubstituted aryl group having 6 to 12 carbon atoms for forming a ring, or a substituted or unsubstituted heteroaryl group having 5 to 13 carbon atoms for forming a ring. For example, Ar₁ and Ar₂ may each independently be a substituted or unsubstituted aryl group having 6 to 12 carbon atoms for forming a ring. One or more substituents of Ar₁ and Ar₂ may be selected from a fluoro group, a chloro group, an alkyl group having 12 and less carbon atoms, a fluoroalkyl group having 12 and less carbon atoms, a cycloalkyl group, an acetyl group, an arylester group, an arylsulfide group, etc.

Non-limiting examples of the substituted or unsubstituted aryl group having 6 to 12 carbon atoms for forming a ring may include a phenyl group, a biphenylyl group, a 1-naphthyl group, a 2-naphthyl group, a fluorophenyl group, a difluorophenyl group, a trifluorophenyl group, a tetrafluorophenyl group, a pentafluorophenyl group, a tolyl group, a nitrophenyl group, a cyanophenyl group, a fluorobiphenyl group, a nitrobiphenyl group, a cyanobiphenyl group, a cyanonaphthyl group, a nitronaphthyl group, a fluoronaphthyl group, etc. In some embodiments, the phenyl group, the biphenylyl group, the naphthyl group, the fluorophenyl group, etc. may be particularly included, and the phenyl group and the biphenylyl group may be included.

Non-limiting examples of the substituted or unsubstituted heteroaryl group having 5 to 13 carbon atoms for forming a ring may include a dibenzofuranyl group, a dibenzothiophenyl group, a pyridyl group, a quinolyl group, an isoquinolyl group, a pyrazyl group, a pyrimidinyl group, a triazine group, an imidazolyl group, an acridinyl group, a carbazolyl group, etc.

In Formula 1, X₁ to X₇ may each independently be selected from hydrogen, deuterium, a halogen atom, an alkyl group having 1 to 15 carbon atoms, a substituted or unsubstituted aryl group having 6 to 18 carbon atoms for forming a ring, or a substituted or unsubstituted heteroaryl group having 5 to 18 carbon atoms for forming a ring, and a may be an integer of 1 or 2.

Non-limiting examples of the alkyl group having 1 to 15 carbon atoms may include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, a cyclopropyl group, a cyclobutyl group, a cyclopentyl group, a cyclohexyl group, a 4-methylcyclohexyl group, a 1-adamantyl group, a 2-adamantyl group, a 1-norbornyl group, a 2-norbornyl group, etc.

Non-limiting examples of the substituted or unsubstituted aryl group having 6 to 18 carbon atoms for forming a ring may include a phenyl group, a biphenylyl group, a 1-naphthyl group, a 2-naphthyl group, a fluorophenyl group, a difluorophenyl group, a trifluorophenyl group, a tetrafluorophenyl group, a pentafluorophenyl group, a tolyl group, a nitrophenyl group, a cyanophenyl group, a fluorobiphenylyl group, a nitrobiphenylyl group, a cyanobiphenylyl group, a cyanonaphthyl group, a nitronaphthyl group, a fluoronaphthyl group, a phenanthryl group, a terphenyl group, a fluoroterphenyl group, etc.

Non-limiting examples of the substituted or unsubstituted heteroaryl group having 5 to 18 carbon atoms for forming a ring may include a dibenzofuranyl group, a dibenzothiophenyl group, a pyridyl group, a quinolyl group, an isoquinolyl group, a pyrazyl group, a pyrimidinyl group, a triazine group, an imidazolyl group, an acridinyl group, etc.

As described above, in one or more embodiments of the present disclosure, the first hole transport material may have a structure in which an amine moiety is combined (e.g., coupled) at position 3 of the dibenzofuran. As demonstrated by representative examples below, the same effect may not be obtained if the amine moiety is combined (e.g., coupled) at another position of the dibenzofuran (for example, position 2).

Non-limiting examples of the first hole transport material may be selected from the group of compounds represented by the following Formulae 1-1 to 1-15:

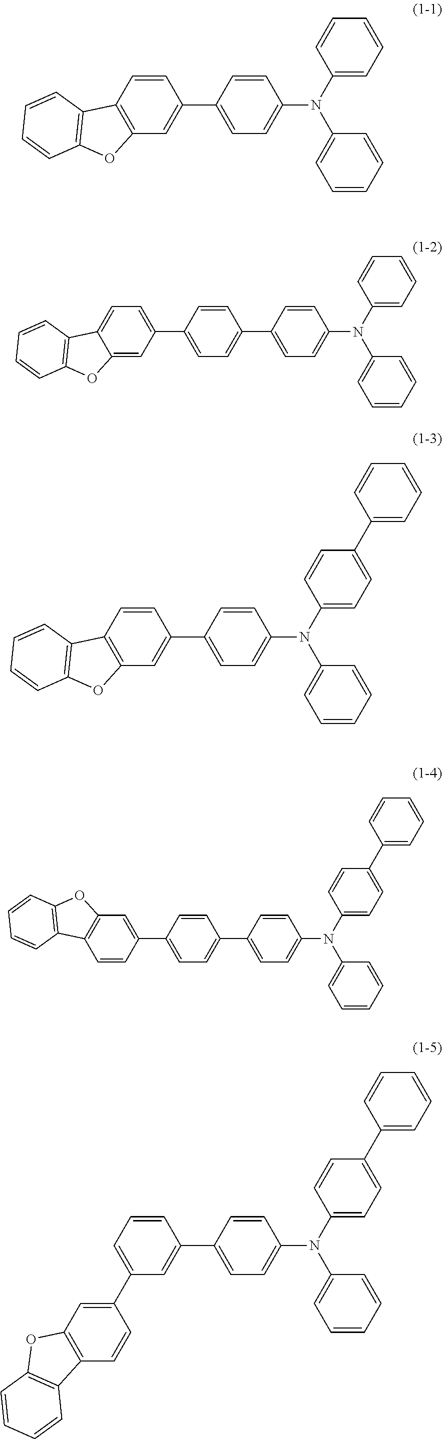 [SMILES: c1ccc(N(c2ccccc2)c2ccc(-c3ccc4c(c3)oc3ccccc34)cc2)cc1 ; c1ccc(N(c2ccccc2)c2ccc(-c3ccc(-c4ccc5c(c4)oc4ccccc45)cc3)cc2)cc1 ; c1ccc(-c2ccc(N(c3ccccc3)c3ccc(-c4ccc5c(c4)oc4ccccc45)cc3)cc2)cc1 ; c1ccc(-c2ccc(N(c3ccccc3)c3ccc(-c4ccc(-c5ccc6c(c5)oc5ccccc56)cc4)cc3)cc2)cc1 ; c1ccc(-c2ccc(N(c3ccccc3)c3ccc(-c4cccc(-c5ccc6c(c5)oc5ccccc56)c4)cc3)cc2)cc1]

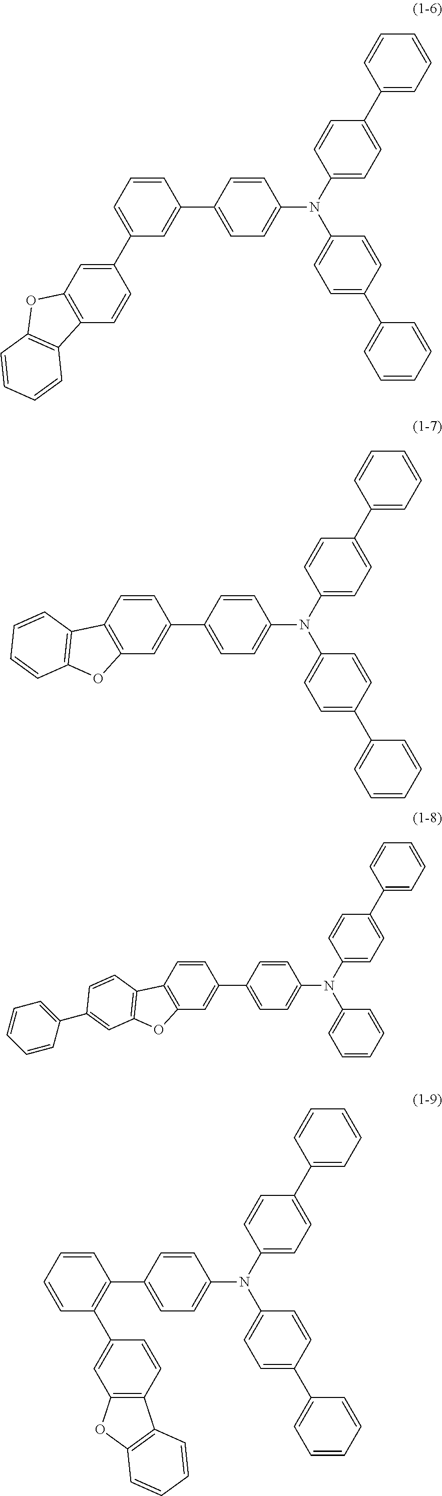

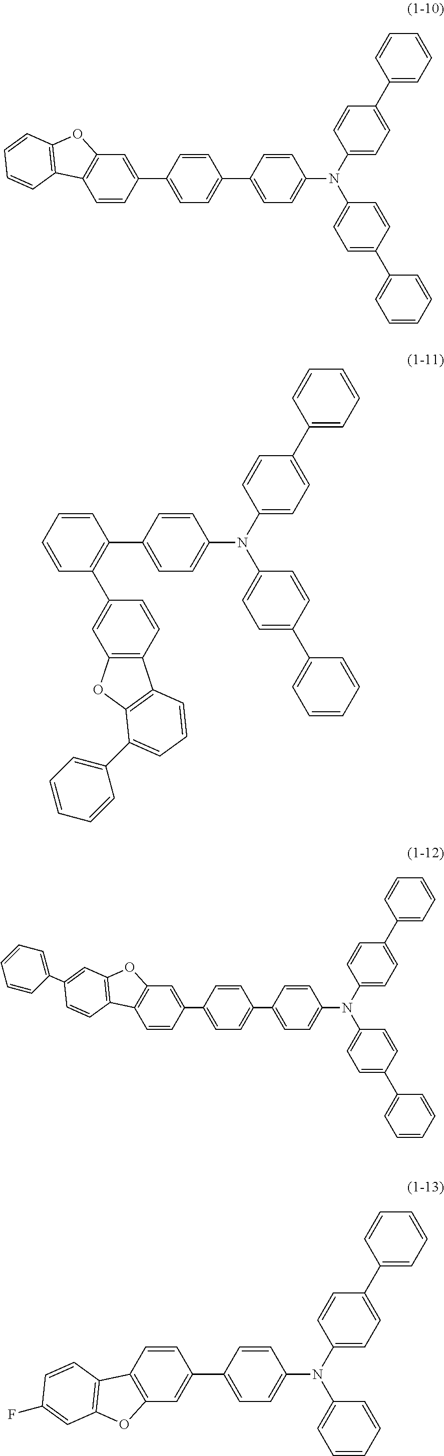 [SMILES: c1ccc(-c2ccc(N(c3ccc(-c4ccccc4)cc3)c3ccc(-c4ccc(-c5ccc6c(c5)oc5ccccc56)cc4)cc3)cc2)cc1 ; c1ccc(-c2ccc(N(c3ccc(-c4ccccc4)cc3)c3ccc(-c4ccccc4-c4ccc5c(c4)oc4c(-c6ccccc6)cccc45)cc3)cc2)cc1 ; c1ccc(-c2ccc(N(c3ccc(-c4ccccc4)cc3)c3ccc(-c4ccc(-c5ccc6c(c5)oc5cc(-c7ccccc7)ccc56)cc4)cc3)cc2)cc1 ; Fc1ccc2c(c1)oc1cc(-c3ccc(N(c4ccccc4)c4ccc(-c5ccccc5)cc4)cc3)ccc12]

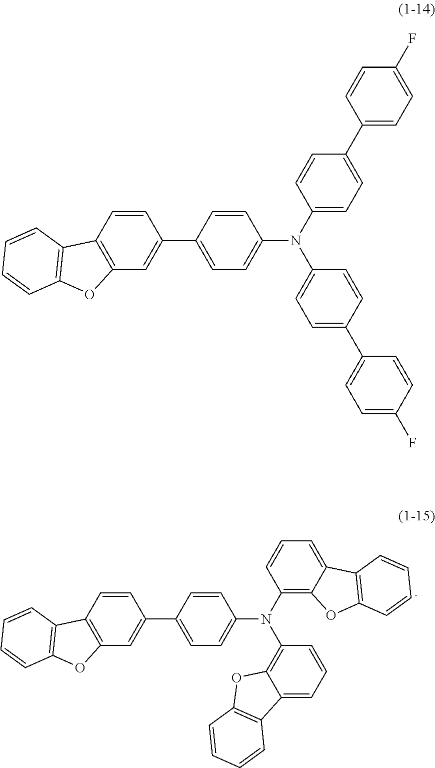 [SMILES: Fc1ccc(-c2ccc(N(c3ccc(-c4ccc(F)cc4)cc3)c3ccc(-c4ccc5c(c4)oc4ccccc45)cc3)cc2)cc1 ; c1ccc2c(c1)oc1cc(-c3ccc(N(c4cccc5c4oc4ccccc45)c4cccc5c4oc4ccccc45)cc3)ccc12]

### 1-1-4-3. Configuration of Third Hole Transport Layer

The third hole transport layer 143 may be positioned between the first hole transport layer 141 and the second hole transport layer 142. The third hole transport layer 143 may include at least one selected from the first hole transport material and the second hole transport material described herein. The second hole transport material may be represented by the following Formula 2. The properties of the organic EL device 100 may be improved by using the following compound represented by Formula 2 as the second hole transport material:

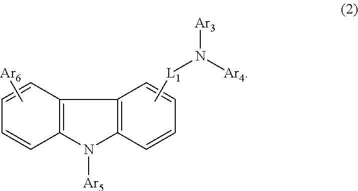

In Formula 2, Ar₃ to Ar₅ may each independently be selected from a substituted or unsubstituted aryl group and a substituted or unsubstituted heteroaryl group.

Non-limiting examples of Ar₃ to Ar₅ may include a phenyl group, a biphenyl group, a terphenyl group, a naphthyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quionoxalyl group, a benzoxazolyl group, a pyrazolyl group, a dibenzofuranyl group, a dibenzothienyl group, etc.

In some embodiments, Ar₃ to Ar₅ may include the phenyl group, the biphenyl group, the terphenyl group, the fluorenyl group, the dibenzofuranyl group, etc.

Ar₆ may be selected from a substituted or unsubstituted aryl group, a substituted or unsubstituted heteroaryl group, a carbazolyl group and an alkyl group. Examples of the aryl group and the heteroaryl group in Ar₆ may be the same as those described herein in connection with Ar₃ to Ar₅. For example, Ar₆ may be selected from a phenyl group, a biphenyl group, a terphenyl group, a fluorenyl group, a dibenzofuranyl group, and a carbazolyl group.

L₁ may be selected from a direct linkage, a substituted or unsubstituted arylene group and a substituted or unsubstituted heteroarylene group. As used herein, “direct linkage” may refer to a bond such as a single bond. Non-limiting examples of L₁ other than the direct linkage may include a phenylene group, a biphenylene group, a terphenylene group, a naphthylene group, an anthrylene group, a phenanthrylene group, a fluorenylene group, an indenylene group, a pyrenylene group, an acetonaphthenylene group, a fluoranthenylene group, a triphenylenylene group, a pyridylene group, a furanylene group, a pyranylene group, a thienylene group, a quinolylene group, an isoquinolylene group, a benzofuranylene group, a benzothienylene group, an indolylene group, a carbazolylene group, a benzoxazolylene group, a benzothiazolylene group, a quinoxaline group, a benzoimidazolylene group, a pyrazolylene group, a dibenzofuranylene group, a dibenzothienylene group. In some embodiments, L₁ may be selected from the phenylene group, the biphenylene group, the terphenylene group, the fluorenylene group, the carbazolylene group, the dibenzofuranylene group, etc.

The second hole transport material represented by Formula 2 may be one of compounds represented by the following Formulae 2-1 to 2-16. For example, the second hole transport material may be one selected from the group of compounds represented by Formulae 2-1 to 2-16:

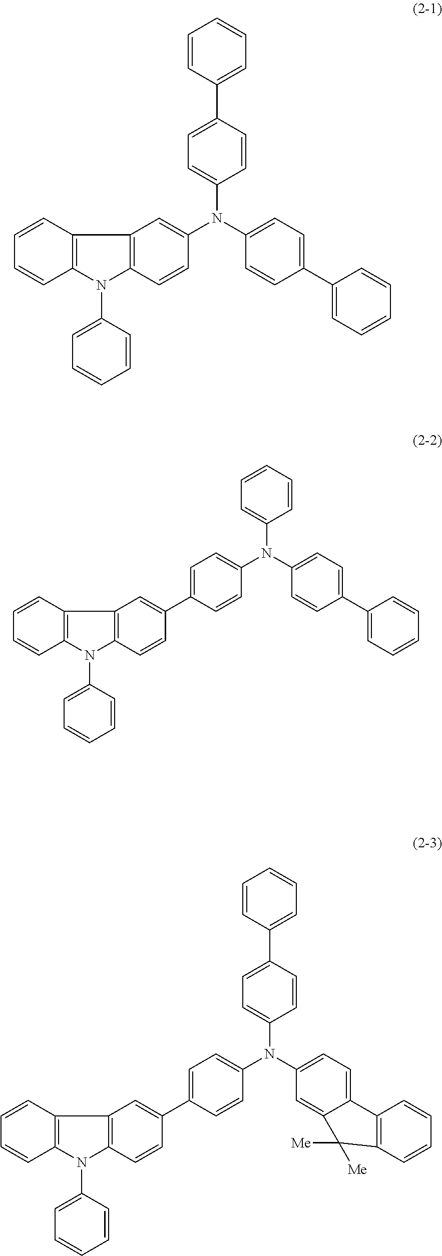 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

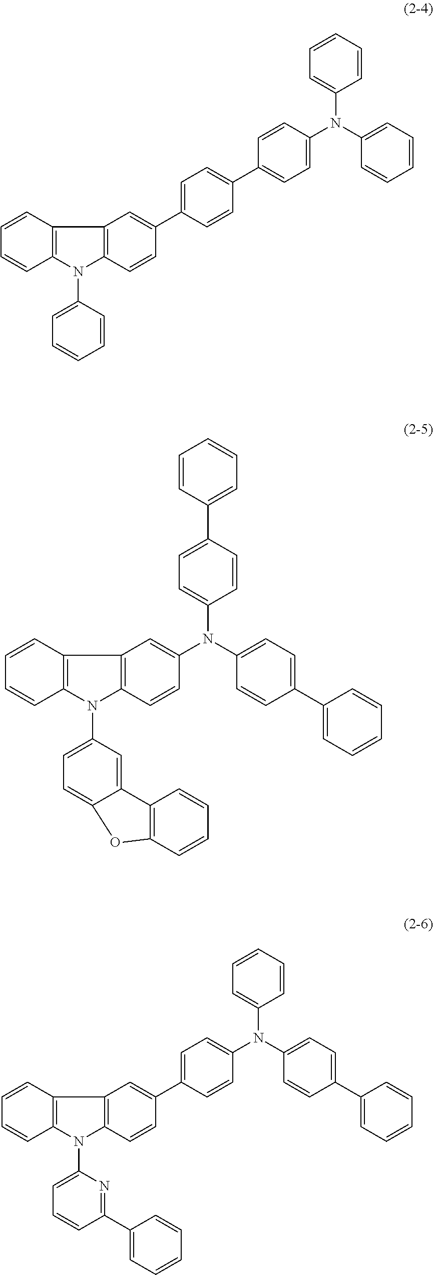 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

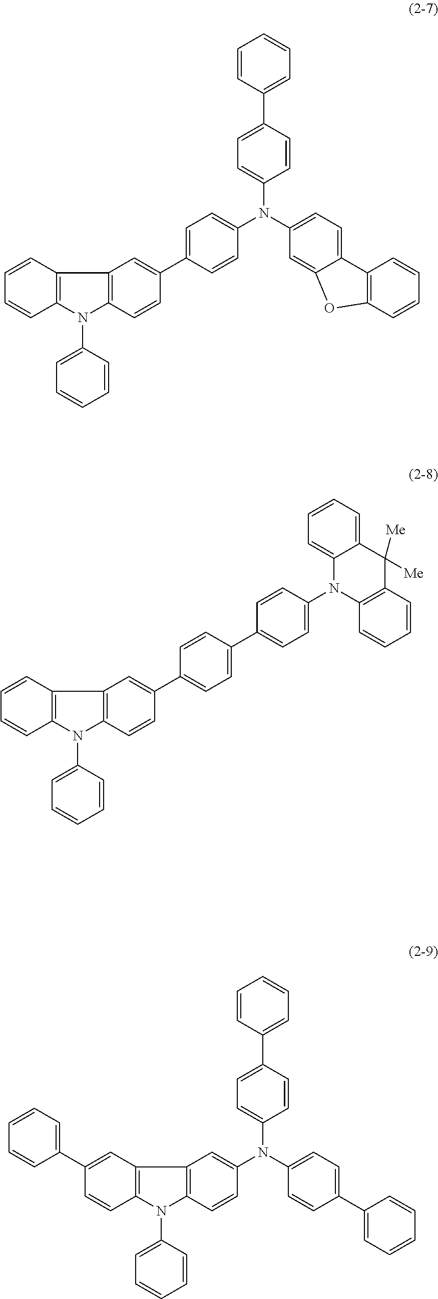 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

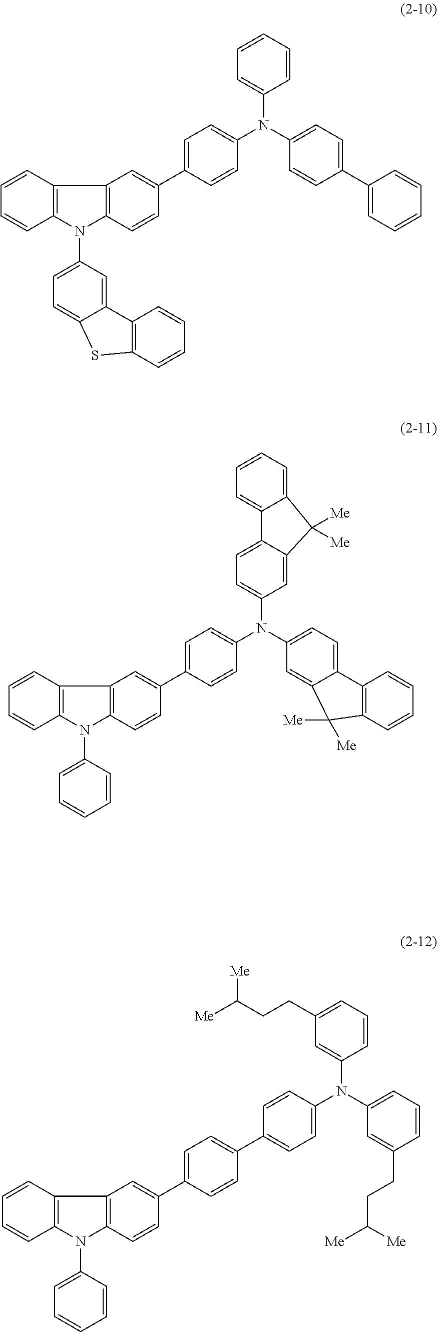 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

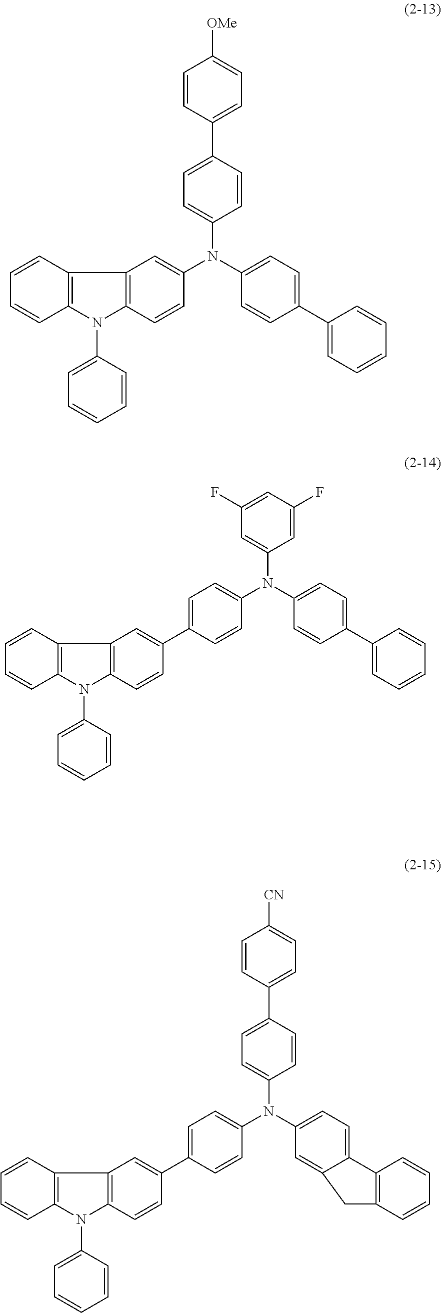 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

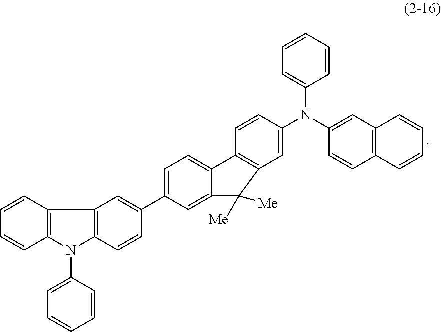 [SMILES: CC1(C)c2cc(-c3ccc4c(c3)c3ccccc3n4-c3ccccc3)ccc2-c2ccc(N(c3ccccc3)c3ccc4ccccc4c3)cc21]

The second hole transport material may be a hole transport material other than the above-mentioned compounds. Non-limiting examples of the second hole transport material may include 1,1-bis[(di-4-tolylamino)phenyl]cyclohexane (TAPC), a carbazole derivative (such as N-phenyl carbazole, polyvinyl carbazole, polyvinyl carbazole, etc.), N,N′-bis(3-methylphenyl)-N,N′-diphenyl-[1,1-biphenyl]-4,4′-diamine (TPD), 4,4′,4″-tris(N-carbazolyl)triphenylamine (TCTA), N,N′-di(1-naphthyl)-N,N′-diphenylbenzidine (NPB), etc. For example, the second hole transport material may be any suitable material capable of being used as the hole transport material of an organic EL device. In some embodiments, the second hole transport material may be represented by Formula 2.

### 1-1-4-4. Modification of Hole Transport Layer

In one or more embodiments, the hole transport layer 140 has a three-layered structure, however the configuration of the hole transport layer 140 is not limited thereto. For example, the hole transport layer 140 may have any suitable structure as long as the second hole transport layer 142 is positioned between the first hole transport layer 141 and the emission layer 150. For example, the third hole transport layer 143 may not be included as shown in FIG. 2. In some embodiments, the third hole transport layer 143 may be positioned between the first hole transport layer 141 and the first electrode 120. In some embodiments, the third hole transport layer 143 may be positioned between the second hole transport layer 142 and the emission layer 150. Each of the first to third hole transport layers 141 to 143 may be formed as a plurality of layers.

### 1-1-5. Configuration of Emission Layer

The emission layer 150 may emit light via fluorescence or phosphorescence. The emission layer 150 may include a host material and a dopant material as a luminescent material. The emission layer 150 may be formed to a thickness within a range of about 10 nm to about 60 nm.

The host material of the emission layer 150 may be represented by the following Formula 3:

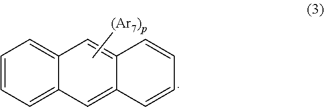

In Formula 3, each Ar₇ may be independently selected from hydrogen, deuterium, a substituted or unsubstituted alkyl group having 1 to 50 carbon atoms, a substituted or unsubstituted cycloalkyl group having 3 to 50 carbon atoms for forming a ring, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms for forming a ring, a substituted or unsubstituted arylthio group having 6 to 50 carbon atoms for forming a ring, a substituted or unsubstituted alkoxycarbonyl group having 2 to 50 carbon atoms, a substituted or unsubstituted aryl group having 6 to 50 carbon atoms for forming a ring, a substituted or unsubstituted heteroaryl group having 5 to 50 carbon atoms for forming a ring, a substituted or unsubstituted silyl group, a carboxyl group, a halogen atom, a cyano group, a nitro group and a hydroxyl group, and p may be an integer from 1 to 10.

The host material represented by Formula 3 may be represented by one of the following Formulae 3-1 to 3-12:

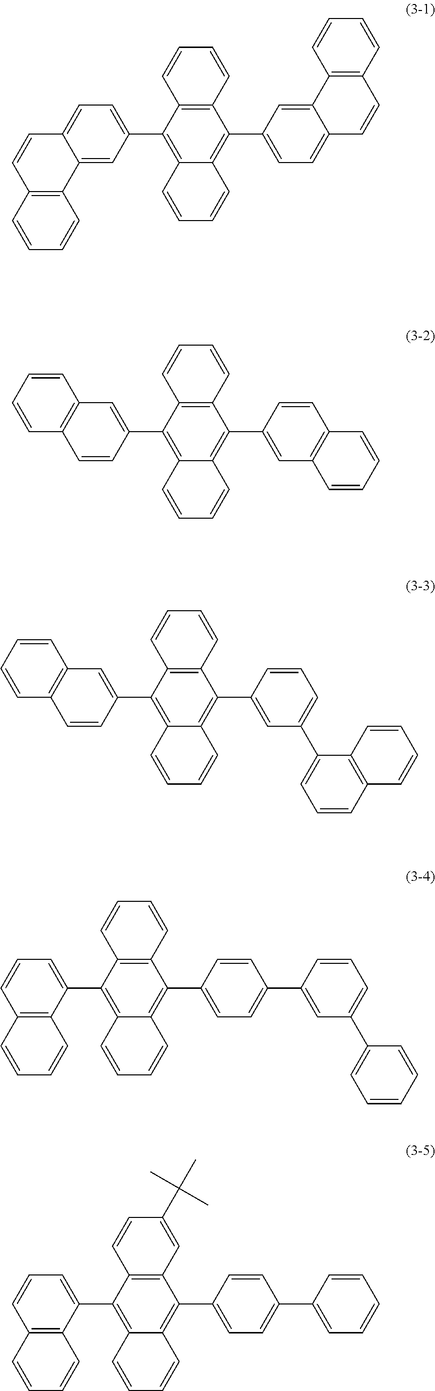

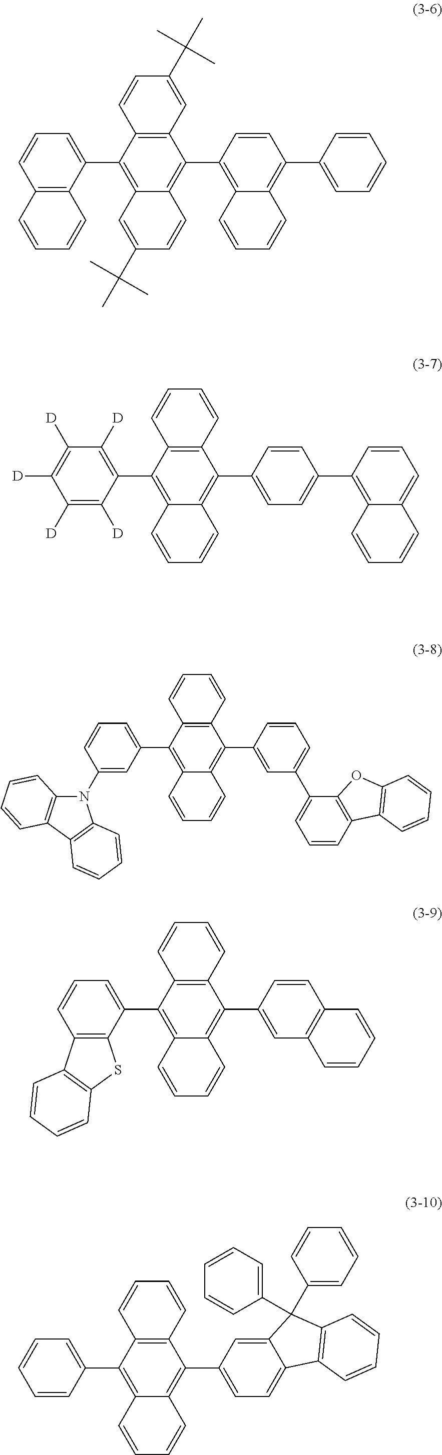

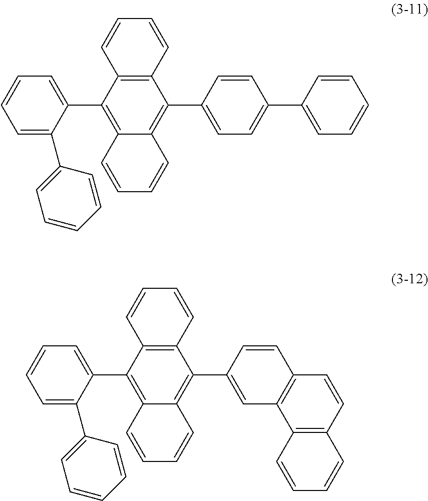

In some embodiments, the host material may be any suitable host material other than the above-mentioned compounds. Examples of such host material may include tris(8-quinolinolato)aluminum (Alq3), 4,4′-N,N′-dicarbazole-biphenyl (CBP), poly(n-vinylcarbazole) (PVK), 9,10-di(naphthalene-2-yl)anthracene (ADN), 4,4′,4″-tris(N-carbazolyl)triphenylamine (TCTA), 1,3,5-tris(N-phenylbenzimidazole-2-yl)benzene (TPBI), 3-tert-butyl-9,10-di(naphtho-2-yl)anthracene (TBADN), distyrylarylene (DSA), 4,4′-bis(9-carbazole)-2,2′-dimethyl-biphenyl (dmCBP), etc. For example, any suitable host material may be used as the host material of an organic EL device. In some embodiments, the host material may be a compound represented by Formula 3.

The emission layer 150 may be formed as an emission layer emitting light of a specific color. For example, the emission layer 150 may be formed as a red emitting layer, a green emitting layer or a blue emitting layer.

In embodiments where the emission layer 150 is a blue emitting layer, any suitable material may be used as a blue dopant. Non-limiting examples of the blue dopant may include perylene and derivatives thereof, an iridium (Ir) complex such as bis[2-(4,6-difluorophenyl)pyridinate]picolinate iridium(III) (Flrpic), etc.

In embodiments where the emission layer 150 is a red emitting layer, any suitable material may be used as a red dopant. Non-limiting examples of the red dopant may include rubrene and derivatives thereof, 4-dicyanomethylene-2-(p-dimethylaminostyryl)-6-methyl-4H-pyrane (DCM) and derivatives thereof, an iridium complex such as bis(1-phenylisoquinoline)(acetylacetonate) iridium(III) (Ir(piq)₂(acac), an osmium (Os) complex, a platinum complex, etc.

In embodiments where the emission layer 150 is a green emitting layer, any suitable material may be used as a green dopant. Non-limiting examples of the green dopant may include coumarin and derivatives thereof, an iridium complex such as tris(2-phenylpyridine) iridium(III) (Ir(ppy)₃), etc.

In one or more embodiments, the electron transport layer 160 may exhibit electron transporting functionality and may include an electron transport material. The electron transport layer 160 may be formed, for example, on the emission layer 150 to a thickness within a range of about 15 nm to about 50 nm. The electron transport layer 160 may be formed using any suitable electron transport material. Non-limiting examples of suitable electron transport materials may include a quinoline derivative such as tris(8-quinolinolato)aluminum (Alq3), a 1,2,4-triazole derivative (TAZ), bis(2-methyl-8-quinolinolato)-(p-phenylphenolate)-aluminum (BAlq), berylliumbis(benzoquinoline-10-olate) (BeBq2), a Li complex such as lithium quinolate (LiQ), etc.

In one or more embodiments, the electron injection layer 170 may facilitate the injection of electrons from the second electrode 180 and may be formed to a thickness within a range of about 0.3 nm to about 9 nm. The electron injection layer 170 may be formed using any suitable material, for example, lithium fluoride (LiF), sodium chloride (NaCl), cesium fluoride (CsF), lithium oxide (Li₂O), barium oxide (BaO), etc.

In one or more embodiments, the second electrode 180 may be a cathode. The second electrode 180 may be formed as a reflection type electrode (e.g., reflection electrode) using a metal, an alloy, a conductive compound, etc. having small work function. Non-limiting examples of the material used to form the second electrode 180 may include lithium (Li), magnesium (Mg), aluminum (Al), aluminum-lithium (Al—Li), calcium (Ca), magnesium-indium (Mg—In), magnesium-silver (Mg—Ag), etc. In some embodiments, the second electrode 180 may be formed as a transmission type electrode using ITO, IZO, etc. The second electrode 180 may be formed on the electron injection layer 170 using an evaporation method or a sputtering method.

### 1-1-6. Modification of Organic EL Device

As shown in FIG. 1, each layer other than the hole transport layer 140 may be formed as a single layer. However, embodiments of the present disclosure are not limited thereto and each of these layers may be formed as a multi-layered structure. A hole injection layer may be positioned between the hole transport layer 140 and the first electrode 120 in the organic EL device 100.

In one or more embodiments, the hole injection layer may facilitate the injection of holes from the first electrode 120. The hole injection layer may be formed, for example, on the first electrode 120 to a thickness within a range of about 10 nm to about 150 nm. The hole injection layer may be formed using any suitable material capable of being used for forming the hole injection layer, without specific limitation. Non-limiting example of the hole injection material may include a triphenylamine-containing polyether ketone (TPAPEK), 4-isopropyl-4′-methyldiphenyliodonium tetrakis(pentafluorophenyl)borate (PPBI), N,N′-diphenyl-N,N′-bis-[4-(phenyl-m-tolyl-amino)-phenyl]-biphenyl-4,4′-diamine (DNTPD), a phthalocyanine compound such as copper phthalocyanine, 4,4′,4″-tris(3-methylphenylphenylamino)triphenylamine (m-MTDATA), N,N′-di(1-naphthyl)-N,N′-diphenylbenzidine (NPB), 4,4′,4″-tris{N,N-diamino}triphenylamine (TDATA), 4,4′,4″-tris(N,N-2-naphthylphenylamino)triphenylamine (2-TNATA), polyaniline/dodecylbenzenesulfonic acid (Pani/DBSA), poly(3,4-ethylenedioxythiophene)/poly(4-styrenesulfonate) (PEDOT/PSS), polyaniline/camphorsulfonic acid (Pani/CSA), polyaniline/poly(4-styrenesulfonate (PANI/PSS), etc.

In one or more embodiments, the organic EL device 100 may not include at least one selected from the electron transport layer 160 and the electron injection layer 170.

### 1-2. EXAMPLES

Hereinafter, the organic EL device according to embodiments of the present disclosure will be described, referring to examples and comparative examples. However, the following embodiments are only for illustration, and the organic EL device according to example embodiments of the present disclosure is not limited thereto.

### 1-2-1. Synthesis of First Hole Transport Material

### Synthetic Example 1

### Synthesis of Compound 1-7

Compound 1-7 was synthesized by the following procedure.

Under an argon atmosphere, 4.2 g of 4-bis(biphenylyl)aminophenyl boronic acid pinacol ester, 2 g of 3-bromodibenzofuran, 0.1 g of tetrakis(triphenylphosphine)palladium(0), 3.3 g of potassium carbonate, 180 mL of tetrahydrofuran, and 20 mL of water were added to a 500 mL, three necked flask, followed by heating and refluxing the resulting mixture at about 80° C. for about 12 hours. After air cooling, water was added thereto, the organic layer was separated, and solvents were distilled. The solid thus obtained was separated by flash column chromatography to produce 3.6 g of the target product as a white solid (Yield 80%).

¹H-NMR (CDCl₃, δ in ppm, 300 MHz) of the target product reported chemical shift values of 7.98 (m, 2H), 7.79 (d, 1H), 7.52-7.63 (m, 12H), 7.44-7.48 (m, 5H), 7.25-7.39 (m, 9H). The mass spectrum of the target product was measured by Fast Atom Bombardment (FAB) method, and the peak mass number was 563 (M⁺, calculated 563.22). From these results, the target product was confirmed to be Compound 1-7.

### Synthetic Example 2

### Synthesis of Compound 1-1

Compound 1-1 was synthesized by performing a procedure similar to that described in Synthetic Example 1 for preparing Compound 1-7, except that 2.3 g of triphenylamine-4-boronic acid was used instead of 4.2 g of 4-bis(biphenylyl)aminophenyl boronic acid pinacol ester used in Synthetic Example 1. 3.0 g of the target product of a white solid was obtained (Yield 90%). The product was identified by NMR and mass spectrometry.

### Synthetic Example 3

### Synthesis of Compound 1-10

Compound 1-10 was synthesized by performing a procedure similar to that described in Synthetic Example 1 for preparing Compound 1-7, except that 4.8 g of 4-bis(biphenylyl)aminobiphenyl boronic acid pinacol ester was used instead of 4.2 g of 4-bis(biphenylyl)aminophenyl boronic acid pinacol ester used in Synthetic Example 1. 2.6 g of the target product of a white solid was obtained (Yield 51%). The product was identified by NMR and mass spectrometry.

### Synthetic Example 4

### Synthesis of Compound 1-13

Compound 1-13 was synthesized by the following procedure. Under an argon atmosphere, 3.6 g of 4-aminophenyl boronic acid pinacol ester, 4.2 g of 3-fluoro-3′-bromodibenzofuran, 0.2 g of tetrakis(triphenylphosphine)palladium(0), 6.6 g of potassium carbonate, 360 mL of tetrahydrofuran, and 40 mL of water were added to a 1 L, three necked flask, followed by heating and refluxing the resulting mixture at about 80° C. for about 12 hours. After air cooling, water was added thereto, the organic layer was separated, and solvents were distilled. The solid thus obtained was separated by flash column chromatography to produce 2.7 g of Intermediate 1 as a yellow solid (Yield 60%).

Under an argon atmosphere, 2.2 g of Intermediate 1, 1.9 g of 4-bromobiphenyl, 0.23 g of bis(dibenzylideneacetonato)palladium(0), 0.6 mL of a 2 M tri-tert-butylphosphine/L solution in toluene, 4.6 g of sodium tert-butoxide, and 100 mL of toluene were added to a 300 mL, three necked flask, followed by heating the resulting mixture at about 80° C. for about 4 hours. After air cooling, water was added thereto, the organic layer was separated, and solvents were distilled. The solid thus obtained was separated by flash column chromatography to produce 2.9 g of Intermediate 2 as a white solid (Yield 84%).

Under an argon atmosphere, 1.7 g of Intermediate 2, 0.7 g of 4-bromobenzene, 0.12 g of bis(dibenzylideneacetonato)palladium(0), 0.3 mL of a 2 M tri-tert-butylphosphine/L solution in toluene, 2.3 g of sodium tert-butoxide, and 50 mL of toluene were added to a 200 mL, three necked flask, followed by heating the resulting mixture at about 80° C. for about 4 hours. After air cooling, water was added thereto, the organic layer was separated, and solvents were distilled. The solid thus obtained was separated by flash column chromatography to produce 1.9 g of Compound 1-13 as a yellow solid (Yield 95%). The product was identified using NMR and mass spectrometry.

### Synthetic Example 5

### Synthesis of Compound 1-14

Compound 1-14 was synthesized by the following procedure. Under an argon atmosphere, 3.6 g of 4-aminophenyl boronic acid pinacol ester, 4.0 g of 3-bromodibenzofuran, 0.2 g of tetrakis(triphenylphosphine)palladium(0), 6.6 g of potassium carbonate, 360 mL of tetrahydrofuran, and 40 mL of water were added to a 1 L, three necked flask, followed by heating and refluxing the resulting mixture at about 80° C. for about 12 hours. After air cooling, water was added thereto, the organic layer was separated, and solvents were distilled. The solid thus obtained was separated by flash column chromatography to produce 3.0 g of Intermediate 3 as a yellow solid (Yield 73%).

Under an argon atmosphere, 1.6 g of Intermediate 3, 2.0 g of 4,4′-fluorobromobiphenyl, 0.23 g of bis(dibenzylideneacetonato)palladium(0), 0.6 mL of a 2 M tri-tert-butylphosphine/L solution in toluene, 2.3 g of sodium tert-butoxide, and 50 mL of toluene were added to a 200 mL, three necked flask, followed by heating the resulting mixture at about 80° C. for about 4 hours. After air cooling, water was added thereto, the organic layer was separated, and solvents were distilled. The solid thus obtained was separated by flash column chromatography to produce 2.0 g of Compound 1-14 as a white solid (Yield 91%). The product was identified using NMR and mass spectrometry.

### Synthetic Example 6

### Synthesis of Compound 1-15

Compound 1-15 was synthesized by the following procedure. Under an argon atmosphere, 1.6 g of Intermediate 3, 2.0 g of 4-bromodibenzofuran, 0.23 g of bis(dibenzylideneacetonato)palladium(0), 0.6 mL of a 2 M tri-tert-butylphosphine/L solution in toluene, 2.3 g of sodium tert-butoxide, and 50 mL of toluene were added to a 200 mL, three necked flask, followed by heating the resulting mixture at about 80° C. for about 4 hours. After air cooling, water was added thereto, the organic layer was separated, and solvents were distilled. The solid thus obtained was separated by flash column chromatography to produce 2.0 g of Compound 1-15 as a yellow solid (Yield 85%). The product was identified using NMR and mass spectrometry.

### 1-2-2. Manufacture of Organic EL Device

An organic EL device was manufactured as follows. First, an ITO-glass substrate patterned and washed in advance was subjected to surface treatment using UV-Ozone (O₃). The thickness of the ITO layer (first electrode) was about 150 nm. After ozone treatment, the substrate was washed and inserted in a glass bell jar-type evaporator (e.g., glass bell jar evaporator) for forming HTL1, HTL2, HTL3, an emission layer and an electron transport layer, one by one by evaporation under a vacuum of about 10⁻⁴ to about 10⁻⁵ Pa. The layer thicknesses of each of HTL1, HTL2 and HTL3 were about 10 nm. The thickness of the emission layer was about 25 nm, and the thickness of the electron transport layer was about 25 nm. Then, the substrate was moved into a glass bell jar type evaporator (e.g., glass bell jar evaporator) for forming a metal layer, and materials for the electron injection layer and the cathode were evaporated thereon under a vacuum of about 10⁻⁴ to about 10⁻⁵ Pa. The thickness of the electron injection layer was about 1.0 nm and the thickness of the second electrode was about 100 nm.

Here, “HTL1”, “HTL2” and “HTL3” refer to hole transport layers respectively formed using the materials as shown in Table 1. In Table 1, HTL1, HTL2, and HTL3 refer to the hole transport layers used as the first hole transport layer 141, the third hole transport layer 143, and the second hole transport layer 142, respectively. Compounds 6-1 to 6-3 may be represented by Formulae 6-1 to 6-3:

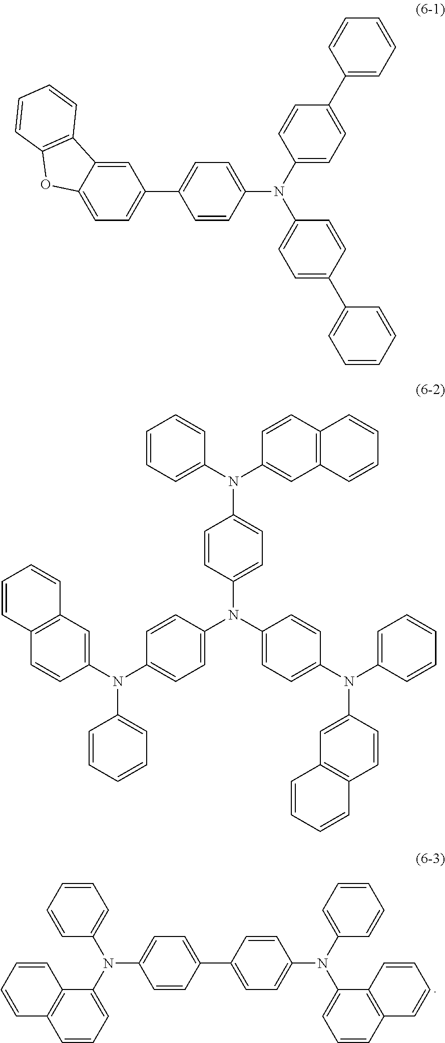 [SMILES: c1ccc(-c2ccc(N(c3ccc(-c4ccccc4)cc3)c3ccc(-c4ccc5oc6ccccc6c5c4)cc3)cc2)cc1 ; c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1]

The host material used in the emission layer was 9,10-di(2-naphthyl)anthracene (ADN, Compound 3-2). The dopant was 2,5,8,11-tetra-t-butylperylene (TBP). The amount of the dopant was about 3 wt % on the basis of the amount of the host. Alq3 was used as the electron transport material, and LiF was used as the electron injection material. Al was used as the second electrode material.

TABLE 1

| | | | | Driving | Emission | |
|---|---|---|---|---|---|---|
| | | | | voltage | efficiency | Life time |
| | HTL1 | HTL2 | HTL3 | [V] | [cd/A] | LT50 (h) |
| Example | Compound | Compound | Compound | 6.5 | 6.7 | 4,600 |
| 1-1 | 4-15 | 2-3 | 1-7 | | | |
| Example | Compound | Compound | Compound | 6.9 | 6.7 | 3,200 |
| 1-2 | 2-3 | 4-15 | 1-7 | | | |
| Example | Compound | Compound | Compound | 6.6 | 6.7 | 2,900 |
| 1-3 | 4-15 | 6-3 | 1-7 | | | |
| Example | Compound | Compound | Compound | 6.5 | 5.5 | 2,200 |
| 1-4 | 4-15 | 1-7 | 2-3 | | | |
| Example | Compound | Compound | Compound | 6.8 | 6.3 | 2,100 |
| 1-5 | 4-15 | 2-7 | 1-1 | | | |
| Example | Compound | Compound | Compound | 6.4 | 6.3 | 3,400 |
| 1-6 | 4-15 | 2-3 | 1-10 | | | |
| Example | Compound | Compound | Compound | 7.0 | 6.5 | 2,400 |
| 1-7 | 4-15 | 2-3 | 1-13 | | | |
| Example | Compound | Compound | Compound | 7.2 | 6.6 | 2,600 |
| 1-8 | 4-15 | 2-3 | 1-14 | | | |
| Example | Compound | Compound | Compound | 6.4 | 6.3 | 2,000 |
| 1-9 | 4-15 | 1-7 | 1-15 | | | |
| Example | Compound | Compound | Compound | 6.3 | 6.2 | 2,100 |
| 1-10 | 4-16 | 2-3 | 1-7 | | | |
| Example | Compound | Compound | Compound | 6.1 | 6.2 | 2,300 |
| 1-11 | 4-15 | 2-7 | 1-7 | | | |
| Example | Compound | Compound | Compound | 6.5 | 5.8 | 2,700 |
| 1-12* | 4-15 | 2-3 | 1-7 | | | |
| Example | Compound | Compound | Compound | 6.5 | 6.6 | 3,500 |
| 1-13** | 4-15 | 2-3 | 1-7 | | | |
| Example | Compound | Compound | Compound | 8.0 | 6.6 | 3,700 |
| 1-14 | 4-15 | 1-7 | 1-7 | | | |
| Comparative | Compound | Compound | Compound | 6.6 | 4.5 | 1,900 |
| Example 1-1 | 4-15 | 2-3 | 2-3 | | | |
| Comparative | Compound | Compound | Compound | 6.9 | 5.7 | 1,200 |
| Example 1-2 | 4-15 | 2-3 | 6-1 | | | |
| Comparative | Compound | Compound | Compound | 8.4 | 6.2 | 1,400 |
| Example 1-3 | 6-2 | 2-3 | 1-7 | | | |
| Comparative | Compound | Compound | Compound | 8.5 | 5.2 | 1,900 |
| Example 1-4 | 6-2 | 6-3 | 1-7 | | | |

*DPVBi was used as a host material in the emission layer.
**Compound 3-10 was used as a host material in the emission layer.

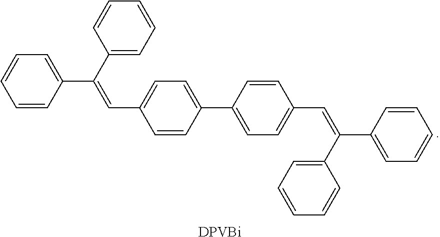 [SMILES: C(=C(c1ccccc1)c1ccccc1)c1ccc(-c2ccc(C=C(c3ccccc3)c3ccccc3)cc2)cc1 ; "DPVBi"]

In Example 1-1, HTL1 to HTL3 refer to the hole transport layers used as the first hole transport layer 141, the third hole transport layer 143, and the second hole transport layer 142, respectively. In Example 1-1, Compound 2-3 was used as a second hole transport material in the third hole transport layer 143. In Example 1-2, the stacking order of the first hole transport layer 141 and the third hole transport layer 143 was switched. As used herein, the statement “the stacking order . . . was switched” may refer to “the order in which materials were included in respective layers was switched, relative to the order used in the previous example configuration”. In Example 1-3, Compound 6-3 was used as a second hole transport material in the third hole transport layer 143. In Example 1-4, the stacking order of the second hole transport layer 142 and the third hole transport layer 143 was switched relative to Example 1-1.

In Examples 1-5 to 1-9, the compounds used in HTL3 were varied. In Examples 1-5 and 1-9, the materials forming HTL2 were also varied. In Example 1-10, Compound 4-16 was used as an electron accepting material in HTL1. In Example 1-11, the compound represented by Formula 2 used in HTL2 was changed relative to Example 1-10. In Example 1-12, HTL1 to HTL3 were substantially the same as in Example 1-1, except that DPVBi was used as a host material in the emission layer instead of ADN. In Example 1-13, HTL1 to HTL3 were substantially the same as in Example 1-1, except that Compound 3-10 was used as a host material in the emission layer instead of ADN. In Example 1-14, HTL2 and HTL3 were formed using substantially the same materials. Thus, Example 1-14 substantially corresponds to an example having a structure as shown in FIG. 2.

In Comparative Examples 1-1 and 1-2, HTL1 and HTL2 were substantially the same as in Example 1-1, and HTL3 included a second hole transport material instead of a first hole transport material as used in Example 1-1. In Comparative Example 1-1, Compound 2-3 was used as the second hole transport material in both the third hole transport layer 143 and the second hole transport layer 142. In Comparative Example 1-2, Compound 6-1 was used as a second hole transport material in the second hole transport layer 142.

In Comparative Example 1-3, HTL2 and HTL3 were substantially the same as in Example 1-1, and HTL1 included Compound 6-2 instead of Compound 4-15 used in Example 1-1. In Comparative Example 1-4, HTL1 and HTL3 were substantially the same as in Comparative Example 1-3, and HTL2 included Compound 6-3 instead of Compound 2-3 used in Comparative Example 1-3. That is, in Comparative Examples 1-3 and 1-4, the electron accepting material was not included in the hole transport layer 140.

### 1-2-3. Evaluation of Properties of Organic EL Device

In order to evaluate the properties of organic EL devices manufactured according to the examples and comparative examples, driving voltage, emission efficiency and half lifetime were measured. The driving voltage and the emission efficiency were measured at a current density of about 10 mA/cm². The initial luminance of the half lifetime (LT50) was about 1,000 cd/m². The measurement of luminance was conducted using a Keithley Instruments Co. 2400 series source meter, Color brightness photometer CS-200 (Konica Minolta holdings, measurement angle of) 1°, and LabVIEW8.2 (National Instruments Co., Ltd. in Japan) in a dark room. Evaluation results are shown in Table 1.

As shown in Table 1, longer lifetimes were obtained in Examples 1-1 to 1-4 than in Comparative Examples 1-1 to 1-4. In Examples 1-1, 1-4 and 1-9 to 1-13, the driving voltage was better (e.g., lower) than in Comparative Examples 1-1 to 1-4. In Examples 1-1 to 1-3, 1-6 to 1-9, 1-13 and 1-14, the emission efficiencies were better (e.g., higher) than in Comparative Examples 1-1 to 1-4. Without being bound by any particular theory, it is believed that the inclusion of a second hole transport layer 142 between the first hole transport layer 141 and the emission layer 150 increases of the lifetime of the organic EL device 100. For example, in Example 1-14, good evaluation results were obtained even though the third hole transport layer 143 was not provided.

Comparing Example 1-1 with Comparative Example 1-2 shows that all measured properties, including the driving voltage, emission efficiency and lifetime of the organic EL device 100 were improved when the material included in the second hole transport layer 142 was a compound in which an amine moiety was combined (e.g., coupled) at the position 3 of dibenzofuran. Comparing Example 1-1 with Example 1-2 shows that when the first hole transport layer 141 is adjacent to the first electrode 120, the driving voltage and the lifetime of the organic EL device may be improved. Comparing Example 1-1 with Example 1-3 shows that when the second hole transport material included in the third hole transport layer is a compound represented by Formula 2, the driving voltage and the lifetime of the organic EL device may be improved. Comparing Example 1-1 with Example 1-4 shows that when the second hole transport layer 142 is adjacent to the emission layer 150, the emission efficiency and the lifetime of the organic EL device may be improved.

When the first hole transport layer 141 according to embodiments of the present disclosure is positioned adjacent to the first electrode 120, the driving voltage of the organic EL device may decrease. When the second hole transport layer 142 according to embodiments of the present disclosure is positioned adjacent to the emission layer 150, the emission efficiency and the lifetime of the organic EL device may increase.

As described above, the lifetime of the organic EL device 100 may be improved by positioning the second hole transport layer 142 between the first hole transport layer 141 and the emission layer 150. In this and similar embodiments, such configuration may enable: (1) passivation of the hole transport layer 140 against electrons not consumed in the emission layer 150, (2) prevention or reduction of the diffusion of energy with an excited state generated (e.g., diffusion of excitons) from the emission layer 150 into the hole transport layer 140, and (3) control over the charge balance of the whole device, etc. It is believed that the above-mentioned effects may be obtained at least in part because the second hole transport layer 142 restrains or reduces the diffusion of the electron accepting material positioned adjacent to the first electrode 120 into the emission layer 150.

In some embodiments, Ar₁ and Ar₂ of the first hole transport material may be each independently a substituted or unsubstituted aryl group having 6 to 12 carbon atoms for forming a ring, and in this case, the emission efficiency and the lifetime of the organic EL device 100 may be further improved.

In some embodiments, the first hole transport material may be represented by one of Formulae 1-1 to 1-15, and in this case, the emission efficiency and the lifetime of the organic EL device 100 may be further improved.

In embodiments where the second hole transport material has a structure represented by Formula 2, the lifetime of the organic EL device 100 may be further improved.

In some embodiments, the electron accepting material may have a LUMO level within a range of about −9.0 eV to about −4.0 eV, and in this case, the lifetime of the organic EL device 100 may be further improved.

In some embodiments, the emission layer 150 may include a luminescent material having a structure represented by Formula 3, and in this case, the lifetime of the organic EL device 100 may be further improved.

In some embodiments, the second hole transport layer 142 may be adjacent to the emission layer 150, and in this case, the lifetime of the organic EL device 100 may be further improved.

In some embodiments, the first hole transport layer 141 may be adjacent to the anode (e.g., first electrode 120), and in this case, the lifetime of the organic EL device 100 may be further improved.

In some embodiments, the third hole transport layer 143 may be provided between the first hole transport layer 141 and the second hole transport layer 142, and in this case, the lifetime of the organic EL device 100 may be further improved.

### 2-1. CONFIGURATION OF AN ORGANIC EL DEVICE ACCORDING TO EMBODIMENTS OF THE PRESENT DISCLOSURE INCLUDING A FIRST HOLE TRANSPORT LAYER THAT INCLUDES A THIRD HOLE TRANSPORT MATERIAL AND ELECTRON ACCEPTING MATERIAL DOPED IN THE THIRD HOLE TRANSPORT MATERIAL

Hereinafter, an organic EL device including a first hole transport layer including a third hole transport material and an electron accepting material doped in the third hole transport material will be described.

According to embodiments of the present disclosure, the organic EL device including the first hole transport layer including the third hole transport material and the electron accepting material doped in the third hole transport material may include an anode, an emission layer, the first hole transport layer positioned between the anode and the emission layer, the first hole transport layer including the third hole transport material and the electron accepting material doped in the third hole transport material, and a second hole transport layer positioned between the first hole transport layer and the emission layer, the second hole transport layer including a fourth hole transport material represented by Formula 1.

The organic EL device including the first hole transport layer including the third hole transport material and the electron accepting material doped in the third hole transport material may have the same (or substantially the same) configuration as the organic EL device described above that includes the first hole transport layer containing electron accepting material, for example, the same configuration of a substrate, the same configuration of a first electrode, the same configuration of an emission layer, the same configuration of an electron transport layer, the same configuration of an electron injection layer, and the same configuration of a second electrode, the same method of manufacturing the organic EL device, and the same modification examples thereof, except for the configuration of a hole transport layer. Hereinafter, the configuration of the hole transport layer according to the present embodiment will be explained in more detail.

### (2-1-1. Configuration of Hole Transport Layer)

The hole transport layer 140 may include a hole transport material having hole transporting functionality. The hole transport layer 140 may be formed, for example, on a hole injection layer to a thickness (e.g., total layer thickness of the stacked structure) of about 10 nm to about 150 nm. In one or more embodiments, the hole transport layer 140 of the organic EL device may include a first hole transport layer 141, a second hole transport layer 142 and a third hole transport layer 143. The ratio of the thicknesses of the hole transport layers is not specifically limited.

### (2-1-1-1. Configuration of First Hole Transport Layer)

The first hole transport layer 141 may be positioned adjacent to the first electrode 120. The first hole transport layer 141 may include a third hole transport material and an electron accepting material doped in the third hole transport material.

The third hole transport material may be represented by the following Formula 2. As described in the following examples, the properties of the organic EL device 100 may be improved by using the third hole transport material represented by the following Formula 2 in the first hole transport layer:

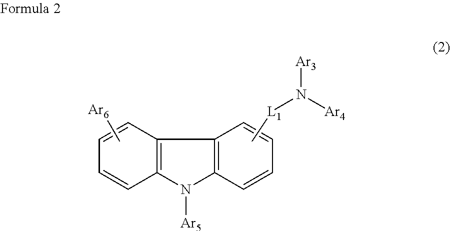

In Formula 2, Ar₃ to Ar₅ may be each independently selected from a substituted or unsubstituted aryl group and a substituted or unsubstituted heteroaryl group. Non-limiting examples of Ar₃ to Ar₅ may include a phenyl group, a biphenyl group, a terphenyl group, a naphthyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quionoxalyl group, a benzoxazolyl group, a pyrazolyl group, a dibenzofuranyl group, a dibenzothienyl group, etc. In some embodiments, Ar₃ to Ar₅ may be selected from the phenyl group, the biphenyl group, the terphenyl group, the fluorenyl group, the dibenzofuranyl group, etc.

Ar₆ may be selected from a substituted or unsubstituted aryl group, a substituted or unsubstituted heteroaryl group, a carbazolyl group and an alkyl group. Examples of the aryl group and the heteroaryl group used in Ar₆ may include the same moieties as those described herein in connection with Ar₃ to Ar₅. In some embodiments, Ar₆ may include a phenyl group, a biphenyl group, a terphenyl group, a fluorenyl group, a dibenzofuranyl group and/or a carbazolyl group.

L₁ may be selected from a direct linkage, a substituted or unsubstituted arylene group and a substituted or unsubstituted heteroarylene group. Non-limiting examples of L₁ may include a phenylene group, a biphenylene group, a terphenylene group, a naphthylene group, an anthrylene group, a phenanthrylene group, a fluorenylene group, an indenylene group, a pyrenylene group, an acetonaphthenylene group, a fluoranthenylene group, a triphenylenylene group, a pyridylene group, a furanylene group, a pyranylene group, a thienylene group, a quinolylene group, an isoquinolylene group, a benzofuranylene group, a benzothienylene group, an indolylene group, a carbazolylene group, a benzoxazolylene group, a benzothiazolylene group, a quinoxaline group, a benzoimidazolylene group, a pyrazolylene group, a dibenzofuranylene group, a dibenzothienylene group, etc. In some embodiments, L₁ may be selected from the phenylene group, the biphenylene group, the terphenylene group, the fluorenylene group, the carbazolylene group, the dibenzofuranylene group, etc. The third hole transport material represented by Formula 2 may be a compound represented by the following Formulae 2-1 to 2-16. However, the third hole transport material is not limited thereto:

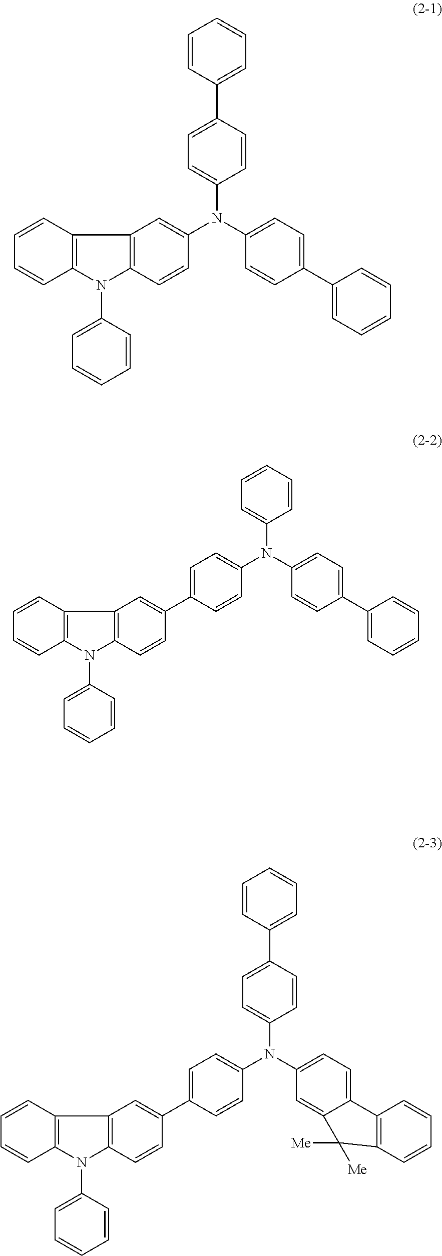 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

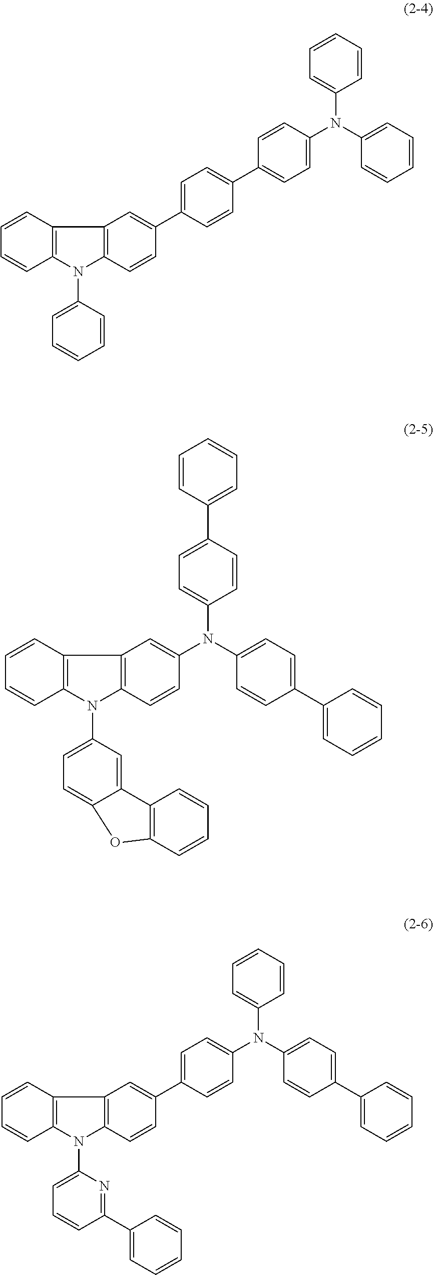 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

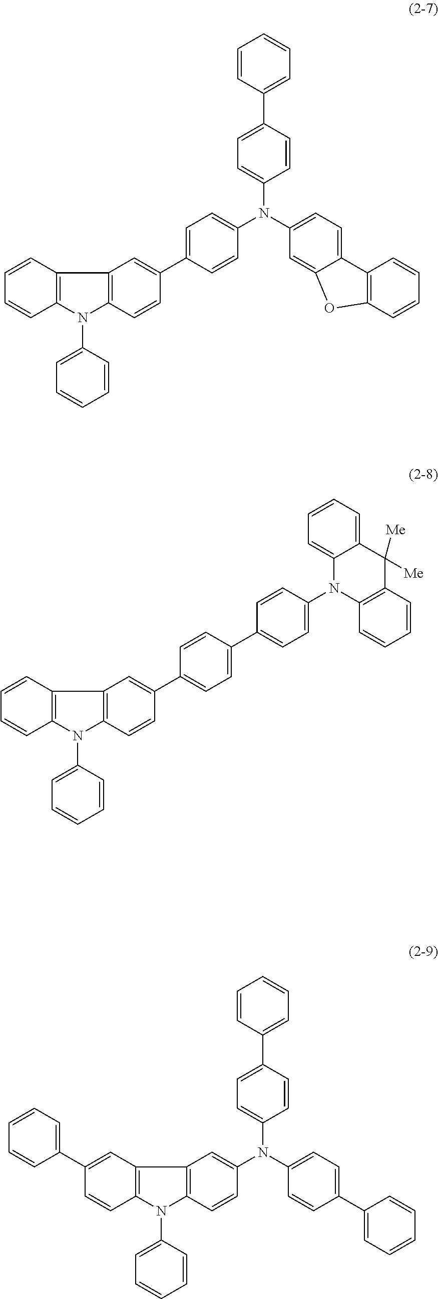 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

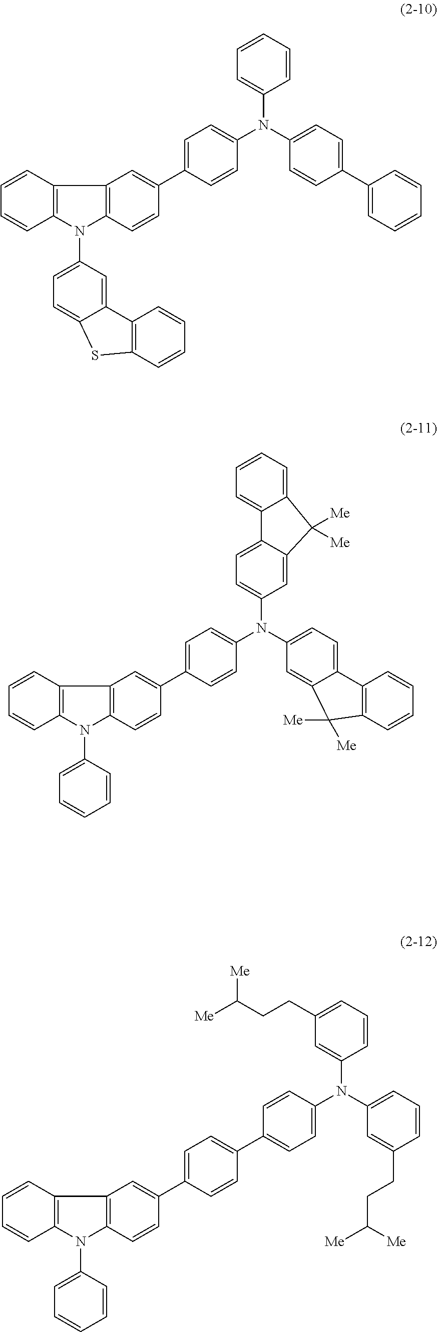 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

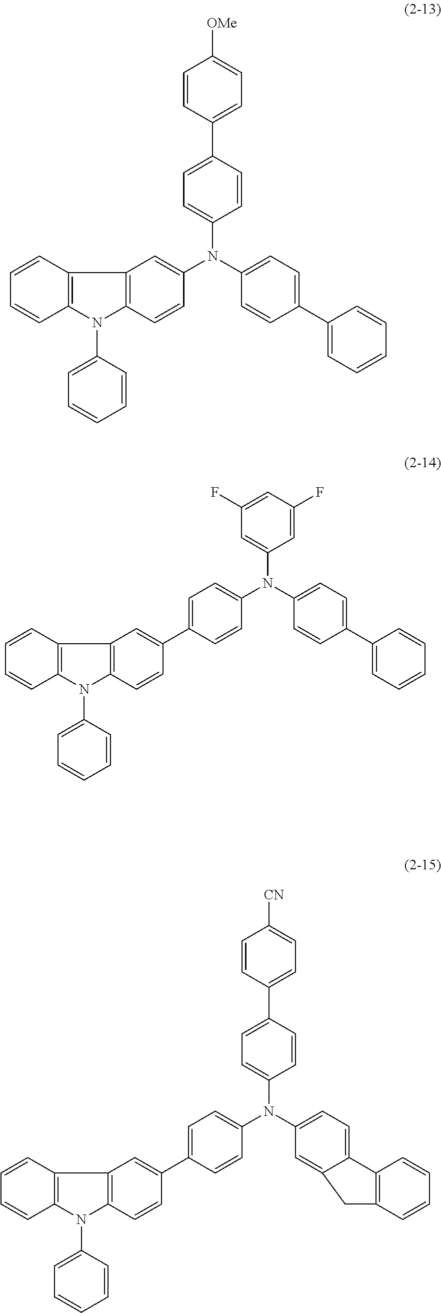 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

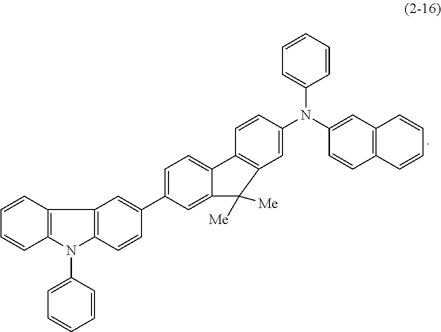 [SMILES: CC1(C)c2cc(-c3ccc4c(c3)c3ccccc3n4-c3ccccc3)ccc2-c2ccc(N(c3ccccc3)c3ccc4ccccc4c3)cc21]

The third hole transport material may be any suitable hole transport material, other than the compounds represented in Formulae 2-1 to 2-16. The third hole transport material may be, for example, 1,1-bis[(di-4-tolylamino)phenyl]cyclohexane (TAPC), a carbazole derivative such as N-phenyl carbazole and polyvinyl carbazole, N,N′-bis(3-methylphenyl)-N,N′-diphenyl-[1,1-biphenyl]-4,4′-diamine (TPD), 4,4′,4″-tris(N-carbazolyl)triphenylamine (TCTA), N,N′-di(1-naphthyl)-N,N′-diphenylbenzidine (NPB), etc. For example, the third hole transport material may be any suitable material capable of being used as the hole transport material of an organic EL device. In some embodiments, the third hole transport material may be represented by Formula 2.

The electron accepting material may be any suitable electron accepting material capable of being used in an organic EL device, and may have a LUMO level within a range of about −9.0 eV to about −4.0 eV, for example, within a range from about −6.0 eV to about −4.0 eV. The electron accepting material having a LUMO level within the range of about −9.0 eV to about −4.0 eV may be represented by the following Formulae 4-1 to 4-14:

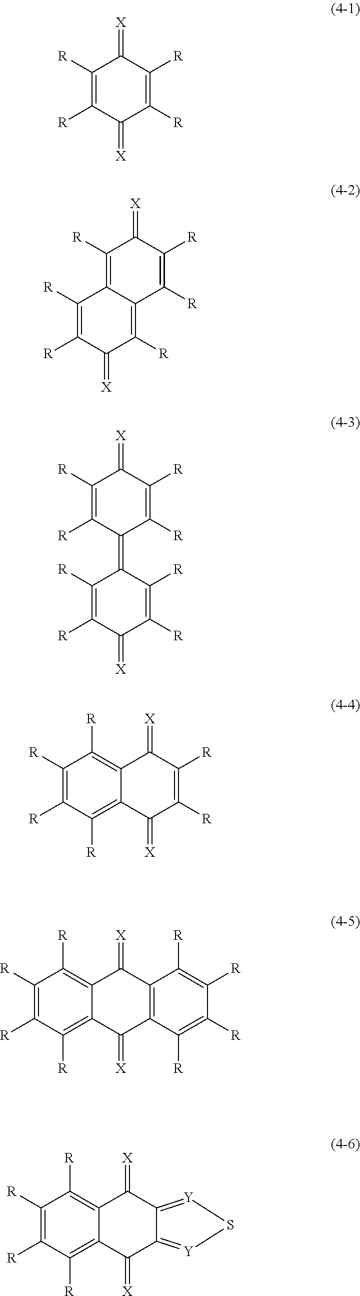

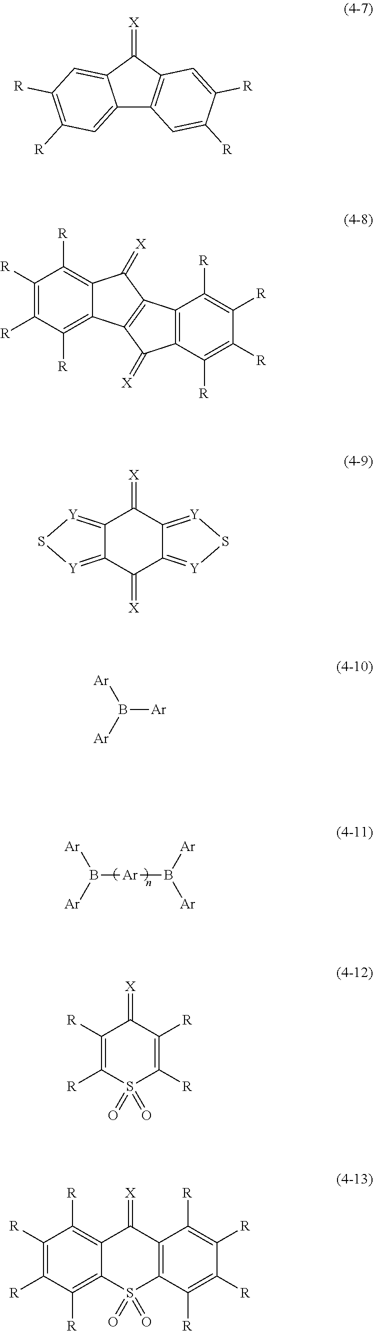

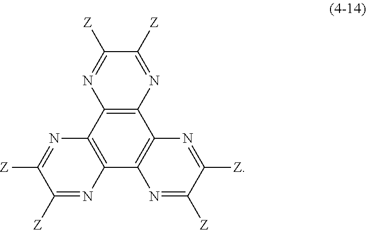

In Formulae 4-1 to 4-14, R may be selected from hydrogen, deuterium, a halogen atom, a fluoroalkyl group having 1 to 50 carbon atoms, a cyano group, an alkoxy group having 1 to 50 carbon atoms, an alkyl group having 1 to 50 carbon atoms, an aryl group having 6 to 50 carbon atoms for forming a ring, and a heteroaryl group having 5 to 50 carbon atoms for forming a ring. Ar may be selected from a substituted aryl group with an electron withdrawing group, an unsubstituted aryl group having 6 to 50 carbon atoms for forming a ring, and a substituted or unsubstituted heteroaryl group having 5 to 50 carbon atoms for forming a ring. Y may be selected from a carbon atom (—CH═) and a nitrogen atom (—N═). Z may be a pseudohalogen (e.g., a pseudohalogen group) or may include sulfur (S) (e.g., Z may be a sulfur-containing group). In addition, n may be an integer from 1 to 10. X may be represented by one of the following Formulae X₁ to X₇:

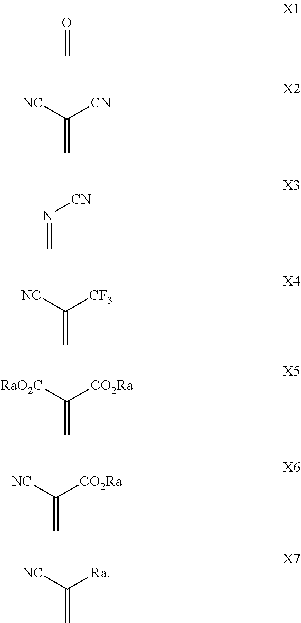

In Formulae X₁ to X₇, Ra may be selected from hydrogen, deuterium, a halogen atom, a fluoroalkyl group having 1 to 50 carbon atoms, a cyano group, an alkoxy group having 1 to 50 carbon atoms, an alkyl group having 1 to 50 carbon atoms, a substituted or unsubstituted aryl group having 6 to 50 carbon atoms for forming a ring and a substituted or unsubstituted heteroaryl group having 5 to 50 carbon atoms for forming a ring.

Non-limiting examples of the substituted or unsubstituted aryl group having 6 to 50 carbon atoms for forming a ring and the substituted or unsubstituted heteroaryl group having 5 to 50 carbon atoms for forming a ring represented, for example, by R, Ar and/or Ra may include a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenyl group, a 3-biphenyl group, a 4-biphenyl group, a p-terphenyl-4-yl group, a p-terphenyl-3-yl group, a p-terphenyl-2-yl group, an m-terphenyl-4-yl group, an m-terphenyl-3-yl group, an m-terphenyl-2-yl group, an o-tolyl group, an m-tolyl group, a p-tolyl group, a p-t-butylphenyl group, a p-(2-phenylpropyl)phenyl group, a 3-methyl-2-naphthyl group, a 4-methyl-1-naphthyl group, a 4-methyl-1-anthryl group, a 4′-methylbiphenylyl group, a 4″-t-butyl-p-terphenyl-4-yl group, a fluoranthenyl group, a fluorenyl group, a 1-pyrrolyl group, a 2-pyrrolyl group, a 3-pyrrolyl group, a pyridinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a quinolyl group, a 3-quinolyl group, a 4-quinolyl group, a 5-quinolyl group, a 6-quinolyl group, a 7-quinolyl group, an 8-quinolyl group, a 1-isoquinolyl group, a 3-isoquinolyl group, a 4-isoquinolyl group, a 5-isoquinolyl group, a 6-isoquinolyl group, a 7-isoquinolyl group, an 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, an 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthroline-2-yl group, a 1,7-phenanthroline-3-yl group, a 1,7-phenanthroline-4-yl group, a 1,7-phenanthroline-5-yl group, a 1,7-phenanthroline-6-yl group, a 1,7-phenanthroline-8-yl group, a 1,7-phenanthroline-9-yl group, a 1,7-phenanthroline-10-yl group, a 1,8-phenanthroline-2-yl group, a 1,8-phenanthroline-3-yl group, a 1,8-phenanthroline-4-yl group, a 1,8-phenanthroline-5-yl group, a 1,8-phenanthroline-6-yl group, a 1,8-phenanthroline-7-yl group, a 1,8-phenanthroline-9-yl group, a 1,8-phenanthroline-10-yl group, a 1,9-phenanthroline-2-yl group, a 1,9-phenanthroline-3-yl group, a 1,9-phenanthroline-4-yl group, a 1,9-phenanthroline-5-yl group, a 1,9-phenanthroline-6-yl group, a 1,9-phenanthroline-7-yl group, a 1,9-phenanthroline-8-yl group, a 1,9-phenanthroline-10-yl group, a 1,10-phenanthroline-2-yl group, a 1,10-phenanthroline-3-yl group, a 1,10-phenanthroline-4-yl group, a 1,10-phenanthroline-5-yl group, a 2,9-phenanthroline-1-yl group, a 2,9-phenanthroline-3-yl group, a 2,9-phenanthroline-4-yl group, a 2,9-phenanthroline-5-yl group, a 2,9-phenanthroline-6-yl group, a 2,9-phenanthroline-7-yl group, a 2,9-phenanthroline-8-yl group, a 2,9-phenanthroline-10-yl group, a 2,8-phenanthroline-1-yl group, a 2,8-phenanthroline-3-yl group, a 2,8-phenanthroline-4-yl group, a 2,8-phenanthroline-5-yl group, a 2,8-phenanthroline-6-yl group, a 2,8-phenanthroline-7-yl group, a 2,8-phenanthroline-9-yl group, a 2,8-phenanthroline-10-yl group, a 2,7-phenanthroline-1-yl group, a 2,7-phenanthroline-3-yl group, a 2,7-phenanthroline-4-yl group, a 2,7-phenanthroline-5-yl group, a 2,7-phenanthroline-6-yl group, a 2,7-phenanthroline-8-yl group, a 2,7-phenanthroline-9-yl group, a 2,7-phenanthroline-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-phenoxazinyl group, a 2-phenoxazinyl group, a 3-phenoxazinyl group, a 4-phenoxazinyl group, a 10-phenoxazinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, a 2-methylpyrrole-1-yl group, a 2-methylpyrrole-3-yl group, a 2-methylpyrrole-4-yl group, a 2-methylpyrrole-5-yl group, a 3-methylpyrrole-1-yl group, a 3-methylpyrrole-2-yl group, a 3-methylpyrrole-4-yl group, a 3-methylpyrrole-5-yl group, a 2-t-butylpyrrole-4-yl group, a 3-(2-phenylpropyl)pyrrole-1-yl group, a 2-methyl-1-indolyl group, a 4-methyl-1-indolyl group, a 2-methyl-3-indolyl group, a 4-methyl-3-indolyl group, a 2-t-butyl-1-indolyl group, a 4-t-butyl-1-indolyl group, a 2-t-butyl-3-indolyl group, a 4-t-butyl-3-indolyl group, etc.

Non-limiting examples of the fluoroalkyl group in the substituted or unsubstituted fluoroalkyl group having 1 to 50 carbon atoms represented, for example, by R and/or Ra may include a perfluoroalkyl group (such as a trifluoromethyl group, a pentafluoroethyl group, a heptafluoropropyl group and/or a heptadecafluorooctane group), a monofluoromethyl group, a difluoromethyl group, a trifluoroethyl group, a tetrafluoropropyl group, an octafluoropentyl group, etc.

Non-limiting examples of the substituted or unsubstituted alkyl group having 1 to 50 carbon atoms represented, for example, by R and/or Ra may include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, an 1,2,3-trinitropropyl group, a cyclopropyl group, a cyclobutyl group, a cyclopentyl group, a cyclohexyl group, a 4-methylcyclohexyl group, a 1-adamantyl group, a 2-adamantyl group, a 1-norbornyl group, a 2-norbornyl group, etc.

The substituted or unsubstituted alkoxy group having 1 to 50 carbon atoms represented, for example, by R and/or Ra may be a group represented by OY. Non-limiting examples of Y may include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, etc. Non-limiting examples of the halogen atom represented, for example, by R and/or Ra may include fluorine, chlorine, bromine, iodine, etc.

Non-limiting examples of the electron accepting material may include compounds represented by the following Formulae 4-15 and 4-16. The LUMO level of Compound 4-15 is about −4.40 eV, and the LUMO level of Compound (4-16) is about −5.20 eV.

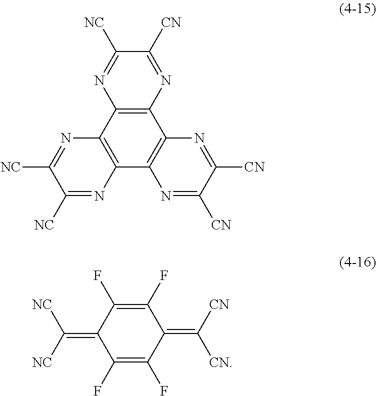 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

The doping amount of the electron accepting material within the hole transport material is not specifically limited. In some embodiments, the doping amount of the electron accepting material may be from about 0.1 wt % to about 50 wt % on the basis of the total amount of the third hole transport material, for example, from about 0.5 wt % to about 5 wt %.

### (2-1-1-2. Configuration of Second Hole Transport Layer)

The second hole transport layer 142 may be positioned adjacent to the emission layer 150. The second hole transport layer 142 may include a fourth hole transport material. The fourth hole transport material may be represented by the following Formula 1:

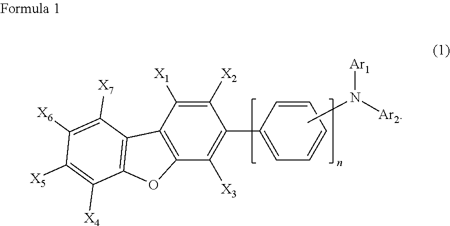

In Formula 1, Ar₁ and Ar₂ may be each independently selected from a substituted or unsubstituted aryl group having 6 to 12 carbon atoms for forming a ring and a substituted or unsubstituted heteroaryl group having 5 to 13 carbon atoms for forming a ring. Ar₁ and Ar₂ may each independently be a substituted or unsubstituted aryl group having 6 to 12 carbon atoms for forming a ring. Non-limiting examples of substituents of Ar₁ and Ar₂ may include a fluoro group, a chloro group, an alkyl group having 12 and less carbon atoms, a fluoroalkyl group having 12 and less carbon atoms, a cycloalkyl group, an acetyl group, an arylester group, an arylsulfide group, etc.

Non-limiting examples of the substituted or unsubstituted aryl group having 6 to 12 carbon atoms for forming a ring may include a phenyl group, a biphenylyl group, a 1-naphthyl group, a 2-naphthyl group, a fluorophenyl group, a difluorophenyl group, a trifluorophenyl group, a tetrafluorophenyl group, a pentafluorophenyl group, a tolyl group, a nitrophenyl group, a cyanophenyl group, a fluorobiphenylyl group, a nitrobiphenylyl group, a cyanobiphenyl group, a cyanonaphthyl group, a nitronaphthyl group, a fluoronaphthyl group, etc. In some embodiments, the phenyl group, the biphenylyl group, the naphthyl group, the fluorophenyl group, etc. may be included, and in some embodiments, the phenyl group and/or the biphenylyl group may be included.

Non-limiting examples of the substituted or unsubstituted heteroaryl group having 5 to 13 carbon atoms for forming a ring may include a dibenzofuranyl group, a dibenzothiophenyl group, a pyridyl group, a quinolyl group, an isoquinolyl group, a pyrazyl group, a pyrimidinyl group, a triazine group, an imidazolyl group, an acridinyl group, a carbazolyl group, etc.

X₁ to X₇ may each independently be selected from hydrogen, deuterium, a halogen atom, an alkyl group having 1 to 15 carbon atoms, a substituted or unsubstituted aryl group having 6 to 18 carbon atoms for forming a ring, and a substituted or unsubstituted heteroaryl group having 5 to 18 carbon atoms for forming a ring, and a may be 1 or 2.

Non-limiting examples of the alkyl group having 1 to 15 carbon atoms may include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, a cyclopropyl group, a cyclobutyl group, a cyclopentyl group, a cyclohexyl group, a 4-methylcyclohexyl group, a 1-adamantyl group, a 2-adamantyl group, a 1-norbornyl group, a 2-norbornyl group, etc.

Non-limiting examples of the substituted or unsubstituted aryl group having 6 to 18 carbon atoms for forming a ring may include a phenyl group, a biphenylyl group, an 1-naphthyl group, a 2-naphthyl group, a fluorophenyl group, a difluorophenyl group, a trifluorophenyl group, a tetrafluorophenyl group, a pentafluorophenyl group, a tolyl group, a nitrophenyl group, a cyanophenyl group, a fluorobiphenylyl group, a nitrobiphenylyl group, a cyanobiphenyl group, a cyanonaphthyl group, a nitronaphthyl group, a fluoronaphthyl group, a phenanthryl group, a terphenyl group, a fluoroterphenyl group, etc.

Non-limiting examples of the substituted or unsubstituted heteroaryl group having 5 to 18 carbon atoms for forming a ring may include a dibenzofuranyl group, a dibenzothiophenyl group, a pyridyl group, a quinolyl group, an isoquinolyl group, a pyrazyl group, a pyrimidinyl group, a triazine group, an imidazolyl group, an acridinyl group, etc.

As described above, the fourth hole transport material may have a structure in which an amine moiety is combined (e.g., coupled) at position 3 of dibenzofuran. As explained in the following embodiments, similar effects may not be obtained if the amine is combined (e.g., coupled) at another position of the dibenzofuran (for example, at position 2).

Non-limiting examples of the fourth hole transport material may include the following, compounds represented by the Formulae 1-1 to 1-15:

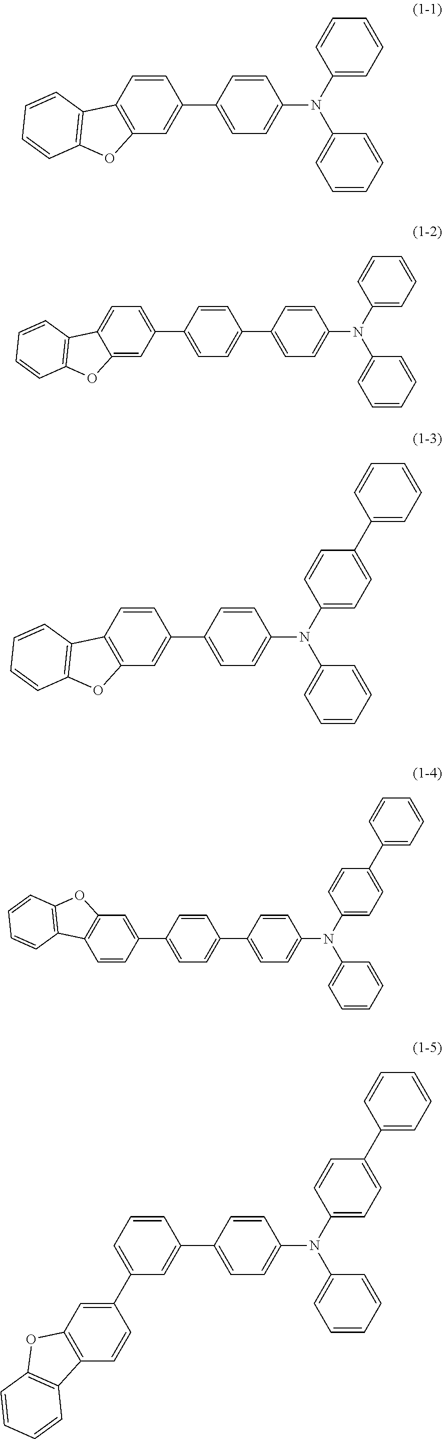 [SMILES: c1ccc(N(c2ccccc2)c2ccc(-c3ccc4c(c3)oc3ccccc34)cc2)cc1 ; c1ccc(N(c2ccccc2)c2ccc(-c3ccc(-c4ccc5c(c4)oc4ccccc45)cc3)cc2)cc1 ; c1ccc(-c2ccc(N(c3ccccc3)c3ccc(-c4ccc5c(c4)oc4ccccc45)cc3)cc2)cc1 ; c1ccc(-c2ccc(N(c3ccccc3)c3ccc(-c4ccc(-c5ccc6c(c5)oc5ccccc56)cc4)cc3)cc2)cc1 ; c1ccc(-c2ccc(N(c3ccccc3)c3ccc(-c4cccc(-c5ccc6c(c5)oc5ccccc56)c4)cc3)cc2)cc1]

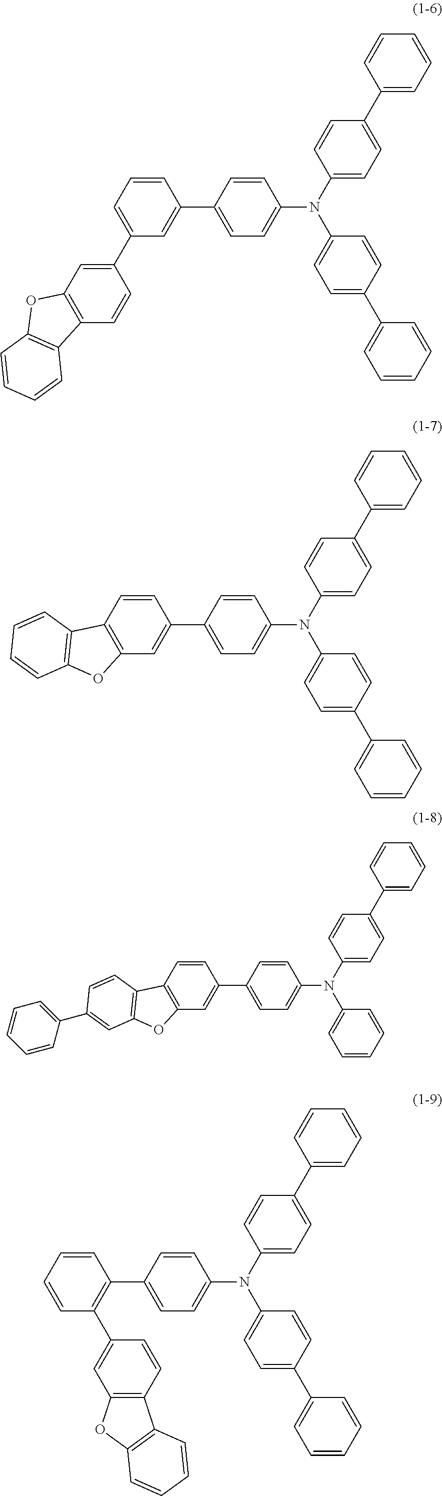

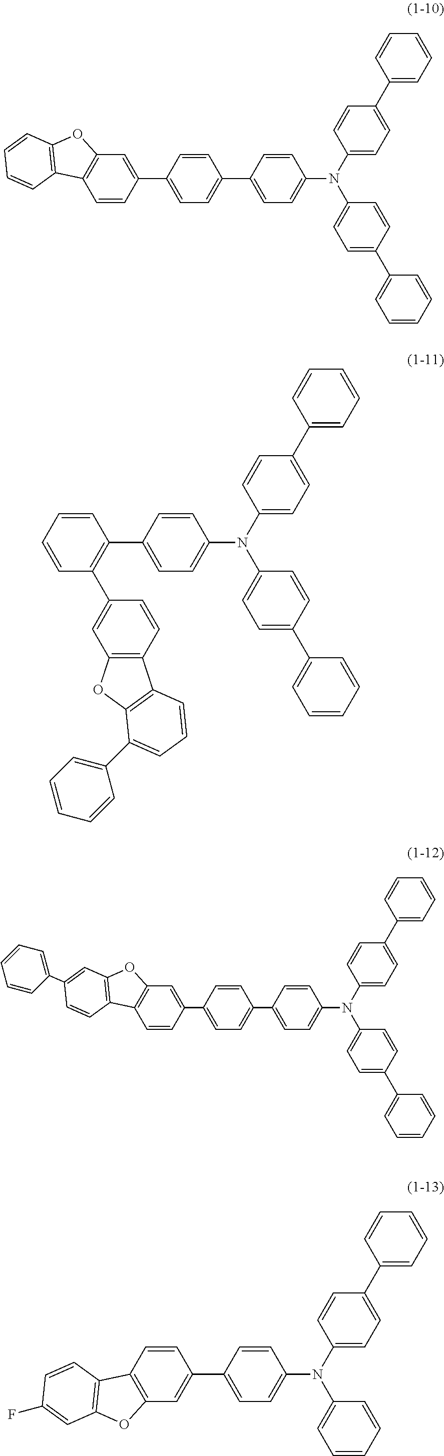 [SMILES: c1ccc(-c2ccc(N(c3ccc(-c4ccccc4)cc3)c3ccc(-c4ccc(-c5ccc6c(c5)oc5ccccc56)cc4)cc3)cc2)cc1 ; c1ccc(-c2ccc(N(c3ccc(-c4ccccc4)cc3)c3ccc(-c4ccccc4-c4ccc5c(c4)oc4c(-c6ccccc6)cccc45)cc3)cc2)cc1 ; c1ccc(-c2ccc(N(c3ccc(-c4ccccc4)cc3)c3ccc(-c4ccc(-c5ccc6c(c5)oc5cc(-c7ccccc7)ccc56)cc4)cc3)cc2)cc1 ; Fc1ccc2c(c1)oc1cc(-c3ccc(N(c4ccccc4)c4ccc(-c5ccccc5)cc4)cc3)ccc12]

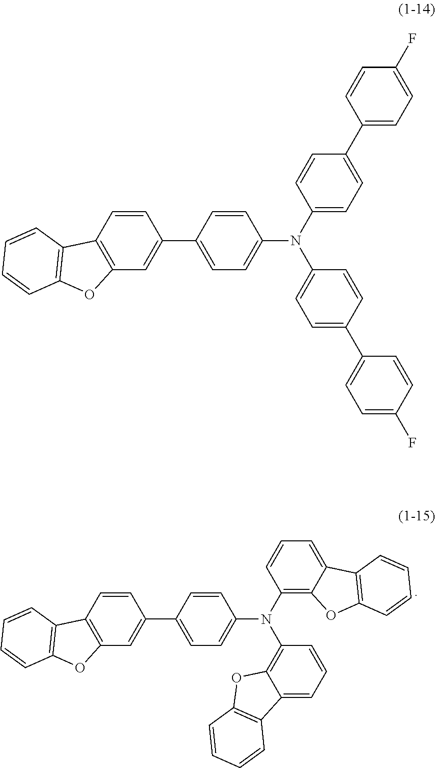 [SMILES: Fc1ccc(-c2ccc(N(c3ccc(-c4ccc(F)cc4)cc3)c3ccc(-c4ccc5c(c4)oc4ccccc45)cc3)cc2)cc1 ; c1ccc2c(c1)oc1cc(-c3ccc(N(c4cccc5c4oc4ccccc45)c4cccc5c4oc4ccccc45)cc3)ccc12]

### (2-1-1-3. Configuration of Third Hole Transport Layer)

The third hole transport layer 143 may be positioned between the first hole transport layer 141 and the second hole transport layer 142. The third hole transport layer 143 may include at least one selected from the third hole transport material and the fourth hole transport material.

### 2-2. EXAMPLES

Hereinafter, one or more embodiments of an organic EL device will be described referring to examples and comparative examples. However, the following embodiments are only for illustration, and the organic EL device according to example embodiments of the present disclosure is not limited thereto.

### 2-2-1. Synthesis of Fourth Hole Transport Material

### Synthetic Example 1

### Synthesis of Compound 1-7

Compound 1-7 was synthesized by the following procedure.

Under an argon atmosphere, 4.2 g of 4-bis(biphenylyl)aminophenyl boronic acid pinacol ester, 2 g of 3-bromodibenzofuran, 0.1 g of tetrakis(triphenylphosphine)palladium(0), 3.3 g of potassium carbonate, 180 mL of tetrahydrofuran, and 20 mL of water were added to a 500 mL, three necked flask, followed by heating and refluxing the resulting mixture at about 80° C. for about 12 hours. After air cooling, water was added thereto, the organic layer was separated, and solvents were distilled. The solid thus obtained was separated by flash column chromatography to produce 3.6 g of the target product as a white solid (Yield 80%).

¹H-NMR (CDCl₃, δ in ppm, 300 MHz) of the target product was measured and chemical shift values were 7.98 (m, 2H), 7.79 (d, 1H), 7.52-7.63 (m, 12H), 7.44-7.48 (m, 5H), 7.25-7.39 (m, 9H). The mass spectrum of the target product was measured by FAB method, and the peak mass number was 563 (M⁺, calculated 563.22). From these results, the target product was confirmed to be Compound 1-7.

### Synthetic Example 2

### Synthesis of Compound 1-1

Compound 1-1 was synthesized by performing a procedure similar to that described in Synthetic Example 1 for preparing Compound 1-7, except that 2.3 g of triphenylamine-4-boronic acid was used instead of 4.2 g of 4-bis(biphenylyl)aminophenyl boronic acid pinacol ester used in Synthetic Example 1. 3.0 g of the target product of a white solid was obtained (Yield 90%). The product was identified by NMR and mass spectrometry as in Synthetic Example 1.

### Synthetic Example 3

### Synthesis of Compound 1-10

Compound 1-10 was synthesized by performing procedure similar to that described in Synthetic Example 1 for preparing Compound 1-7, except that 4.8 g of 4-bis(biphenylyl)aminophenyl boronic acid pinacol ester was used instead of 4.2 g of 4-bis(biphenylyl)aminophenyl boronic acid pinacol ester used in Synthetic Example 1. 2.6 g of the target product of a white solid was obtained (Yield 51%). The product was identified by NMR and mass spectrometry.

### Synthetic Example 4

### Synthesis of Compound 1-13

Compound 1-13 was synthesized by the following procedure. Under an argon atmosphere, 3.6 g of 4-aminophenyl boronic acid pinacol ester, 4.2 g of 3-fluoro-3′-bromodibenzofuran, 0.2 g of tetrakis(triphenylphosphine)palladium(0), 6.6 g of potassium carbonate, 360 mL of tetrahydrofuran, and 40 mL of water were added to a 1 L, three necked flask, followed by heating and refluxing the resulting mixture at about 80° C. for about 12 hours. After air cooling, water was added thereto, the organic layer was separated, and solvents were distilled. The solid thus obtained was separated by flash column chromatography to produce 2.7 g of Intermediate 1 as a yellow solid (Yield 60%).

Under an argon atmosphere, 2.2 g of Intermediate 1, 1.9 g of 4-bromobiphenyl, 0.23 g of bis(dibenzylideneacetonato)palladium(0), 0.6 mL of a 2 M tri-tert-butylphosphine/L solution in toluene, 4.6 g of sodium tert-butoxide, and 100 mL of toluene were added to a 300 mL, three necked flask, followed by heating the resulting mixture at about 80° C. for about 4 hours. After air cooling, water was added thereto, an organic layer was separated, and solvents were distilled. The solid thus obtained was separated by flash column chromatography to produce 2.9 g of Intermediate 2 as a yellow solid (Yield 84%).

Under an argon atmosphere, 1.7 g of Intermediate 2, 0.7 g of 4-bromobenzene, 0.12 g of bis(dibenzylideneacetonato)palladium(0), 0.3 mL of a 2 M tri-tert-butylphosphine/L solution in toluene, 2.3 g of sodium tert-butoxide, and 50 mL of toluene were added to a 200 mL, three necked flask, followed by heating the resulting mixture at about 80° C. for about 4 hours. After air cooling, water was added thereto, the organic layer was separated, and solvents were distilled. The solid thus obtained was separated by flash column chromatography to produce 1.9 g of Compound 1-13 as a yellow solid (Yield 95%). The product was identified using NMR and mass spectrometry.

### Synthetic Example 5

### Synthesis of Compound 1-14

Compound 1-14 was synthesized by the following procedure. Under an argon atmosphere, 3.6 g of 4-aminophenyl boronic acid pinacol ester, 4.0 g of 3-bromodibenzofuran, 0.2 g of tetrakis(triphenylphosphine)palladium(0), 6.6 g of potassium carbonate, 360 mL of tetrahydrofuran, and 40 mL of water were added to a 1 L, three necked flask, followed by heating and refluxing the resulting mixture at about 80° C. for about 12 hours. After air cooling, water was added thereto, the organic layer was separated, and solvents were distilled. The solid thus obtained was separated by flash column chromatography to produce 3.0 g of Intermediate 3 as a yellow solid (Yield 73%).

Under an argon atmosphere, 1.6 g of Intermediate 3, 2.0 g of 4,4′-fluorobromobiphenyl, 0.23 g of bis(dibenzylideneacetonato)palladium(0), 0.6 mL of a 2 M tri-tert-butylphosphine/L solution in toluene, 2.3 g of sodium tert-butoxide, and 50 mL of toluene were added to a 200 mL, three necked flask, followed by heating the resulting mixture at about 80° C. for about 4 hours. After air cooling, water was added thereto, the organic layer was separated, and solvents were distilled. The solid thus obtained was separated by flash column chromatography to produce 2.0 g of Compound 1-14 as a yellow solid (Yield 91%). The product was identified using NMR and mass spectrometry.

### Synthetic Example 6

### Synthesis of Compound 1-15

Compound 1-15 was synthesized by the following procedure. Under an argon atmosphere, 1.6 g of Intermediate 3, 2.0 g of 4-bromodibenzofuran, 0.23 g of bis(dibenzylideneacetonato)palladium(0), 0.6 mL of a 2 M tri-tert-butylphosphine/L solution in toluene, 2.3 g of sodium tert-butoxide, and 50 mL of toluene were added to a 200 mL, three necked flask, followed by heating the resulting mixture at about 80° C. for about 4 hours. After air cooling, water was added thereto, the organic layer was separated, and solvents were distilled. The solid thus obtained was separated by flash column chromatography to produce 2.0 g of Compound 1-15 as a yellow solid (Yield 85%). The product was identified using NMR and mass spectrometry.

### 2-2-2. Manufacture of Organic EL Device

An organic EL device including a first hole transport layer including a third hole transport material and an electron accepting material doped in the third hole transport material according to an embodiment of the present disclosure was manufactured as follows. First an ITO-glass substrate patterned and washed in advance was surface treated using UV-Ozone (O₃). The layer thickness of the ITO layer (first electrode) was about 150 nm. After ozone treatment, the substrate was washed and inserted in a glass bell jar type evaporator (e.g., glass bell jar evaporator) for forming HTL1, HTL2, HTL3, an emission layer and an electron transport layer one by one by evaporation under a vacuum of about 10⁻⁴ to about 10⁻⁵ Pa. The layer thickness of each of the HTL1, HTL2 and HTL3 was about 10 nm. The thickness of the emission layer was about 25 nm, and the thickness of the electron transport layer was about 25 nm. Then, the substrate was moved into a glass bell jar type evaporator (e.g., glass bell jar evaporator) for forming a metal layer, and materials for the electron injection layer and the cathode were evaporated thereon under a vacuum of about 10⁻⁴ to about 10⁻⁵ Pa. The thickness of the electron injection layer was about 1.0 nm and the thickness of the second electrode was about 100 nm.

Here, “HTL1”, “HTL2” and “HTL3” refer to hole transport layers respectively formed using the materials as shown in Table 2. In Table 2, HTL1, HTL2, and HTL3 refer to the hole transport layers used as the first hole transport layer 141, the third hole transport layer 143, and the second hole transport layer 142, respectively. In Table 2, the expression “Compound 2-3, 4-15”, for example, refers to Compound 4-15 used as an electron accepting material being doped into Compound 2-3 used as a hole transport material. The doping amount of the electron accepting material was about 3 wt % on the basis of the amount of the hole transport material. The doping amount of the electron accepting material was the same in all Examples 2-1 to 2-13 and Comparative Examples 2-1 and 2-2. In Table 2, Compounds 6-1 to 6-3 may be represented by Formulae 6-1 to 6-3:

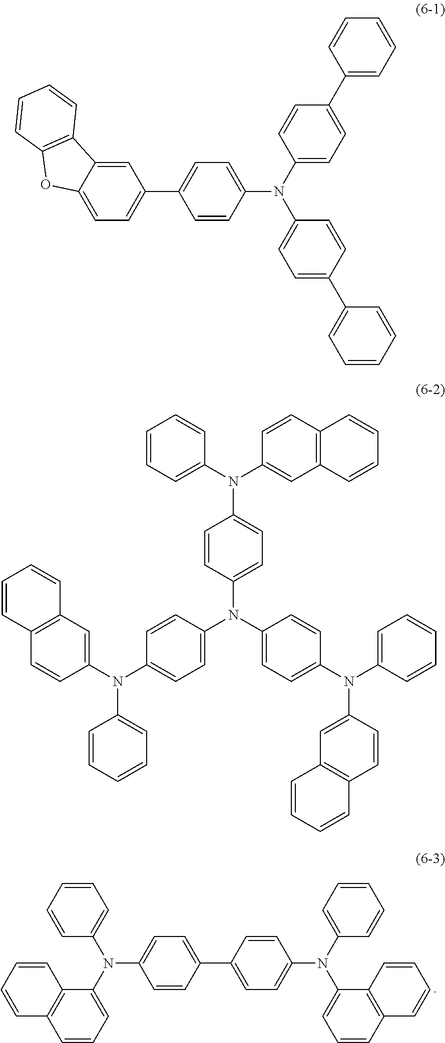 [SMILES: c1ccc(-c2ccc(N(c3ccc(-c4ccccc4)cc3)c3ccc(-c4ccc5oc6ccccc6c5c4)cc3)cc2)cc1 ; c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1]

The host material in the emission layer was 9,10-di(2-naphthyl)anthracene (ADN, Compound 3-2). The dopant material was 2,5,8,11-tetra-t-butylperylene (TBP). The doping amount of the dopant was about 3 wt % on the basis of the host. Alq3 was used as the electron transport material and LiF was used as the electron injection material. Al was used as the second electrode material.

TABLE 2

| | | | | Driving | Emission | |
|---|---|---|---|---|---|---|
| | | | | voltage | efficiency | Lifetime |
| | HTL1 | HTL2 | HTL3 | [V] | [cd/A] | LT50 (h) |
| Example 2-1 | Compound | Compound | Compound | 6.3 | 6.9 | 5,400 |
| | 2-3, 4-15 | 2-3 | 1-7 | | | |
| Example 2-2 | Compound | Compound | Compound | 6.8 | 7.3 | 3,200 |
| | 6-2, 4-15 | 2-3 | 1-7 | | | |
| Example 2-3 | Compound | Compound | Compound | 6.7 | 6.5 | 3,100 |
| | 2-3, 4-15 | 1-7 | 2-3 | | | |
| Example 2-4 | Compound | Compound | Compound | 6.8 | 6.9 | 3,200 |
| | 1-7 | 2-3, 4-15 | 1-7 | | | |
| Example 2-5 | Compound | Compound | Compound | 6.8 | 7.2 | 2,700 |
| | 2-3, 4-15 | 2-3 | 1-1 | | | |
| Example 2-6 | Compound | Compound | Compound | 6.6 | 7.0 | 2,900 |
| | 2-3, 4-15 | 2-3 | 1-15 | | | |
| Example 2-7 | Compound | Compound | Compound | 7.2 | 7.4 | 2,200 |
| | 2-3, 4-15 | 2-3 | 1-14 | | | |
| Example 2-8 | Compound | Compound | Compound | 6.8 | 7.0 | 2,200 |
| | 2-3, 4-15 | 2-3 | 1-13 | | | |
| Example 2-9 | Compound | Compound | Compound | 6.3 | 6.5 | 3,300 |
| | 2-3, 4-15 | 2-3 | 1-10 | | | |
| Example 2- | Compound | Compound | Compound | 6.3 | 6.2 | 3,400 |
| 10* | 2-7, 4-16 | 2-3 | 1-7 | | | |
| Example 2- | Compound | Compound | Compound | 6.3 | 6.2 | 3,100 |
| 11 | 2-3, 4-16 | 2-3 | 1-7 | | | |
| Example 2- | Compound | Compound | Compound | 6.4 | 6.7 | 3,500 |
| 12** | 2-7, 4-15 | 2-3 | 1-7 | | | |
| Example 2- | Compound | Compound | Compound | 7.1 | 7.2 | 3,000 |
| 13 | 2-3, 4-15 | 1-7 | 1-7 | | | |
| Comparative | Compound | Compound | Compound | 6.5 | 5.7 | 1,600 |
| Example 2-1 | 2-3, 4-15 | 2-3 | 2-3 | | | |
| Comparative | Compound | Compound | Compound | 7.2 | 5.5 | 2,100 |
| Example 2-2 | 2-3, 4-15 | 2-3 | 6-1 | | | |
| Comparative | Compound | Compound | Compound | 7.5 | 4.9 | 1,300 |
| Example 2-3 | 6-2 | 2-3 | 1-7 | | | |
| Comparative | Compound | Compound | Compound | 7.8 | 4.7 | 1,700 |
| Example 2-4 | 2-3 | 2-3 | 1-7 | | | |
| Comparative | Compound | Compound | Compound | 8.1 | 4.3 | 700 |
| Example 2-5 | 6-2 | 6-3 | 6-1 | | | |
| Comparative | Compound | Compound | Compound | 7 | 2.3 | 600 |
| Example 2-6 | 2-3 | 1-7 | 2-3, 4-15 | | | |

*DPVBi was used as the host of the emission layer.
**Compound 3-10 was used as the host of the emission layer.

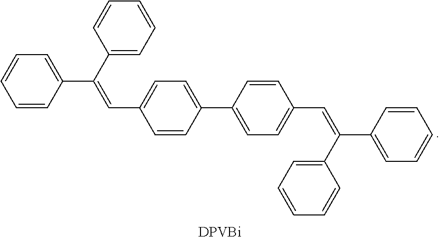 [SMILES: C(=C(c1ccccc1)c1ccccc1)c1ccc(-c2ccc(C=C(c3ccccc3)c3ccccc3)cc2)cc1 ; "DPVBi"]

In Examples 2-1 to 2-5, HTL1, HTL2, and HTL3 refer to the first hole transport layer 141, the third hole transport layer 143 and the second hole transport layer 142, respectively. In Example 2-1, Compound 2-3 was used as the third hole transport material forming the first hole transport layer 141. In Example 2-2, Compound 6-2 was used as the third hole transport material forming the first hole transport layer 141.

In Example 2-3, the stacking order of the second hole transport layer 142 and the third hole transport layer 143 was switched relative to Example 2-1. That is, in Example 2-3, the material forming the third hole transport layer 143 of Example 2-1 was included in the second hole transport layer 142. In Example 2-4, the stacking order of the first hole transport layer 141 and the third hole transport layer 143 was switched and the second hole transport layer included Compound 1-7 instead of Compound 2-3 relative to Example 2-3. In Examples 2-5 to 2-9, the compound represented by Formula 1 used in HTL3 was varied relative to Example 2-1. In Example 2-10, HTL1, HTL2, and HTL3 were substantially the same as in Example 2-1, except that HTL1 included Compound 2-7 as the hole transport material instead of Compound 2-3, and DPVBi was used as the host of the emission layer instead of ADN. In Example 2-11, HTL1, HTL2, and HTL3 were substantially the same as in Example 2-1, except that HTL1 included Compound 4-16 as the electron transport material instead of Compound 4-15. In Example 2-12, HTL1, HTL2, and HTL3 were substantially the same as in Example 2-1, except that HTL1 included Compound 2-7 as the hole transport material of HTL1 instead of Compound 2-3, and Compound 3-10 was used as the host of the emission layer instead of ADN. In Example 2-13, HTL2 and HTL3 constituted substantially the same layer. Thus, Example 2-13 is an example corresponding to the structure as shown in FIG. 2.

In Comparative Examples 2-1 and 2-2, HTL1 and HTL2 were substantially the same as in Example 2-1, and HTL3 included a third hole transport material instead of a fourth hole transport material as used in Example 2-1. In Comparative Example 2-1, Compound 2-3 was used as the third hole transport material. In Comparative Example 2-2, Compound 6-1 was used as the third hole transport material.

In Comparative Example 2-3, HTL1, HTL2, and HTL3 were substantially the same as in Example 2-2, except that the electron accepting material (Compound 4-15) was not included in the first hole transport layer 141. In Comparative Example 2-4, HTL1, HTL2, and HTL3 were substantially the same as in Example 2-1, except that the electron accepting material (Compound 4-15) was not included in the first hole transport layer 141. In Comparative Example 2-5, HTL1, HTL2, and HTL3 were formed using Compounds 6-2, 6-3, and 6-1, respectively. In Comparative Example 2-6, materials included in HTL1 of Example 2-1 were instead included in HTL3, materials included in HTL2 of Example 2-1 were instead included in HTL1, and material included in HTL3 of Example 2-1 were instead included in HTL2.

### 2-2-3. Evaluation of Properties of Organic EL Device

To evaluate the properties of the organic EL devices according to the examples and the comparative examples, driving voltage, emission efficiency and half lifetime (LT50) of each device were measured. The driving voltage and the emission efficiency were measured at a current density of about 10 mA/cm². The initial luminance of the half lifetime was about 1,000 cd/m². The measurement was performed using a Keithley Instruments Co. 2400 series source meter, Color brightness photometer CS-200 (Konica Minolta Holdings Co., Ltd., measurement angle of 1°), and LabVIEW8.2 (National Instruments Co., Ltd. in Japan) in a dark room. Evaluation results are shown in Table 2.

As shown in Table 2, the emission efficiency and the lifetime were better for Examples 2-1 to 2-13 than for Comparative Examples 2-1 to 2-6. The driving voltage was better (e.g., lower) for Examples 2-1 and 2-9 to 2-12 than for Comparative Examples 2-1 to 2-6. Without being bound by any particular theory, it is believed that the improvement of the emission efficiency and the lifetime of the organic EL device 100 was at least in part due to positioning the second hole transport layer 142 between the first hole transport layer 141 and the emission layer 150. As can be seen from the results obtained for Example 2-13, improved characteristics can be achieved even without including the third hole transport layer 143.

Comparing Example 2-1 with Comparative Example 2-2, the properties of the organic EL device 100 were improved when the material included in the second hole transport layer 142 was a compound in which an amine moiety was coupled at position 3 of dibenzofuran. Comparing Example 2-1 with Example 2-2 shows that when the compound represented by Formula 2 is used as the third hole transport material (e.g., in the first hole transport layer), the driving voltage and the lifetime of the organic EL device may be improved. Comparing Example 2-1 with Example 2-3 shows that when the second hole transport layer 142 is positioned adjacent to the emission layer 150, the driving voltage, the emission efficiency and the lifetime of the organic EL device may be improved.

Comparing Example 2-1 with Example 2-4 shows that when the first hole transport layer 141 is positioned adjacent to the first electrode 120, the driving voltage and the lifetime of the organic EL device may be improved.

When the electron accepting material according to embodiments of the present disclosure is introduced in HTL1 used as the first hole transport layer 141, the driving voltage of the resulting organic EL device may decrease. In embodiments where the second hole transport layer 142 is positioned adjacent to the emission layer 150, the lifetime of the resulting organic EL device may increase.

As described above, the emission efficiency and the lifetime of the organic EL device 100 may be improved by positioning the second hole transport layer 142 between the first hole transport layer 141 and the emission layer 150. In this and similar embodiments, such configuration may enable: (1) passivation of the hole transport layer 140 against electrons not consumed in the emission layer 150, (2) prevention or reduction of diffusion of energy with an excited state generated (e.g., diffusion of excitons) from the emission layer 150 into the hole transport layer 140, and (3) control over the charge balance of the whole device, etc. It is believed that the above-mentioned effects may be obtained at least in part because the second hole transport layer 142 restrains or reduces the diffusion of the electron accepting material positioned adjacent to the first electrode 120 into the emission layer 150.

In some embodiments, Ar₁ and Ar₂ of the fourth hole transport material may each independently be a substituted or unsubstituted aryl group having 6 to 12 carbon atoms for forming a ring, and in this case, the emission efficiency and the lifetime of the organic EL device 100 may be further improved.

The fourth hole transport material may be represented by one of Formulae 1-1 to 1-15, and in this case, the emission efficiency and the lifetime of the organic EL device 100 may be further improved.

The third hole transport material may have a structure represented by Formula 2, and in this case, the emission efficiency and the lifetime of the organic EL device 100 may be further improved.

The electron accepting material doped in the first hole transport layer 141 may have a LUMO level of about −9.0 eV to about −4.0 eV, and in this case, the emission efficiency and the lifetime of the organic EL device 100 may be further improved.

The emission layer 150 may include a luminescent material having a structure represented by Formula 3, and in this case, the emission efficiency and the lifetime of the organic EL device 100 may be further improved.

The second hole transport layer 142 may be positioned adjacent to the emission layer 150, and in this case, the emission efficiency and the lifetime of the organic EL device 100 may be further improved.

The first hole transport layer 141 may be positioned adjacent to the anode (e.g., first electrode 120), and in this case, the emission efficiency and the life of the organic EL device 100 may be further improved.

The third hole transport layer 143 may be between the first hole transport layer 141 and the second hole transport layer 142, and in this case, the emission efficiency and the lifetime of the organic EL device 100 may be further improved.

As described above, according to embodiments of the present disclosure, a second hole transport layer may be provided between a first hole transport layer and an emission layer, and the lifetime of an organic EL device may be improved.

As used herein, expressions such as “at least one of,” “one of,” “at least one selected from,” and “one selected from,” when preceding a list of elements, modify the entire list of elements and do not modify the individual elements of the list. Further, the use of “may” when describing embodiments of the present invention refers to “one or more embodiments of the present invention”.

In addition, as used herein, the terms “use,” “using,” and “used” may be considered synonymous with the terms “utilize,” “utilizing,” and “utilized,” respectively.

As used herein, the terms “substantially,” “about,” and similar terms are used as terms of approximation and not as terms of degree, and are intended to account for the inherent deviations in measured or calculated values that would be recognized by those of ordinary skill in the art.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. §112(a) and 35 U.S.C. §132(a).

The above-disclosed subject matter is to be considered illustrative and not restrictive, and the appended claims and equivalents thereof are intended to cover all such modifications, enhancements, and other embodiments, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. An organic electroluminescent (EL) device comprising:
an anode;
an emission layer;
a first hole transport layer between the anode and the emission layer, the first hole transport layer comprising an electron accepting material; and
a second hole transport layer between the first hole transport layer and the emission layer, the second hole transport layer comprising a first hole transport material represented by Formula 1) 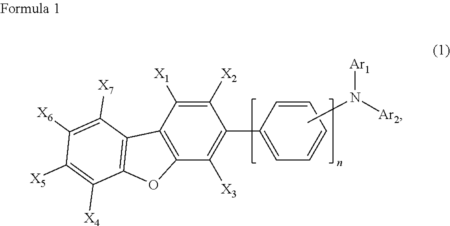
wherein Ar₁ and Ar₂ are each independently selected from a substituted or unsubstituted aryl group having 6 to 12 carbon atoms for forming a ring, and a substituted or unsubstituted heteroaryl group having 5 to 13 carbon atoms for forming a ring,
X₁ to X₇ are each independently selected from hydrogen, deuterium, a halogen atom, an alkyl group having 1 to 15 carbon atoms, a substituted or unsubstituted aryl group having 6 to 18 carbon atoms for forming a ring, and a substituted or unsubstituted heteroaryl group having 5 to 18 carbon atoms for forming a ring, and
a is 1 or 2.

2. The organic EL device of claim 1, wherein Ar₁ and Ar₂ are each independently a substituted or unsubstituted aryl group having 6 to 12 carbon atoms for forming a ring.

3. The organic EL device of claim 1, wherein the first hole transport material is selected from the group consisting of compounds represented by Formulae 1-1 to 1-15:

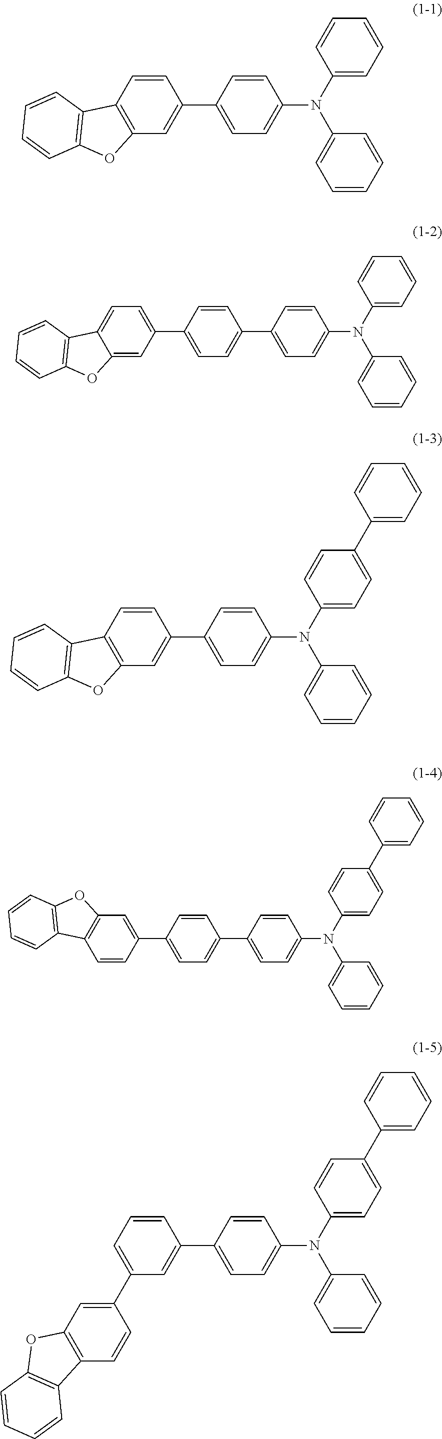 [SMILES: c1ccc(N(c2ccccc2)c2ccc(-c3ccc4c(c3)oc3ccccc34)cc2)cc1 ; c1ccc(N(c2ccccc2)c2ccc(-c3ccc(-c4ccc5c(c4)oc4ccccc45)cc3)cc2)cc1 ; c1ccc(-c2ccc(N(c3ccccc3)c3ccc(-c4ccc5c(c4)oc4ccccc45)cc3)cc2)cc1 ; c1ccc(-c2ccc(N(c3ccccc3)c3ccc(-c4ccc(-c5ccc6c(c5)oc5ccccc56)cc4)cc3)cc2)cc1 ; c1ccc(-c2ccc(N(c3ccccc3)c3ccc(-c4cccc(-c5ccc6c(c5)oc5ccccc56)c4)cc3)cc2)cc1]

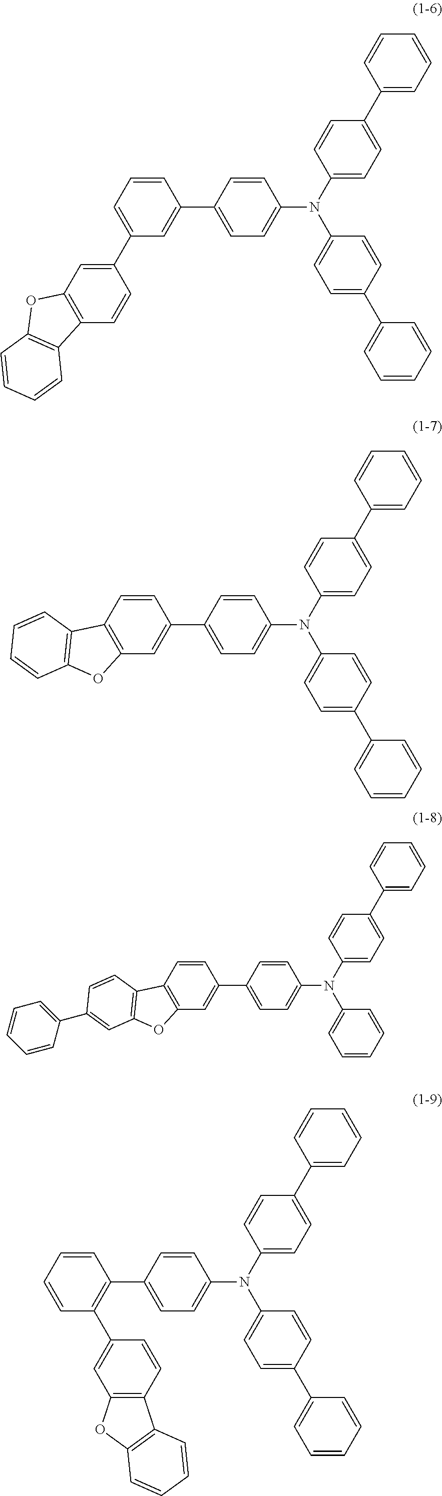

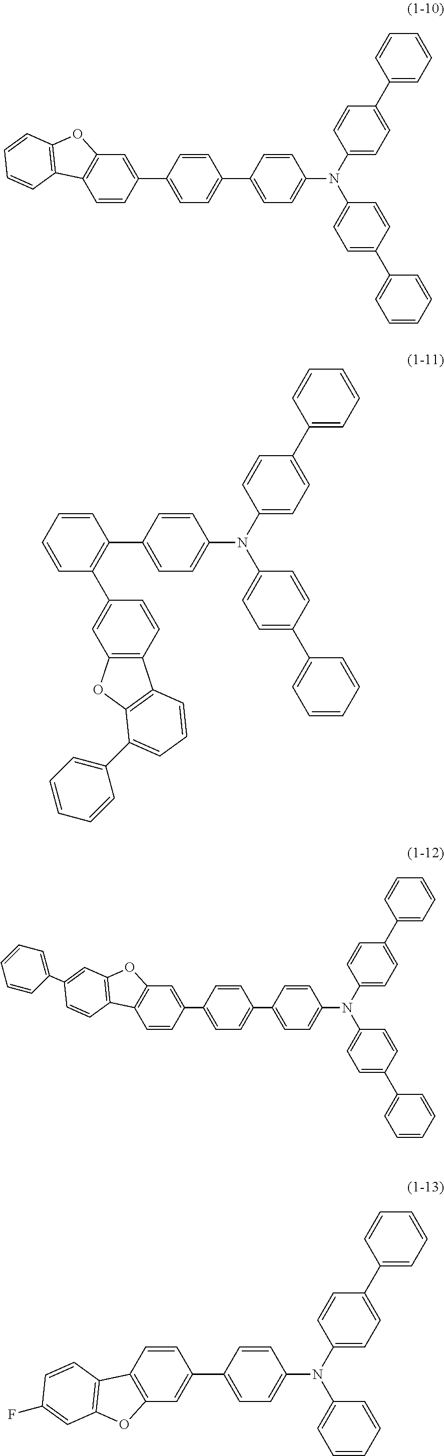 [SMILES: c1ccc(-c2ccc(N(c3ccc(-c4ccccc4)cc3)c3ccc(-c4ccc(-c5ccc6c(c5)oc5ccccc56)cc4)cc3)cc2)cc1 ; c1ccc(-c2ccc(N(c3ccc(-c4ccccc4)cc3)c3ccc(-c4ccccc4-c4ccc5c(c4)oc4c(-c6ccccc6)cccc45)cc3)cc2)cc1 ; c1ccc(-c2ccc(N(c3ccc(-c4ccccc4)cc3)c3ccc(-c4ccc(-c5ccc6c(c5)oc5cc(-c7ccccc7)ccc56)cc4)cc3)cc2)cc1 ; Fc1ccc2c(c1)oc1cc(-c3ccc(N(c4ccccc4)c4ccc(-c5ccccc5)cc4)cc3)ccc12]

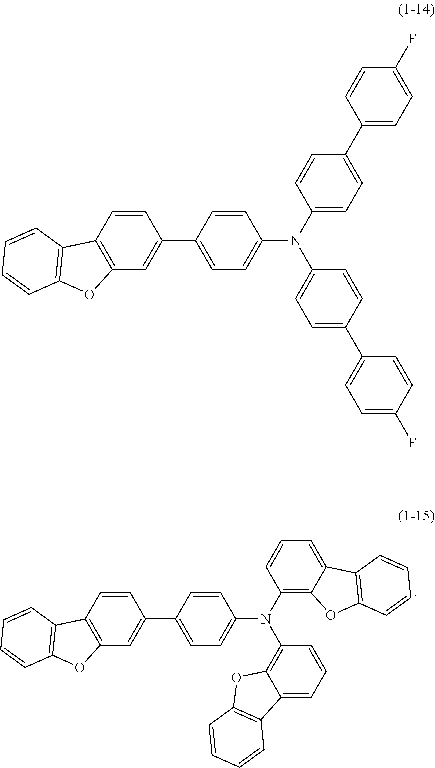 [SMILES: Fc1ccc(-c2ccc(N(c3ccc(-c4ccc(F)cc4)cc3)c3ccc(-c4ccc5c(c4)oc4ccccc45)cc3)cc2)cc1 ; c1ccc2c(c1)oc1cc(-c3ccc(N(c4cccc5c4oc4ccccc45)c4cccc5c4oc4ccccc45)cc3)ccc12]

4. The organic EL device of claim 1, wherein the electron accepting material has a Lowest Unoccupied Molecular Orbital (LUMO) level within a range of about −9.0 eV to about −4.0 eV.

5. The organic EL device of claim 1, wherein the first hole transport layer comprises a second hole transport material represented by Formula 2: 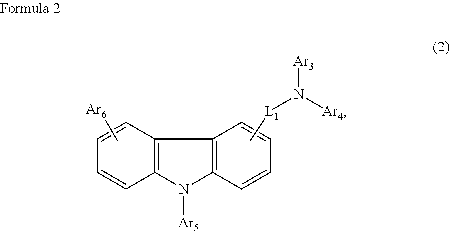
wherein Ar₃ to Ar₅ are each independently selected from a substituted or unsubstituted aryl group and a substituted or unsubstituted heteroaryl group,
Ar₆ is selected from a substituted or unsubstituted aryl group, a substituted or unsubstituted heteroaryl group, a carbazolyl group and an alkyl group, and
L₁ is selected from a direct linkage, a substituted or unsubstituted arylene group and a substituted or unsubstituted heteroarylene group.

6. The organic EL device of claim 5, wherein the second hole transport material is selected from the group consisting of compounds represented by Formulae 2-1 to 2-16:

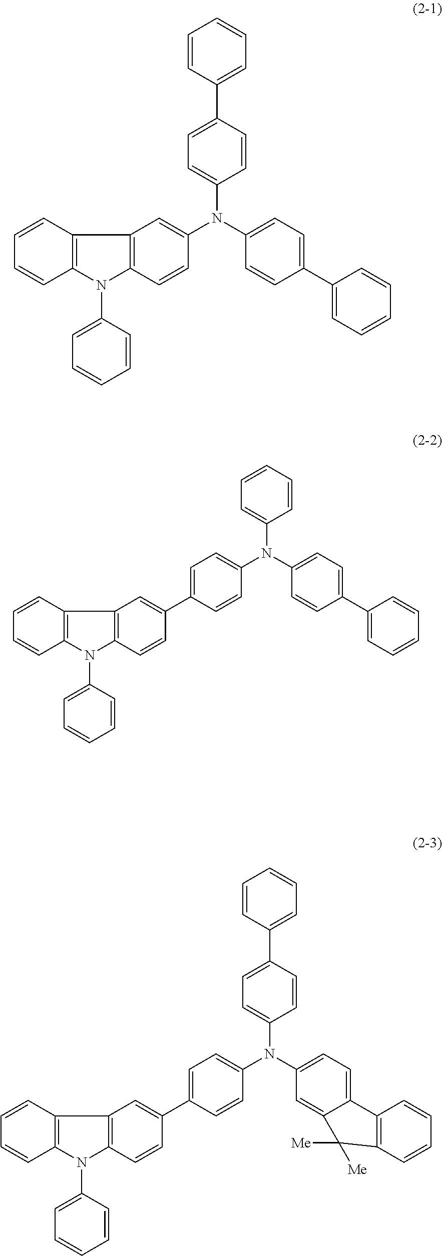 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

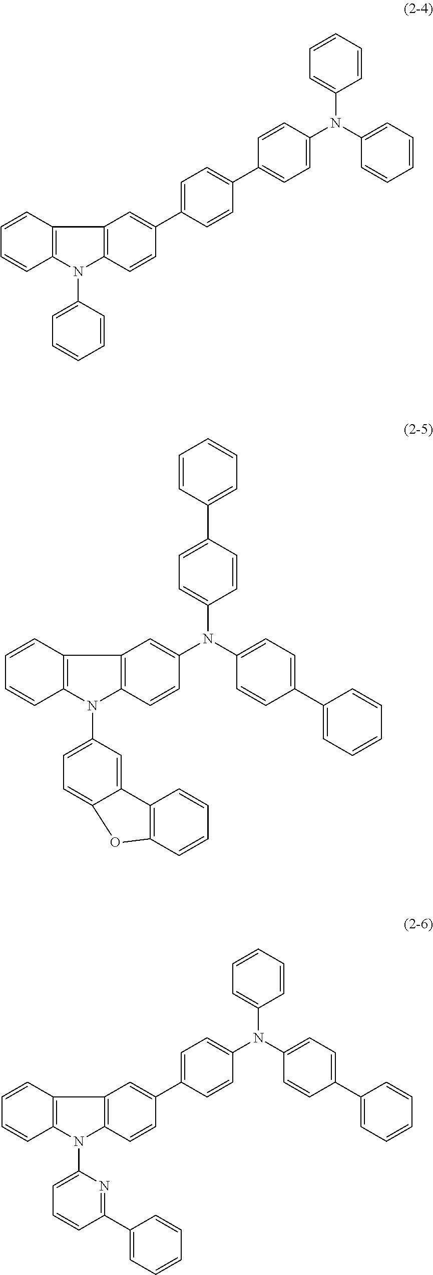 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

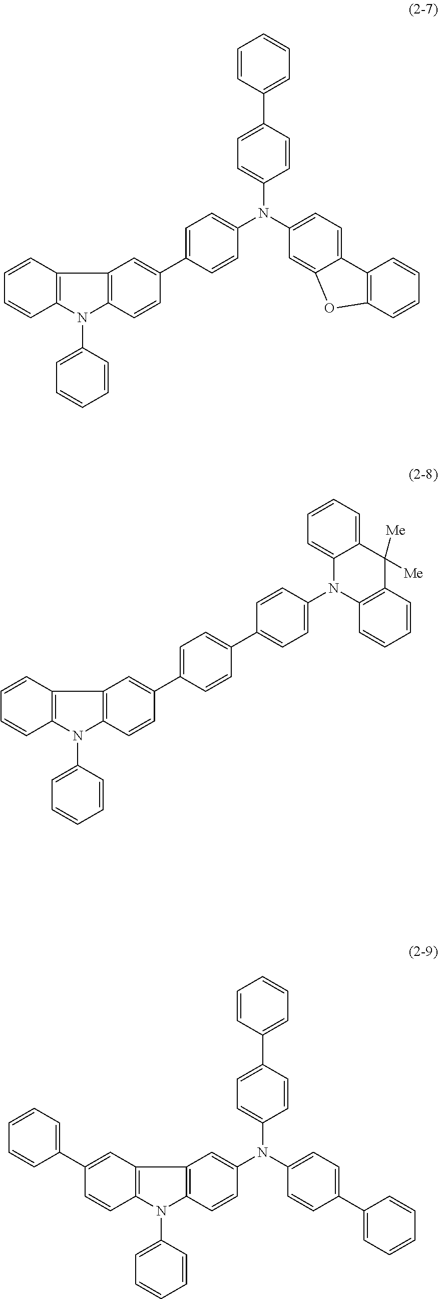 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

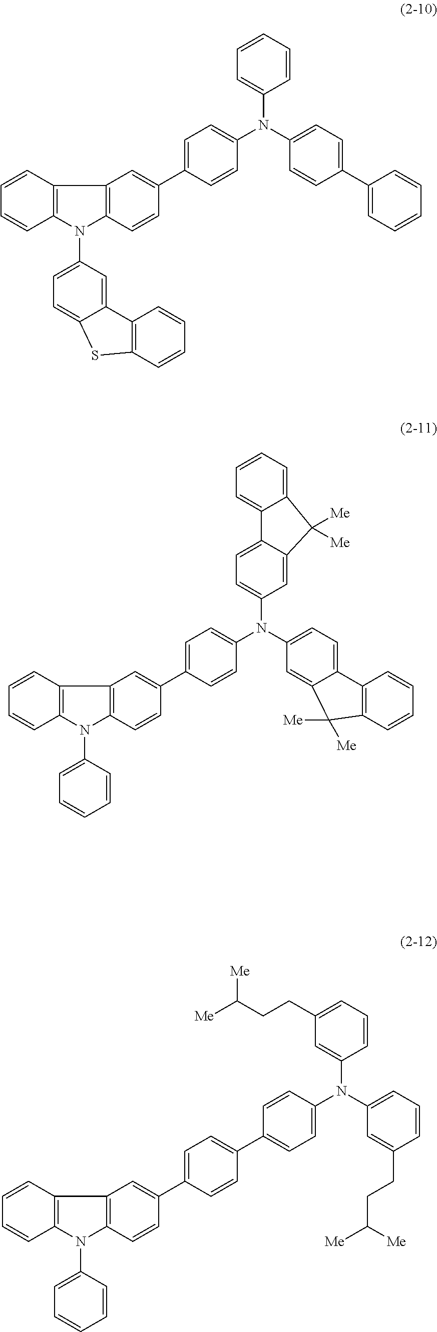 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

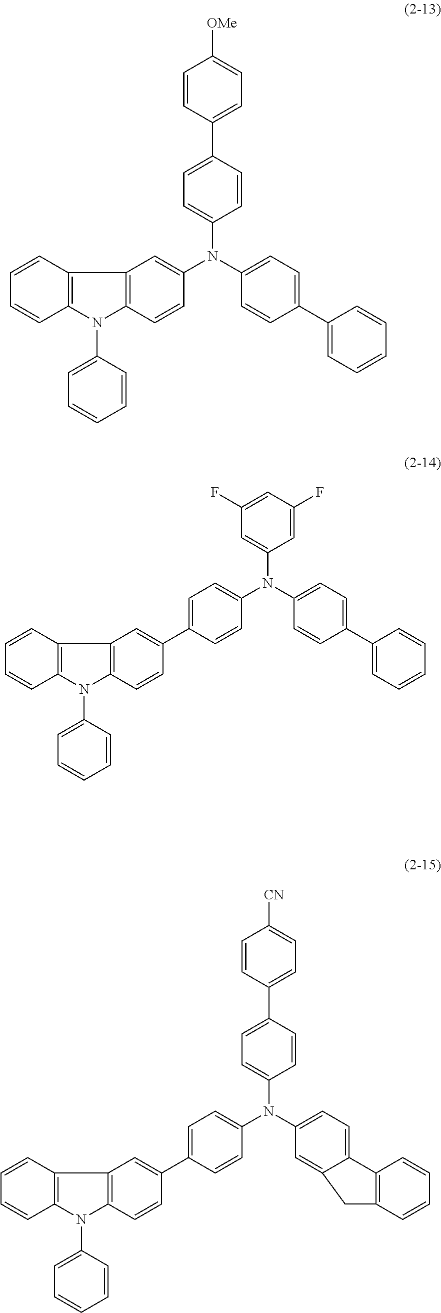 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

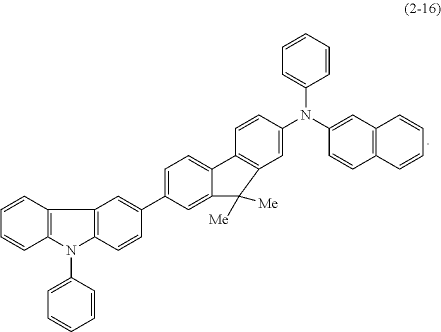 [SMILES: CC1(C)c2cc(-c3ccc4c(c3)c3ccccc3n4-c3ccccc3)ccc2-c2ccc(N(c3ccccc3)c3ccc4ccccc4c3)cc21]

7. The organic EL device of claim 5, further comprising a third hole transport layer between the first hole transport layer and the second hole transport layer, the third hole transport layer comprising at least one selected from the first hole transport material and the second hole transport material.

8. The organic EL device of claim 1, wherein the emission layer comprises a host material having a structure represented by the following Formula 3: 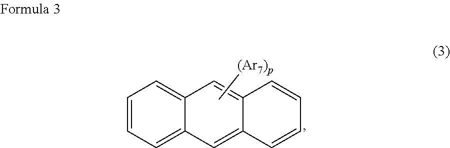
wherein each Ar₇ is independently selected from hydrogen, deuterium, a substituted or unsubstituted alkyl group having 1 to 50 carbon atoms, a substituted or unsubstituted cycloalkyl group having 3 to 50 carbon atoms for forming a ring, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms for forming a ring, a substituted or unsubstituted arylthio group having 6 to 50 carbon atoms for forming a ring, a substituted or unsubstituted alkoxycarbonyl group having 2 to 50 carbon atoms, a substituted or unsubstituted aryl group having 6 to 50 carbon atoms for forming a ring, a substituted or unsubstituted heteroaryl group having 5 to 50 carbon atoms for forming a ring, a substituted or unsubstituted silyl group, a carboxyl group, a halogen atom, a cyano group, a nitro group and a hydroxyl group, and
p is an integer selected from 1 to 10.

9. The organic EL device of claim 1, wherein the second hole transport layer is adjacent to the emission layer.

10. The organic EL device of claim 1, wherein the first hole transport layer is adjacent to the anode.

11. An organic electroluminescent (EL) device comprising:
an anode;
an emission layer;
a first hole transport layer between the anode and the emission layer, the first hole transport layer comprising a third hole transport material and an electron accepting material doped in the third hole transport material; and
a second hole transport layer between the first hole transport layer and the emission layer, the second hole transport layer comprising a fourth hole transport material represented by Formula 1: 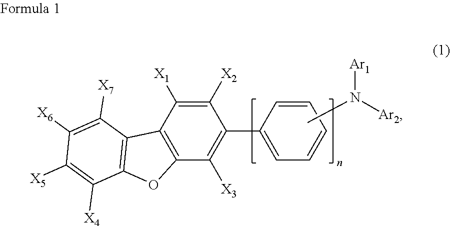
wherein Ar₁ and Ar₂ are each independently selected from a substituted or unsubstituted aryl group having 6 to 12 carbon atoms for forming a ring, and a substituted or unsubstituted heteroaryl group having 5 to 13 carbon atoms for forming a ring,
X₁ to X₇ are each independently selected from hydrogen, deuterium, a halogen atom, an alkyl group having 1 to 15 carbon atoms, a substituted or unsubstituted aryl group having 6 to 18 carbon atoms for forming a ring, and a substituted or unsubstituted heteroaryl group having 5 to 18 carbon atoms for forming a ring, and
a is 1 or 2.

12. The organic EL device of claim 11, wherein Ar₁ and Ar₂ are each independently a substituted or unsubstituted aryl group having 6 to 12 carbon atoms for forming a ring.

13. The organic EL device of claim 11, wherein the fourth hole transport material is selected from the group consisting of compounds represented by Formulae 1-1 to 1-15:

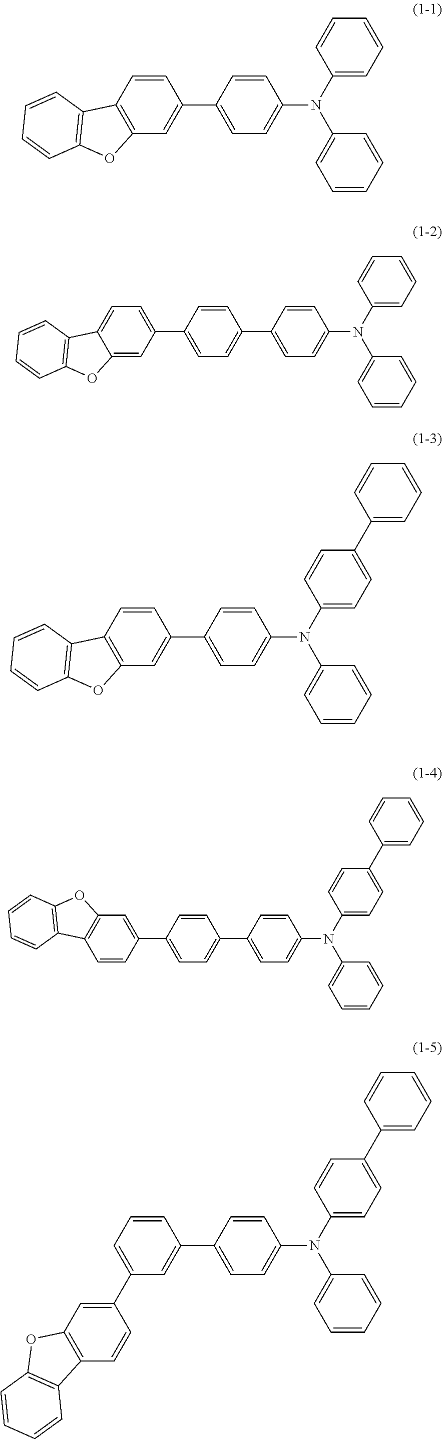 [SMILES: c1ccc(N(c2ccccc2)c2ccc(-c3ccc4c(c3)oc3ccccc34)cc2)cc1 ; c1ccc(N(c2ccccc2)c2ccc(-c3ccc(-c4ccc5c(c4)oc4ccccc45)cc3)cc2)cc1 ; c1ccc(-c2ccc(N(c3ccccc3)c3ccc(-c4ccc5c(c4)oc4ccccc45)cc3)cc2)cc1 ; c1ccc(-c2ccc(N(c3ccccc3)c3ccc(-c4ccc(-c5ccc6c(c5)oc5ccccc56)cc4)cc3)cc2)cc1 ; c1ccc(-c2ccc(N(c3ccccc3)c3ccc(-c4cccc(-c5ccc6c(c5)oc5ccccc56)c4)cc3)cc2)cc1]

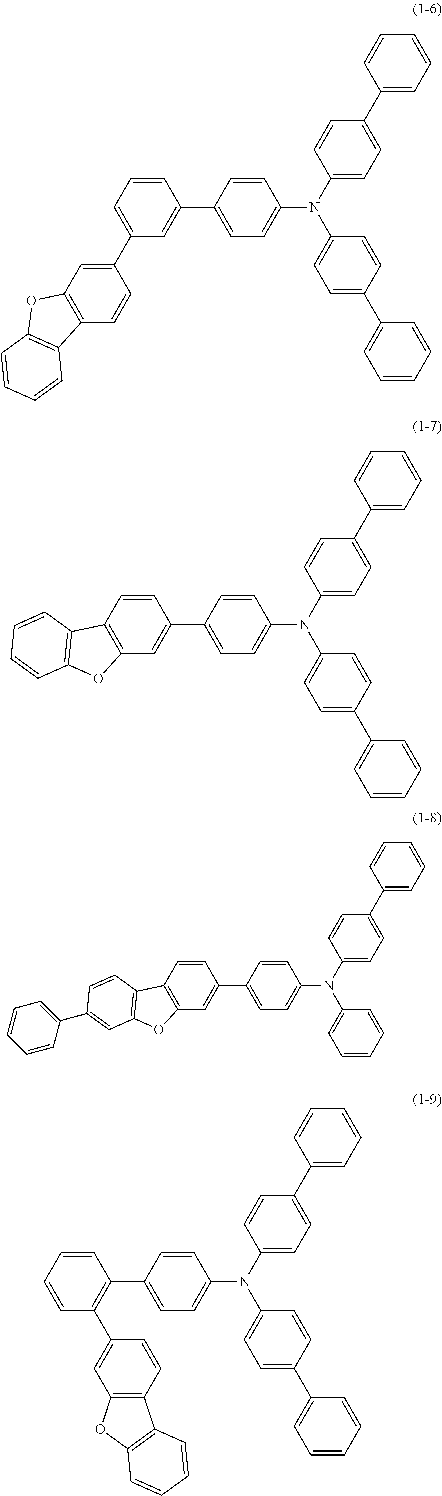

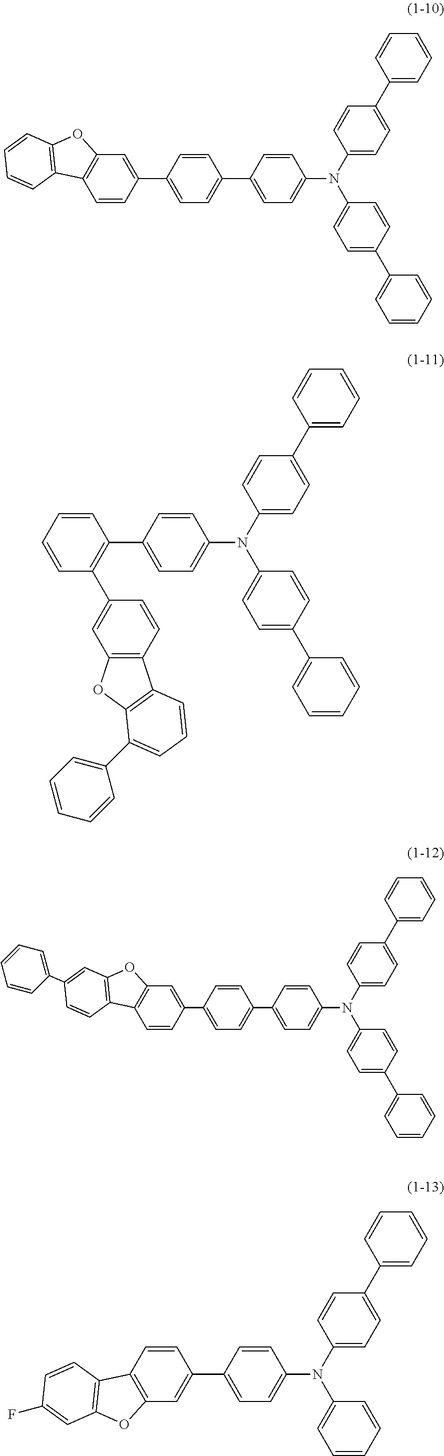 [SMILES: c1ccc(-c2ccc(N(c3ccc(-c4ccccc4)cc3)c3ccc(-c4ccc(-c5ccc6c(c5)oc5ccccc56)cc4)cc3)cc2)cc1 ; c1ccc(-c2ccc(N(c3ccc(-c4ccccc4)cc3)c3ccc(-c4ccccc4-c4ccc5c(c4)oc4c(-c6ccccc6)cccc45)cc3)cc2)cc1 ; c1ccc(-c2ccc(N(c3ccc(-c4ccccc4)cc3)c3ccc(-c4ccc(-c5ccc6c(c5)oc5cc(-c7ccccc7)ccc56)cc4)cc3)cc2)cc1 ; Fc1ccc2c(c1)oc1cc(-c3ccc(N(c4ccccc4)c4ccc(-c5ccccc5)cc4)cc3)ccc12]

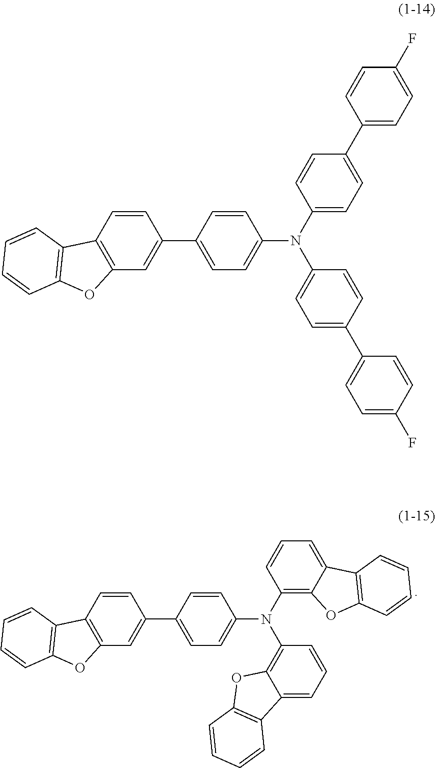 [SMILES: Fc1ccc(-c2ccc(N(c3ccc(-c4ccc(F)cc4)cc3)c3ccc(-c4ccc5c(c4)oc4ccccc45)cc3)cc2)cc1 ; c1ccc2c(c1)oc1cc(-c3ccc(N(c4cccc5c4oc4ccccc45)c4cccc5c4oc4ccccc45)cc3)ccc12]

14. The organic EL device of claim 11, wherein the third hole transport material is represented by Formula 2: 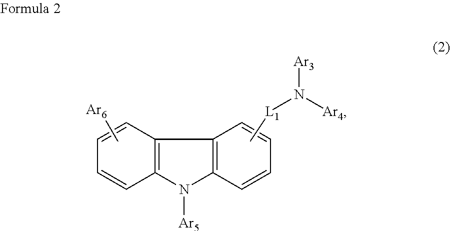
wherein Ar₃ to Ar₅ are each independently a substituted or unsubstituted aryl group or a substituted or unsubstituted heteroaryl group,
Ar₆ is selected from a substituted or unsubstituted aryl group, a substituted or unsubstituted heteroaryl group, a carbazolyl group and an alkyl group, and
L₁ is selected from a direct linkage, a substituted or unsubstituted arylene group and a substituted or unsubstituted heteroarylene group.

15. The organic EL device of claim 14, wherein the third hole transport material is selected from the group consisting of compounds represented by Formulae 2-1 to 2-16:

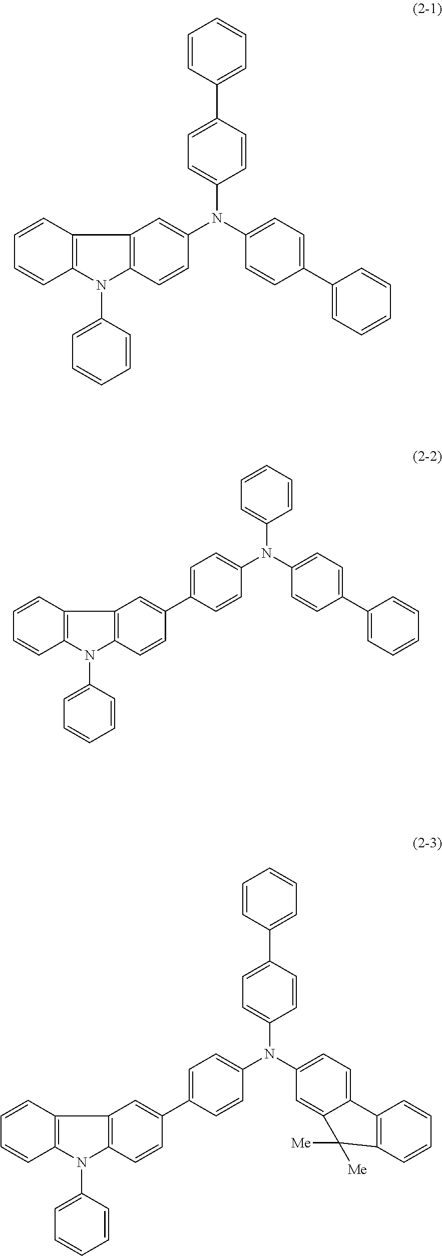 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

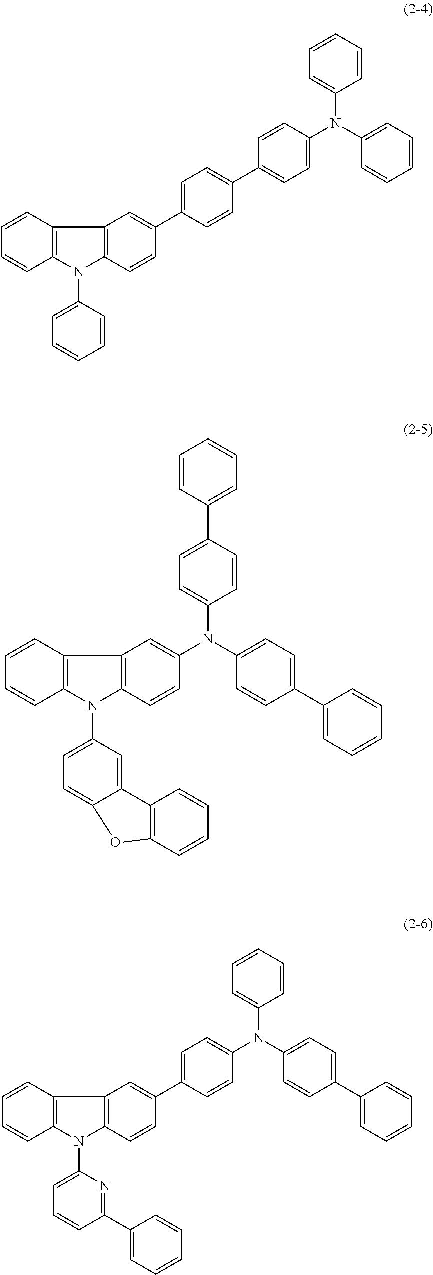 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

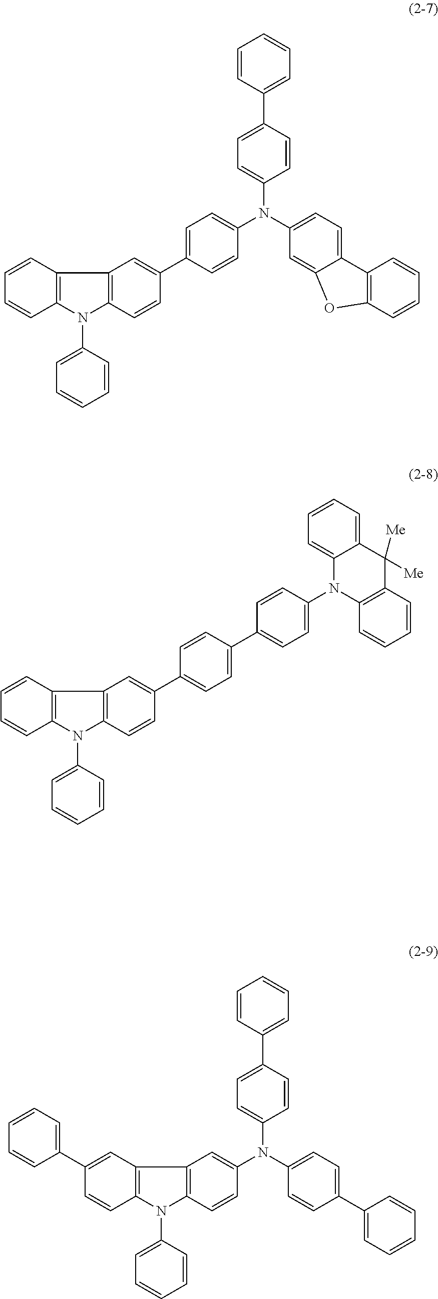 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

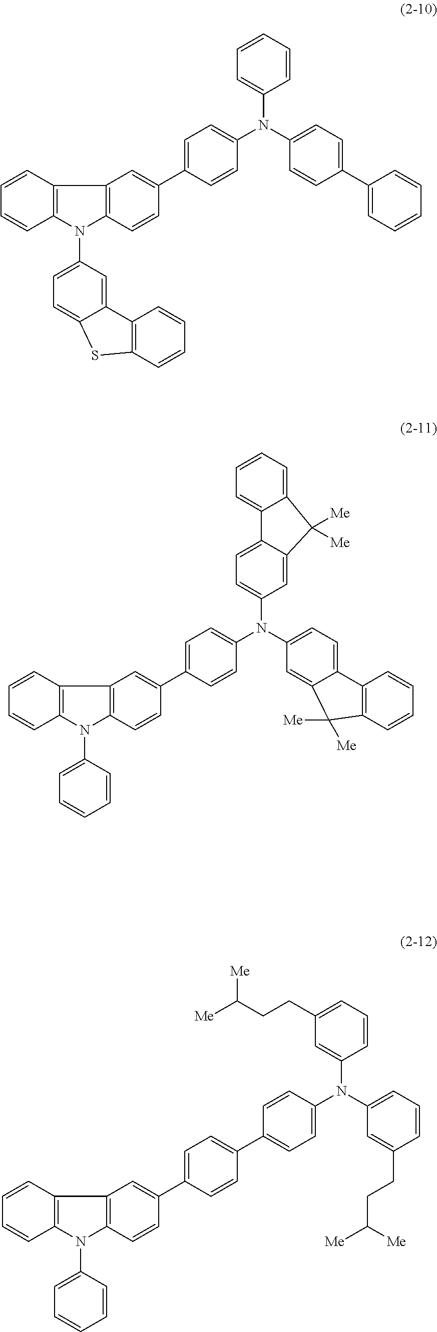 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

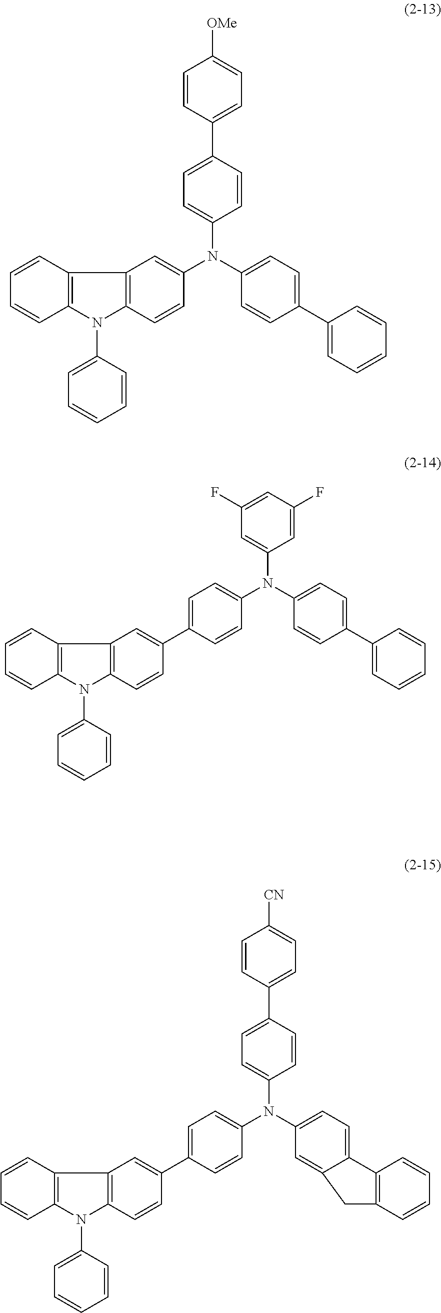 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

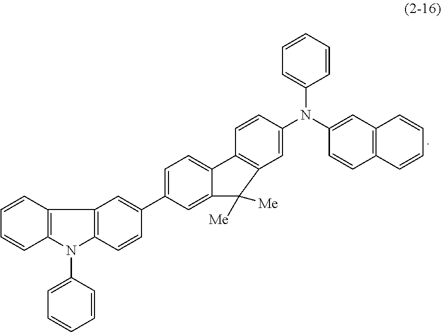 [SMILES: CC1(C)c2cc(-c3ccc4c(c3)c3ccccc3n4-c3ccccc3)ccc2-c2ccc(N(c3ccccc3)c3ccc4ccccc4c3)cc21]

16. The organic EL device of claim 11, wherein the electron accepting material has a Lowest Unoccupied Molecular Orbital (LUMO) level within a range of about −9.0 eV to about −4.0 eV.

17. The organic EL device of claim 11, wherein the emission layer comprises a host material having a structure represented by Formula 3: 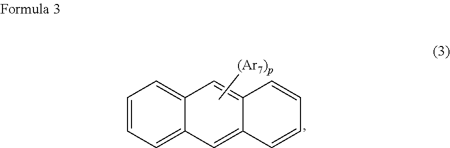
wherein each Ar₇ is independently selected from hydrogen, deuterium, a substituted or unsubstituted alkyl group having 1 to 50 carbon atoms, a substituted or unsubstituted cycloalkyl group having 3 to 50 carbon atoms for forming a ring, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 carbon atoms for forming a ring, a substituted or unsubstituted arylthio group having 6 to 50 carbon atoms for forming a ring, a substituted or unsubstituted alkoxycarbonyl group having 2 to 50 carbon atoms, a substituted or unsubstituted aryl group having 6 to 50 carbon atoms for forming a ring, a substituted or unsubstituted heteroaryl group having 5 to 50 carbon atoms for forming a ring, a substituted or unsubstituted silyl group, a carboxyl group, a halogen atom, a cyano group, a nitro group and a hydroxyl group, and
p is an integer from 1 to 10.

18. The organic EL device of claim 11, wherein the second hole transport layer is adjacent to the emission layer.

19. The organic EL device of claim 11, wherein the first hole transport layer is adjacent to the anode.

20. The organic EL device of claim 11, further comprising a third hole transport layer between the first hole transport layer and the second hole transport layer, the third hole transport layer comprising at least one selected from the third hole transport material and the fourth hole transport material.
